(19) United States
(12) Patent Application Publication
(10) Pub. No.: US 2008/0230773 A1
(43) Pub. Date: Sep. 25, 2008

(54) Polymer Composition for Preparing Electronic Devices by Microcontact Printing Processes and Products Prepared by the Processes

(75) Inventors: Kimberly DICKEY, Cambridge, MA (US); Brian T. Mayers, Somerville, MA (US); Sandip Agarwal, Cambridge, MA (US); Jeffrey Carbeck, Belmont, MA (US); David Christopher Coffey, Allston, MA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Nano Terra Inc., Cambridge, MA (US)

(21) Appl. No.: 12/052,329

(22) Filed: Mar. 20, 2008

Related U.S. Application Data
(60) Provisional application No. 60/895,883, filed on Mar. 20, 2007.
(60) Provisional application No. 60/975,608, filed on Sep. 27, 2007.

(51) Int. Cl. H01L 51/00; H01B 1/12

(52) U.S. Cl. 257/40; 438/99; 252/511; 257/E51.001

(57) ABSTRACT

The present invention is directed to methods for patterning substrates using contact printing processes and inks comprising an organic semiconductive or semiconductive polymer, inks for use with the processes, and products formed by the processes.

This application claims the benefit of the filing date of U.S. Provisional Appl. No. 60/895,883, filed Mar. 20, 2007, and U.S. Provisional Appl. No. 60/975,608, filed Sep. 27, 2007, both of which are incorporated herein by reference in their entireties.

### BACKGROUND OF THE INVENTION

1. Field of the Invention

The present invention is directed to methods for patterning a substrate using contact printing processes that employ a stamp and an ink comprising an organic semiconductive or semiconductive polymer.

2. Background

The integration of plastics and other polymeric materials into electronic devices presents numerous advantages in terms of the variety of substrates onto which electronic circuits can be formed. In particular, flexible electronic devices can be utilized as displays, personal electronics, wearable devices, and the like. Central to this development is the ability to form conductive patterns using processes that are compatible with flexible substrates such as plastics, and other materials (e.g, “low” temperatures in the range of 0° C. to 200° C.). In particular, the integration of non-metallic conductors with flexible substrates offers the widest range of device possibilities. However, most traditional patterning methods such as, for example, photolithography, require deposition and/or etching temperatures above 200° C., and are therefore unsuited for creating precise conductive patterns at lower temperatures.

There are a limited number of techniques available for directly patterning polymeric materials. A common method for patterning polymeric materials, especially organic polymers, is ink-jet printing. However, due to droplet spreading ink-jet printing does not usually provide the necessary feature resolution to form sub-micron patterns.

More recently developed soft-lithographic printing techniques such as “micro-contact printing” (see, e.g., U.S. Pat. No. 5,512,131) are suitable for forming patterns at lower temperatures. Soft lithographic methods typically utilize an elastomeric stamp whereby ink comprising an etchant or a molecule is transferred from the stamp to a substrate in a pattern defined by the topography of the stamp. Soft-lithographic methods have demonstrated the ability to produce patterns having lateral dimensions as small as 40 nm in a cost-effective, reproducible manner at low temperatures. However, the range of patterns that can be formed using these techniques is somewhat limited because contact printing processes are typically dependent upon process conditions and ink/substrate compatibility. In particular, a method does not exist to directly form a conductive or semiconductive polymeric pattern on a substrate.

What is needed is a contact printing method for forming conductive or semiconductive polymer patterns on substrates.

Additionally, the physical and chemical properties of a stamp must be balanced to provide efficient, uniform inking of the stamp and formation of a pattern. For example, while inert elastomers, such as surface-fluorinated or surface-silanized elastomers, exhibit excellent pattern transfer and durability, stamps formed from these materials can be difficult to evenly coat with an ink, resulting in uneven printing. Additionally, surface treatment processes can be difficult to reproduce.

What is needed is a stamp composition that can provide uniform pattern transfer of a conductive or semiconductive polymer to a wide variety of substrates over a large surface area and over multiple printing cycles.

### BRIEF SUMMARY OF THE INVENTION

The present invention is directed to patterning surfaces using contact-printing techniques that utilize conductive or semiconductive polymeric inks.

The present invention is directed to a process for forming a conductive or semiconductive polymer pattern on a substrate, the process comprising:
providing a stamp having a surface including at least one protrusion thereon, the protrusion being contiguous with and defining a pattern on the surface of the stamp;
applying an ink comprising a conductive or semiconductive polymer and a solvent to the stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer pattern has an electron or hole mobility of about 10⁻⁶ cm²/V·s or more.

In some embodiments, the process further comprises preventing chemical or photo-initiated degradation of the conductive or semiconductive polymer during the applying and the contacting. In some embodiments, the preventing comprises shielding the conductive or semiconductive polymer from ultraviolet light. In some embodiments, the preventing comprises excluding oxidative reagents from the conductive or semiconductive polymer during the applying and the contacting.

In some embodiments, the process further comprises maintaining the conductive or semiconductive polymer in a fluidic, gelled or flexible state during at least the contacting.

In some embodiments, the process further comprises maintaining the stamp, the substrate, or a combination thereof at a temperature of about 50° C. or less during the contacting.

In some embodiments, the process further comprises wetting the stamp with a first solvent prior to the applying, wherein the first solvent is the same or different from the ink solvent, and wherein the first solvent maintains the ink in a fluidic, gelled or flexible state during at least the contacting. In some embodiments, the first solvent has a vapor pressure at 25° C. of about 20 mm Hg or less.

In some embodiments, the process further comprises wetting the stamp with a first solvent prior to the applying, wherein the first solvent is the same or different from the ink solvent, and wherein the first solvent facilitates uniformly coating the at least one protrusion with the ink.

In some embodiments, the first solvent has a vapor pressure at 25° C. of about 20 mm Hg or less.

In some embodiments, the process further comprises maintaining the stamp, the substrate, or a combination thereof at a temperature of about 50° C. or more during the contacting.

In some embodiments, the process further comprises providing thermal energy to the substrate, the stamp, or a combination thereof during the contacting.

In some embodiments, the process further comprises pre-treating the stamp surface prior to the applying.

In some embodiments, the pre-treating comprises depositing on at least a portion of the stamp a layer chosen from: a fluorinated (C₄-C₂₀)alkyl-trihalosilane, a fluorinated (C₄-C₂₀)alkyl-trialkoxysilane, a halogen radical, an elastomer coating having a modulus of about 3 MPa or more, a polyacrylate coating, a polyurethane coating, an epoxy coating, a metal coating, a metal oxide coating, composites thereof, and combinations thereof.

In some embodiments, the process further comprises incubating the coated stamp for a time period of about 2 minutes to about 1 hour prior to the contacting.

In some embodiments, the applying comprises spray coating the stamp with the ink, incubating the coated stamp for about 1 minute to about 10 minutes, and spinning the stamp at about 100 to about 5,000 rpm.

In some embodiments, the applying provides a coated stamp comprising a discontinuous coating of the ink on the at least one protrusion and the stamp surface.

In some embodiments, the ink is substantially free from crystallinity during the applying and the contacting.

In some embodiments, the conductive or semiconductive polymer pattern is substantially free from cracks, pinholes, and mechanical defects.

The present invention is also directed to a product prepared by the above processes.

Process products of the present invention include, but are not limited to, an organic thin film transistor, an organic light emitting diode, an organic field effect transistor, an organic molecular switch, an organic photovoltaic device, an organic light-emitting electrochemical cell, and combinations thereof.

The present invention is also directed to a low-temperature process for forming a conductive or semiconductive polymer pattern on a substrate, the process comprising:
providing a stamp having a surface including at least one protrusion thereon, the protrusion being contiguous with and defining a pattern on the surface of the stamp,
wherein the at least one protrusion comprises an elastomer having a modulus of about 3 MPa or more; wetting the stamp with a first solvent to provide a wetted stamp;
applying an ink comprising a conductive or semiconductive polymer and a solvent to the wetted stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer is maintained in a fluidic or flexible state during the contacting, wherein a temperature of about 50° C. or less is maintained during the process, and wherein the conductive or semiconductive polymer pattern has an electron or hole mobility of about 10⁻⁶ cm²/V·s or more.

In some embodiments, the at least one protrusion comprises an elastomer having a surface free energy that is about 50% or less than a surface free energy of the substrate.

In some embodiments, the at least one protrusion comprises an elastomer having a surface free energy of about 25 ergs/cm² to about 35 ergs/cm².

The present invention is also directed to an elastomeric stamp composition comprising:
an elastomeric stamp having a body and a surface including at least one protrusion thereon, the protrusion having face and sidewall portions, and the protrusion being contiguous with and defining a pattern on the surface of the stamp, the face comprising a first elastomer and the body comprising a second elastomer, wherein the first elastomer has a modulus at least about 20% greater than the second elastomer;
a first solvent having a vapor pressure at 25° C. of about 20 mm Hg or less present in at least the body in a concentration of about 30% by volume, wherein the first solvent is in fluid communication with the face portion; and
an ink comprising a conductive or semiconductive polymer and a solvent discontinuously coating the stamp surface and the at least one protrusion, wherein the ink uniformly coats the face of the at least one protrusion, wherein the sidewall portion is substantially free from the ink, and wherein the solvent present in the body continuously wets the ink on at least the face.

In some embodiments, the elastomeric stamp composition further comprises a rigid backing layer attached to the body and substantially parallel to the face portion.

In some embodiments, the first elastomer has a modulus of 3 MPa or more and the second elastomer has a modulus of about 3 MPa or less.

The present invention is also directed to a metallized elastomeric stamp composition comprising:
an elastomeric stamp having a surface including at least one protrusion thereon, the protrusion having face and sidewall portions, and the protrusion being contiguous with and defining a pattern on the surface of the stamp;
a metal coating at least the face of the at least one protrusion;
a self-assembled monolayer-forming species (“SAM-forming species”) covalently attached to at least a portion of the metal coating; and
an ink comprising a conductive or semiconductive polymer and a solvent discontinuously coating the stamp surface and the at least one protrusion, wherein the ink uniformly coats the face of the at least one protrusion and wherein the sidewall portion is substantially free from the ink.

In some embodiments, the SAM-forming species has the structure:

-L-M-X

wherein -L- is a linker group that covalently bonds the SAM-forming species to the metal surface; -M- is a group chosen from: an optionally substituted C₁-C₂₀ alkyl, an optionally substituted C₁-C₂₀ alkenyl, an optionally substituted C₁-C₂₀ alkynyl, an optionally substituted C₁-C₂₀ aryl, an optionally substituted C₁-C₂₀ heteroaryl, and combinations thereof, and —X is an optional terminal group.

In some embodiments, -L- is a group chosen from: —S—; —O—; —NH—; —NR—; —NH—C(O)—; —NR—C(O)—; —C(O)—NH—; —C(O)—NR—; —SiH₂—; —Si(R)(R′)-; —Si(OR)(OR′)—; and combinations thereof, wherein R and R′ are independently an optionally substituted C₁-C₈ alkyl, alkenyl, alkynyl, aryl, or heteroaryl group.

In some embodiments, —X is a group chosen from: fluoro (—F), secondary amino (—N(R)(R′)), trialkylsilyl (—Si(R)(R′)(R″)), and combinations thereof, wherein R, R′ and R″ are independently a C₁-C₄ straight- or branched-chain alkyl group.

In some embodiments, the ink metallized elastomeric stamp composition further comprises a second SAM-forming species having the structure:

-L-M-X′

wherein —X′ is a group chosen from: carboxy (—COOH), primary amino (—NH₂), hydroxy (—OH), and combinations thereof.

In some embodiments, about 50% or more of the metal surface area is covered by the SAM-forming species covalently attached thereto.

In some embodiments, the SAM-forming species uniformly covers the metal surface.

The present invention is also directed to a polymer ink composition consisting essentially of:
a semiconductive or a conductive or semiconductive polymer in a concentration of about 0.1% to about 5% by weight;
a first solvent having a vapor pressure at 25° C. of about 20 mm Hg or less present in a concentration of about 50% or less by weight; and
a second solvent having a vapor pressure greater than the first solvent, wherein the semiconductive or a conductive or semiconductive polymer has a solubility in the second solvent of about 1 mg/mL or more.

In some embodiments, the second solvent is toluene.

Further embodiments, features, and advantages of the present inventions, as well as the structure and operation of the various embodiments of the present invention, are described in detail below with reference to the accompanying drawings.

### BRIEF DESCRIPTION OF THE DRAWINGS

The accompanying drawings, which are incorporated herein and form a part of the specification, illustrate one or more embodiments of the present invention and, together with the description, further serve to explain the principles of the invention and to enable a person skilled in the pertinent art to make and use the invention.

FIGS. 1A, 1B, 1C, 1D and 1E provide schematic cross-sectional representations of patterns that can be prepared by methods of the present invention.

FIG. 2 provides a schematic cross-sectional representation of a pattern on a curved substrate that can be prepared by methods of the present invention.

FIGS. 3A, 3B and 3C provide three-dimensional schematic representations of metal-coated elastomeric stamps according to embodiments of the invention.

FIGS. 4A and 4B provide three-dimensional schematic representations of elastomeric stamps suitable for use with an embodiment of the invention.

FIGS. 5A, 5B and 5C provide three-dimensional schematic representations of a process for preparing a metallized stamp according to an embodiment of the invention.

FIGS. 6 and 7 provide flow diagrams for methods of preparing a metallized elastomeric stamp composition and an elastomeric stamp composition, respectively.

FIG. 8 provides a flow diagram for methods of patterning a substrate according to a method of the present invention.

FIG. 9 provides an optical microscope image of a coated stamp composition prepared by depositing an ink including a conductive or semiconductive polymer onto the surface of an elastomeric stamp. The coated stamp provided in FIG. 9 was prepared by depositing an ink comprising a conductive or semiconductive polymer onto a PDMS stamp that was plasma-treated and then functionalized with a fluorosilane.

FIGS. 10A and 10B provide optical microscope images of coated stamp compositions prepared by depositing an ink including a conductive or semiconductive polymer onto the surface of an elastomeric stamp. The coated stamp provided in FIG. 10A was prepared by depositing an ink comprising a conductive or semiconductive polymer onto a PDMS stamp that was plasma-treated and then functionalized with a fluorosilane. The coated stamp provided in FIG. 10B was prepared by depositing an ink comprising a conductive or semiconductive polymer onto a metallized elastomeric stamp, according to the methods of the present invention.

FIGS. 11A, 11B and 11C provide optical microscope images of patterned substrates. The ink composition comprising a conductive or semiconductive polymer from a PDMS stamp that was plasma-treated was then functionalized with a fluorosilane to a substrate according to the methods of the present invention. The patterned substrate provided in FIG. 11B was prepared by transferring an ink comprising a conductive or semiconductive polymer from a metallized elastomeric stamp to a substrate according to the methods of the present invention. The patterned substrate provided in FIG. 11C was prepared by transferring an ink comprising a conductive or semiconductive polymer from an elastomeric stamp according to the methods of the present invention.

FIGS. 12A and 12B show the distribution of pixel widths and pixel length, respectively, for a conductive or semiconductive polymer patterns printed on a silver-coated substrate.

FIGS. 13A and 13B shows the distribution of pixel spacings in a horizontal direction and a vertical direction, respectively, for a conductive or semiconductive polymer pattern printed on a silver-coated substrate.

FIGS. 14A and 14B provide optical profilometry images, 1400 and 1450, respectively, and line scans, 1410 and 1460, respectively, of a conductive or semiconductive polymer pattern printed on a polyimide substrate (Sample 4) in a vertical direction (FIG. 14A) and in a horizontal direction (FIG. 14B).

FIG. 15 provides a three dimensional optical profilometry image of a conductive or semiconductive polymer pattern printed on a polyimide substrate (Sample 5).

FIGS. 16A-16D provide optical microscope images of representative defects that can be present in patterns prepared by contact printing methods. FIG. 16A provides an example of a missing pixel in an array printed on a silver-coated substrate. FIG. 16B provides an example of a deformed pixel on a silver-coated substrate. FIG. 16C provides an example of a pixel that was double printed on a silver-coated substrate. FIG. 16D provides an example of surface contamination on a polyimide substrate.

FIGS. 17A and 17B provide optical microscope images of conductive or semiconductive polymer patterns on silver-coated substrates prepared using a rigid epoxy stamp and a PDMS stamp having a conformal epoxy coating thereon, respectively.

FIG. 18 provides a summary of several printing experiments performed in accordance with the exemplary embodiments of present invention.

FIGS. 19A and 19B provides optical microscope images of conductive or semiconductive polymer patterns on polyimide substrates, respectively, prepared in accordance with an embodiment of the present invention.

FIG. 20A provides optical microscope images of a conductive or semiconductive polymer pattern on a silver-coated substrate prepared in accordance with an embodiment of the present invention. FIGS. 20B-20C provide profilometry scans along the x-axis and the y-axis, respectively, of the pattern provided in FIG. 20A.

FIGS. 21A-21J show optical microscope images of sample 1: a conductive or semiconductive polymer pattern printed on a silver-coated substrate from (a)-(b) Edge 1; (c)-(d) Edge 2; (e)-(f) Edge 3; (g)-(h) Edge 4, and (i)-(j) the Center of the pattern.

FIGS. 22A-22J show optical microscope images of sample 2: a conductive or semiconductive polymer pattern printed on a silver-coated substrate from (a)-(b) Edge 1; (c)-(d) Edge 2; (e)-(f) Edge 3; (g)-(h) Edge 4, and (i)-(j) the Center of the pattern.

FIGS. 23A-23J show optical microscope images of sample 3: a conductive or semiconductive polymer pattern printed on a silver-coated substrate from (a)-(b) Edge 1; (c)-(d) Edge 2; (e)-(f) Edge 3; (g)-(h) Edge 4, and (i)-(j) the Center of the pattern.

FIGS. 24A-24J show optical microscope images of sample 4: a conductive or semiconductive polymer pattern printed on a polyimide substrate from (a)-(b) Edge 1; (c)-(d) Edge 2; (e)-(f) Edge 3; (g)-(h) Edge 4, and (i)-(j) the Center of the pattern

FIGS. 25A-25J show optical microscope images of sample 5: a conductive or semiconductive polymer pattern printed on a polyimide substrate from (a)-(b) Edge 1; (c)-(d) Edge 2; (e)-(f) Edge 3; (g)-(h) Edge 4, and (i)-(j) the Center of the pattern.

FIGS. 26A-26J show optical microscope images of sample 6: a conductive or semiconductive polymer pattern printed on a polyimide substrate from (a)-(b) Edge 1; (c)-(d) Edge 2; (e)-(f) Edge 3; (g)-(h) Edge 4, and (i)-(j) the Center of the pattern.

FIG. 27 provides a cross-sectional schematic representation of an injection molding apparatus suitable for fabricating a stamp of the present invention.

One or more embodiments of the present invention will now be described with reference to the accompanying drawings. In the drawings, like reference numbers can indicate identical or functionally similar elements. Additionally, the left-most digit(s) of a reference number can identify the drawing in which the reference number first appears.

### DETAILED DESCRIPTION OF THE INVENTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

### Substrates and Patterns

The polymeric patterns prepared by the methods of the present invention are formed on a substrate. Substrates suitable for patterning by the methods of the present invention are not particularly limited by size, composition, or geometry, and include any substrate capable of being contacted with a stamp. For example, the present invention is suitable for patterning planar, non-planar, flat, curved, spherical, rigid, flexible, symmetric, and asymmetric objects and surfaces, and any combination thereof. The methods are also not limited by surface roughness or surface waviness, and are equally applicable to smooth, rough and wavy substrates, and substrates exhibiting heterogeneous surface morphology (i.e., substrates having varying degrees of smoothness, roughness and/or waviness).

As used herein, a substrate is “planar” if, after accounting for random variations in the height of a substrate (e.g., surface roughness, waviness, etc.), points on the surface of the substrate lie in approximately the same plane. Planar substrates can include, but are not limited to, windows, embedded circuits, sheets, and the like. Planar substrates can include flat variants of the above having holes there through.

As used herein, a substrate is “non-planar” if, after accounting for random variations in the height of a substrate (e.g., surface roughness, waviness, etc.), points on the surface of the substrate do not lie in the same plane. Non-planar substrates can include, but are not limited to, gratings, substrates having a tiered geometry, and the like.

Both planar and non-planar substrates can be flat or curved. As used herein, a substrate is “curved” when the radius of curvature of a substrate is non-zero over a distance of 100 μm or more, or 1 mm or more, across the surface of a substrate. Flat substrates generally do not have a radius of curvature.

As used herein, a substrate is “rigid” when the plane, curvature, or geometry of the substrate cannot be easily distorted. Rigid substrates can undergo temperature-induced distortions due to thermal expansion, or become flexible at temperatures above a glass transition, and the like.

As used herein, a substrate is “flexible” when it can be reversibly moved between flat and curved geometries. Flexible substrates include, but are not limited to, polymers (e.g., plastics), woven fibers, thin films, metal foils, composites thereof, laminates thereof, and combinations thereof. In some embodiments, a flexible substrate can be patterned using the methods of the present invention in a reel-to-reel manner.

Substrates for use with the present invention are not particularly limited by composition. Substrates suitable for use with the present invention include materials chosen from metals, crystalline materials (e.g., monocrystalline, polycrystalline, and partially crystalline materials), amorphous materials, conductors, semiconductors, insulators, optics, painted substrates, fibers, glasses, ceramics, zeolites, plastics, thermosetting and thermoplastic materials (e.g., optionally doped: polyacrylates, polycarbonates, polyurethanes, polystyrenes, cellulosic polymers, polyolefins, polyamides, polyimides, resins, polyesters, polyphenylenes, and the like), films, thin films, foils, plastics, polymers, wood, fibers, minerals, biomaterials, living tissue, bone, alloys thereof, composites thereof, laminates thereof, and any other combinations thereof. In some embodiments, a material is selected from a doped and/or a porous variant of any of the above materials.

In some embodiments, at least a portion of a substrate is conductive or semiconductive. As used herein, “conductive” and “semiconductive” materials include species, compounds, polymers, films, coatings, substrates, and the like capable of transporting or carrying electrical charge. Generally, the charge transport properties of a semiconductive material can be modified based upon an external stimulus such as, but not limited to, an electrical field, a magnetic field, a temperature change, a pressure change, exposure to radiation, and combinations thereof. In some embodiments, a conductive or semiconductive material has an electron or hole mobility of about 10⁻⁶ cm²/V·s or more, about 10⁻⁵ cm²/V·s or more, about 10⁻⁴ cm²/V·s or more, about 10⁻³ cm²/V·s or more, about 0.01 cm²/V·s or more, or about 0.1 cm²/V·s or more. Electrically conductive and semiconductive materials include, but are not limited to, metals, alloys, thin films, crystalline materials, amorphous materials, polymers, laminates, foils, plastics, and combinations thereof.

As used herein, a “dielectric” refers to species, compounds, polymers, films, coatings, substrates, and the like that are resistant to the movement or transfer of electrical charge. In some embodiments, a dielectric has a dielectric constant, ρ, of about 1.5 to about 8, about 1.7 to about 5, about 1.8 to about 4, about 1.9 to about 3, about 2 to about 2.7, about 2.1 to about 2.5, about 8 to about 90, about 15 to about 85, about 20 to about 80, about 25 to about 75, or about 30 to about 70. Dielectrics suitable for use with the present invention include, but are not limited to, plastics, polymers (e.g., polydimethylsiloxane, a silsesquioxane, a polyethylene, a polypropylene, and the like), metal oxides, metal carbides, metal nitrides, ceramics (e.g., silicon carbide, hydrogenated silicon carbide, silicon nitride, silicon carbonitride, silicon oxynitride, silicon oxycarbide, and combinations thereof), glasses (e.g., SiO₂, borosilicate glass, borophosphorosilicate glass, organosilicate glass, etc., and fluorinated and porous variants thereof), zeolites, minerals, biomaterials, living tissue, bone, monomeric precursors thereof, particles thereof, and combinations thereof.

Plastics suitable for use with the present invention include those materials disclosed, for example but not limitation, in Plastics Materials and Processes: A Concise Encyclopedia, Harper, C. A. and Petrie, E. M., John Wiley and Sons, Hoboken, N.J. (2003) and Plastics for Engineers: Materials, Properties, Applications, Domininghaus, H., Oxford University Press, USA (1993), which are incorporated herein by reference in their entirety.

In some embodiments, a substrate comprises a first area including a conductive or semiconductive material and a second area including a dielectric or insulating material. The substrate can be flat, or include topographical features such as thin-film transistors, and the like. In some embodiments, the methods described herein are particularly suitable for blanket depositing a conductive or semiconductive polymer pattern on an array of thin-film transistors. For example, varying the stamp, ink, or patterning conditions can enable the formation of patterns having regions of blanket deposition on topographical substrates; gap-filling patterns on topographical substrates, trenches and the like; or conformal patterns that coat topographical substrates, depending on the substrate and device being patterned.

Exemplary substrates on which a polymeric pattern can be formed by the present invention include, but are not limited to, windows; mirrors; optical elements (e.g, optical elements for use in eyeglasses, cameras, binoculars, telescopes, and the like); watch crystals; holograms; optical filters; data storage devices (e.g., compact discs, DVD discs, CD-ROM discs, and the like); flat panel electronic displays (e.g., LCDs, plasma displays, and the like); touch-screen displays (such as those of computer touch screens and personal data assistants); solar cells; photovoltaics; LEDs; lighting; flexible electronics; flexible displays (e.g., electronic paper and electronic books); cellular phones; global positioning systems; calculators; diagnostics; sensors; resist layers; biological interfaces; antireflection coatings; graphic articles (e.g., signage); batteries; fuel cells; antennas; motor vehicles; artwork (e.g., sculptures, paintings, lithographs, and the like); jewelry; and combinations thereof.

The present invention contemplates optimizing the performance, efficiency, cost, and speed of the process steps by selecting inks, stamps and substrates that are compatible with one another. For example, in some embodiments, a substrate or a stamp can be selected based upon its optical transmission properties, thermal conductivity, electrical conductivity, and combinations thereof.

In some embodiments, at least a portion of a substrate is transparent, translucent, or opaque to at least one type of radiation suitable for initiating a reaction of an ink on the substrate (e.g., visible, UV, infrared and/or microwave radiation). For example, a substrate transparent to ultraviolet light can be used with an ink whose reaction can be initiated by ultraviolet light, which permits the reaction of an ink on the front-surface of a substrate to be initiated by illuminating a back-surface of the substrate with ultraviolet light.

In some embodiments, the substrate is pre-treated prior to patterning. As used herein, “pre-treating the substrate” refers to chemically or physically modifying a substrate prior to applying or reacting an ink. Pre-treating can include, but is not limited to, cleaning, oxidizing, reducing, derivatizing, functionalizing, as well as exposing a substrate to: a reactive gas, an oxidizing plasma, a reducing plasma, a thermal energy, an ultraviolet radiation, and combinations thereof.

In some embodiments, pre-treating the substrate comprises depositing a contact layer onto the substrate. As used herein, a “contact layer” refers to a thin film, self-assembled monolayer, and the like, and combinations thereof capable of increasing an adhesive force between the substrate and the ink. In some embodiments, the depositing a contact layer comprises depositing a self-assembled monolayer. In some embodiments, the depositing a self-assembled monolayer comprises depositing a self-assembled monolayer-forming monomer comprising an aromatic substituent (e.g., 4-phenylbutyltrichlorosilane, phenyltrichlorosilane, etc.).

Not being bound by any particular theory, pre-treating a substrate can increase or decrease an adhesive interaction between an ink and a substrate. For example, derivatizing a substrate with a polar functional group (e.g., oxidizing a surface of the substrate) can promote the wetting of a substrate by a hydrophilic ink and deter surface wetting by a hydrophobic ink. In some embodiments, pre-treating a substrate can ensure uniform patterning, and facilitate the formation of patterns having a lateral dimension of about 100 μm or less.

The methods of the present invention are useful for creating conductive patterns on substrates. As used herein, a “pattern” refers to a feature deposited onto a substrate. A pattern is contiguous with, and can be distinguished from, the areas of the substrate surrounding the pattern. For example, a pattern can be distinguished from the areas of the substrate surrounding the pattern based upon the topography of the pattern on the substrate, the composition of the pattern in comparison to the substrate, or another property of the pattern that differs from the areas of the substrate surrounding the pattern.

Patterns can be defined by their physical dimensions. All patterns have at least one lateral dimension. As used herein, a “lateral dimension” refers to a dimension of a pattern that lies in the plane of a flat surface, or along the curvature of a non-flat surface. One or more lateral dimensions of a pattern define, or can be used to define, the area of a substrate that a pattern occupies. Typical lateral dimensions of patterns include, but are not limited to, length, width, radius, diameter, and combinations thereof.

All patterns also have at least one vertical dimension that can be described by a vector that lies out of the plane of the substrate. As used herein, a “vertical dimension” or “elevation” refers to the largest vertical distance between the height of the surface of a substrate and the highest point on a pattern. For flat substrates, the elevation of a pattern refers to its highest point of the pattern relative to the plane of the substrate. In some embodiments, patterns prepared by the present invention have a uniform elevation across the surface of the pattern.

A pattern produced by the methods of the present invention has lateral and vertical dimensions that are typically defined in units of length, such as angstroms (Å), nanometers (nm), microns (μm), millimeters (mm), centimeters (cm), etc.

When a substrate is flat, a lateral dimension of a pattern is the magnitude of a vector between two points located on opposite sides of a pattern, wherein the two points are in a plane of the substrate, and wherein the vector is parallel to a plane of the substrate. In some embodiments, two points used to determine a lateral dimension of a symmetric pattern also lie on a mirror plane of the symmetric pattern. A lateral dimension of an asymmetric pattern can be determined by aligning a vector orthogonally to at least one edge of the pattern.

In some embodiments, a pattern produced by the methods of the present invention has at least one lateral dimension of about 40 nm to about 100 μm. In some embodiments, a pattern produced by the methods of the present invention has at least one lateral dimension of about 40 nm or less, about 50 nm or less, 80 nm or less, about 100 nm or less, about 500 nm or less, about 1 μm or less, about 2 μm or less, about 5 μm or less, about 10 μm or less, about 15 μm or less, about 20 μm or less, about 25 μm or less, about 30 μm or less, about 40 μm or less, or about 50 μm or less, about 60 μm or less, about 80 μm or less, or about 100 μm or less, or any range there between.

In some embodiments, a pattern produced by the methods of the present invention has an elevation of about 5 nm to about 10 μm. In some embodiments, a pattern produced by the methods of the present invention has a minimum elevation of about 5 nm or more, about 10 nm or more, about 20 nm or more, about 50 nm or more, about 75 nm or more, about 100 nm or more, about 125 nm or more, about 150 nm or more, about 175 nm or more, or about 200 nm. In some embodiments, a pattern produced by the methods of the present invention has a maximum elevation of about 10 μm or less, about 8 μm or less, about 6 μm or less, about 5 μm or less, about 4 μm or less, about 3 μm or less, about 2 μm or less, about 1 μm or less, about 800 nm or less, about 600 nm or less, about 500 nm or less, about 400 nm or less, about 350 nm or less, about 300 nm or less, about 250 nm or less, about 200 nm or less, about 175 nm or less, or about 150 nm or less.

In some embodiments, a pattern produced by the methods of the present invention has an aspect ratio (i.e., a ratio of the elevation distance to a lateral dimension) of about 1,000:1 to about 1:100,000, about 100:1 to about 1:100, about 80:1 to about 1:80, about 50:1 to about 1:50, about 20:1 to about 1:20, about 15:1 to about 1:15, about 10:1 to about 1:10, about 8:1 to about 1:8, about 5:1 to about 1:5, about 2:1 to about 1:2, or about 1:1.

A lateral and/or vertical dimension of a pattern can be determined using an analytical method that can measure surface topography such as, for example, scanning mode atomic force microscopy (AFM) or profilometry. Patterns can also be characterized based upon a property such as, but not limited to, conductivity, resistivity, density, permeability, porosity, hardness, and combinations thereof using, for example, scanning probe microscopy. In some embodiments, a pattern can be differentiated from the surrounding surface area using, for example, scanning electron microscopy or transmission electron microscopy.

In preferable embodiments of the present invention a pattern has a different composition or morphology compared to the surrounding surface area. Thus, surface analytical methods can be employed to determine both the composition of the pattern, as well as the lateral dimension of the pattern. Analytical methods suitable for determining the composition and lateral and vertical dimensions of a pattern include, but are not limited to, Auger electron spectroscopy, energy dispersive x-ray spectroscopy, micro-Fourier transform infrared spectroscopy, particle induced x-ray emission, Raman spectroscopy, x-ray diffraction, x-ray fluorescence, laser ablation inductively coupled plasma mass spectrometry, Rutherford backscattering spectrometry/Hydrogen forward scattering, secondary ion mass spectrometry, time-of-flight secondary ion mass spectrometry, x-ray photoelectron spectroscopy, and combinations thereof.

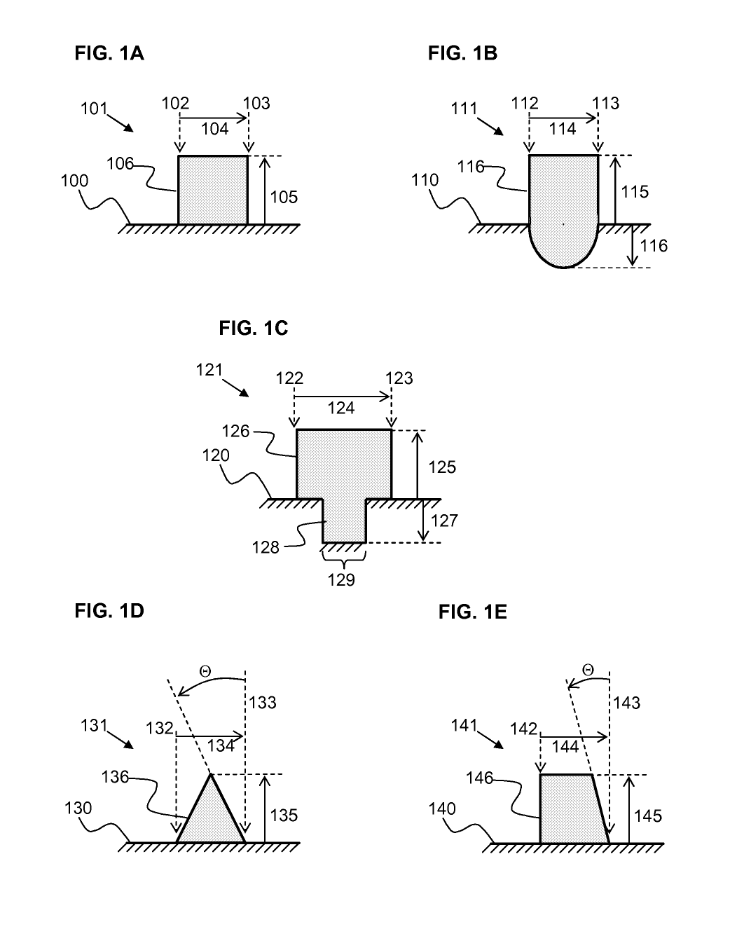

When the surrounding substrate is planar, a lateral dimension of a pattern is the magnitude of a vector between two points located on opposite sides of the pattern, wherein the two points are in the plane of the substrate, and wherein the vector is parallel to the plane of the substrate. In some embodiments, two points used to determine a lateral dimension of a symmetric pattern also lie on a mirror plane of the symmetric pattern. In some embodiments, a lateral dimension of an asymmetric pattern can be determined by aligning the vector orthogonally to at least one edge of the pattern. For example, in FIGS. 1A-1E points lying in the plane of the substrate and on opposite sides of the patterns, 101, 111, 121, 131 and 141, are shown by dashed arrows, 102 and 103; 112 and 113; 122 and 123; 132 and 133; and 142 and 143, respectively. The lateral dimension of these patterns is the magnitude of the vectors 104, 114, 124, 134 and 144, respectively.

A vertical dimension of a pattern is the magnitude of a vector orthogonal to the substrate between a point in the plane of the substrate and a point at the top-most height of the pattern. For example, in FIGS. 1A-1E the vertical dimensions of the patterns are shown by the magnitude of the vectors 105, 115, 125, 135 and 145 respectively. As used herein, a “sidewall” refers to any surface of a pattern that is not substantially planar to a plane oriented parallel to the substrate. For example, in FIGS. 1A-1E patterns 101, 111, 121, 131 and 141 are shown having sidewalls 106, 116, 126, 136 and 146, respectively. In those embodiments in which the sidewall of a pattern is orthogonal to a plane oriented parallel to the substrate, the height of the sidewall is equal to the vertical dimension of the pattern.

While the pattern illustrated schematically in FIGS. 1A-1E show that the pattern 101, 111, 121, 131 and 141 have a composition that differs from the surrounding substrate, the present invention encompasses pattern having both the same and a different chemical composition compared to the substrate. For example, a pattern can be formed by a combination of an additive process (e.g., deposition), and a reactive process (e.g., reaction between the ink and the substrate), and combinations thereof.

In some embodiments, a pattern can provide a “gap-filling portion,” which as used herein refers to a pattern having regions both above and below the plane of a substrate in which the pattern completely covers a gap. Referring to FIG. 1C, the pattern, 121, comprises a portion lying above the plane of the substrate having an elevation, 125, and a second portion lying below the plane of the substrate having a penetration distance, 127. The portion of the substrate comprising a gap, 129, has been filled by the pattern and the edges of the gap have been covered by the pattern (i.e., the lateral dimension, 124, is wider than the gap, 129). As used herein, the gap region can include a hole, a trench, an area between adjacent features on the substrate, and the like.

In some embodiments, a pattern has an “angled” sidewall. As used herein, an “angled sidewall” refers to a sidewall that is not orthogonal to a plane oriented parallel to the substrate. The sidewall angle is equal to the angle formed between a vector orthogonal to the surface that intersects an edge of a pattern and a vector intersecting the edge of the pattern at the same point that is parallel to the surface of the sidewall. An orthogonal sidewall has a sidewall angle of 0°. For example, the sidewall angle in FIGS. 1D and 1E of the pattern 131 and 141 is shown as Θ. In some embodiments, a pattern on a substrate formed by the methods of the present invention has a sidewall angle of about 80° to about −50°, about 80° to about −30°, about 80° to about −10°, or about 80° to about 0°.

A substrate is “curved” when the radius of curvature of a substrate is non-zero over a distance on the substrate of 1 mm or more, or over a distance on the substrate of 10 mm or more. For a curved substrate, a lateral dimension of a pattern is defined as the magnitude of a segment of the circumference of a circle connecting two points on opposite sides of a pattern, wherein the circle has a radius equal to the radius of curvature of the substrate. A lateral dimension of a curved substrate having multiple or undulating curvature, or waviness, can be determined by summing the magnitude of segments from multiple circles.

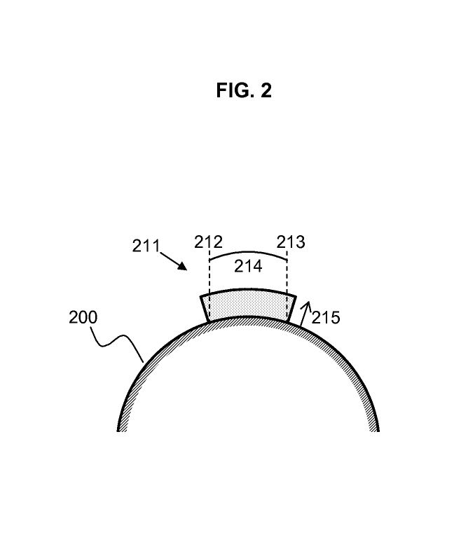

FIG. 2 displays a cross-sectional schematic of a curved substrate, 200, having a pattern, 211, thereon. A lateral dimension of the pattern, 211, is equivalent to the length of the line segment, 214, which can connect points 212 and 213. Pattern 211 has a vertical dimension shown by the magnitude of vector 215.

In some embodiments, a substrate can be patterned to form a conductive grating thereon. Gratings prepared by the present invention can be utilized in the optical arts, or for other applications requiring a regularly patterned substrate or surface.

### Stamps

The soft lithography processes for use with the present invention employ a “stamp.” As used herein, a “stamp” refers to a three-dimensional object having a surface including one protrusion thereon, the protrusion being contiguous with and defining a pattern on the surface of the stamp. An ink is transferred from a surface of the protrusion upon contact with a substrate. Thus, a pattern produced on a substrate by the methods of the present invention is generally formed as a mirror image of the protrusion pattern.

The stamps comprise an elastomer, which refers to a material that can flex and undergo deformation (i.e., compression, torsional flexing, extension, and the like in response to an external force). Elastomers suitable for use in stamps of the present invention include, but are not limited to, poly(dialkylsiloxanes) (e.g., poly(dimethylsiloxane) (“PDMS”)), poly(silsesquioxane), polyisoprene, polybutadiene, poly(acrylamide), poly(butylstyrene), polychloroprene, acryloxy elastomers, fluorinated and perfluorinated elastomers (e.g., TEFLON®, E. I. DuPont de Nemours & Co., Wilmington, Del.), copolymers thereof, and combinations thereof. Other materials suitable for use in the stamps, and methods to prepare stamps suitable for use with the present invention are disclosed in U.S. Pat. Nos. 5,512,131; 5,900,160; 6,180,239 and 6,776,094, all of which are incorporated herein by reference in their entirety.

Stamps having a topographical pattern and a flexible or elastomeric morphology can be prepared from a master stamp comprising a topographical pattern in the surface of a rigid or semi-rigid material. A polymer precursor is applied to the master, cured (e.g., by heating or exposure to radiation), and the resulting stamp is separated from the master.

Stamps for use with the present invention are not particularly limited by geometry, and can be flat, curved, smooth, rough, wavy, and combinations thereof. The thickness of the stamp can be homogeneous or varied. In some embodiments, a stamp has a three dimensional shape designed to conformally contact a substrate. In some embodiments, the three-dimensional shape of a stamp is non-planar or curved and is specifically formed in the shape of a substrate to be patterned. A stamp can comprise multiple patterned surfaces having the same, or a different pattern. For example, a stamp can comprise a cylinder wherein one or more protrusions on a curved face of the cylinder define a pattern. An ink can be applied to a cylindrical stamp as it rotates, and as the cylindrical stamp is rolled across a surface, the pattern is repeated. For stamps having multiple patterned surfaces: cleaning, applying, contacting, removing, and reacting steps can occur in parallel on different surfaces of the same stamp.

The methods of the present invention involve applying an ink to a surface of the stamp (e.g., a face of a protrusion on the stamp), and transferring the ink from the protrusion to a substrate. The properties of the stamp can be selected to optimize either of the applying and the contacting processes.

Not being bound by any particular theory, both the applying and the contacting involve surface interactions between the ink and the stamp and the ink and the substrate. In the former, applying the ink uniformly to the stamp requires that the ink be able to uniformly wet at least the face of the protrusion on the stamp surface. Usually, stamps comprising materials having very low surface free energy (e.g., a surface free energy less than about 15 ergs/cm²) are unsuitable for use with the present invention due to difficulty applying a uniform ink coating to the stamp composition, and in particular, difficulty applying a uniform ink coating to a face of a protrusion. As used herein, a “surface free energy” generally refers to the work required to increase the area of a substance by one unit area and can be described in units of ergs/cm². In some embodiments, a surface free energy of an elastomer can be proportional to a contact angle form by a drop of water, or another fluid, on the surface of the elastomer, which relates to the wettability of the surface of an elastomer. In most cases, as surface free energy increases, a surface becomes more readily wetted by an ink, and generally, adhesive forces between the surface and the ink increase.

On the other hand, after a stamp has been uniformly coated with an ink, the contacting of the ink from the stamp to a substrate is also driven, at least in part, by surface interactions. Thus, stamps comprising materials having a surface free energy equal to or greater than a surface free energy of a substrate can result in non-uniform transfer of the ink to the substrate. Therefore, stamp materials having very high surface free energy (e.g., a surface free energy greater than about 35 ergs/cm²) can also be unsuitable for use with the present invention. Thus, In some embodiments, at least a portion of a stamp surface (e.g., the face of the at least one protrusion) has a surface free energy of about 15 ergs/cm² to about 35 ergs/cm², about 18 ergs/cm² to about 32 ergs/cm², about 20 ergs/cm² to about 30 ergs/cm², about 24 ergs/cm² to about 30 ergs/cm², or about 25 ergs/cm² to about 30 ergs/cm².

Additionally, in some embodiments, at least a portion of a stamp surface (e.g., the face of the at least one protrusion) has a surface free energy at least about 10% less, at least about 20% less, at least about 30% less, at least about 40% less, at least about 50% less, at least about 75% less, or at least about 90% less than a surface free energy of the substrate.

In some embodiments, the surface free energy of a stamp can be controlled by a pre-treatment process. Pre-treatment processes suitable for use with the present invention include, but are not limited to, cleaning, oxidizing, reducing, derivatizing, and functionalizing, abrading, roughening, as well as exposing a stamp surface to: a reactive gas, a plasma, a thermal energy, an ultraviolet radiation, and combinations thereof. Pre-treating processes can chemically modify the surface of a stamp in a uniform manner (whereby an entire surface of a stamp is pre-treated) or in a localized manner (whereby a limited region of a stamp surface is pre-treated). Surface roughening can be performed by mechanical roughening, exposure to an etchant, and combinations thereof.

The pre-treating can include forming a thin layer of a reagent or material on a surface of a stamp, or chemically modifying a surface of a stamp to assist with either of applying a uniform ink coating to a stamp or transferring an ink from the at least one protrusion to a substrate. For example, a stamp comprising a material having a low surface free energy (i.e., about 15 ergs/cm² or less) can exhibit improved uniformity during an applying process by pre-treating at least a portion of the stamp surface to increase its surface free energy. Similarly, a stamp comprising a material having a high surface free energy (i.e., about 35 ergs/cm² or more) can exhibit improved uniformity during a transferring process by pre-treating at least a portion of the stamp surface to decrease its surface free energy.

In addition, the intensity of a pre-treatment can be varied to control the density of surface modification. For example, a pre-treating can modify about 10% or more, about 25% or more, about 50% or more, about 75% or more, about 90% or more, or about 100% of the surface area of a stamp, wherein the surface modification can be localized, uniform, and combinations thereof. In some embodiments, the pre-treating comprises depositing a conformal layer on a stamp surface or conformally modifying a stamp surface.

In some embodiments, an area of a stamp surface is modified to increase its surface free energy, and a second area of a stamp surface is modified to decrease its surface free energy. For example, in some embodiments, the face of a protrusion is pre-treated to increase the surface free energy, and a sidewall of a protrusion is pre-treated to decrease the surface free energy. In some embodiments, both the face of a protrusion and a surface of the stamp are pre-treated to increase the surface free energy, and a sidewall of a protrusion is pre-treated to decrease the surface free energy.

In some embodiments, the pre-treating comprises derivatizing at least a portion of a stamp surface. Non-limiting examples of reagents suitable for reducing a surface free energy of a stamp surface include, but are not limited to, a fluorine plasma (i.e., a plasma comprising at least one of F₂, NF₃, SF₆, CF₄, C₂F₂, and the like), a fluorinating solvent, a (C₄-C₂₀)alkyl-trihalosilane, a perfluorinated or partially fluorinated (C₄-C₂₀)alkyl-trihalosilane, a (C₄-C₂₀)alkyl-trialkoxysilane, a perfluorinated or partially fluorinated (C₄-C₂₀)alkyl-trialkoxysilane, and combinations thereof. Not being bound by any particular theory, the surface free energy of a stamp can be decreased by fluorination of the stamp surface, which can involve the formation of C—F bonds, Si—F bonds, metal-F bonds, and combinations thereof. Moreover, fluorination can be used to prevent an ink from penetrating into the body of a stamp. For example, derivatizing the surface of a stamp with fluorine groups or a fluorocarbon moiety can reduce absorption of an ink by a stamp and facilitate transferring the ink to a substrate.

Non-limiting examples of reagents suitable for increasing a surface free energy of a stamp surface include, but are not limited to, a metal, a metal oxide, a polyacrylate, a polyurethane, an epoxy, and combinations thereof. In some embodiments, a reagent suitable for modifying a surface free energy of a stamp surface is chosen from: (tridecafluoro-1,1,2,2-tetrahydrooctyl)trichlorosilane, DYMAX® OP-30 epoxy (Dymax Corp., Torrington, Conn.), and combinations thereof.

In traditional microcontact printing processes wherein a self-assembled monolayer patterned is formed on a substrate, a solvent present in an ink is usually removed (e.g., by evaporation) after the ink has been applied to a stamp. However, a solvent can also penetrate into a stamp because of the porous structure of most elastomers. Absorption of a solvent by a stamp can result in degradation of the stamp, which can increase materials costs, as well as stamp swelling, which can result in the loss of feature size and pattern misalignment. Therefore, the development of stamps that minimize solvent absorption has been a previous focus of efforts in the microcontact printing field. Conversely, as discussed herein, the presence of a solvent during both the applying of an ink to a stamp and the contacting of the ink-coated stamp with a substrate can be critical for performing microcontact printing processes utilizing an ink comprising a conductive or semiconductive polymer. Thus, in some embodiments, the composition and/or structure of a stamp can be tailored to control the absorption of a solvent by the stamp.

The present invention is directed to an elastomeric stamp composition comprising:
an elastomeric stamp having a body and a surface including at least one protrusion thereon, the protrusion having face and sidewall portions, and the protrusion being contiguous with and defining a pattern on the surface of the stamp, the face comprising a first elastomer and the body comprising a second elastomer, wherein the first elastomer has a modulus at least about 20% greater than the second elastomer;
a first solvent having a vapor pressure at 25° C. of about 20 mm Hg or less present in at least the body in a concentration of about 30% by volume, wherein the first solvent is in fluid communication with the face portion; and
an ink comprising a conductive or semiconductive polymer and a solvent discontinuously coating the stamp surface and the at least one protrusion, wherein the ink uniformly coats the face of the at least one protrusion, wherein the sidewall portion is substantially free from the ink, and wherein the solvent present in the body continuously wets the ink on at least the face.

The presence and concentration of a first solvent in the body portion of the stamp can be controlled by the thickness of the stamp. Stamps for use with the present invention can have a thickness of the body portion of the stamp of about 300 μm to about 10 mm, about 400 μm to about 10 mm, about 500 μm to about 10 mm, about 500 μm to about 5 mm, about 600 μm to about 2.5 mm, about 700 μm to about 2 mm, or about 750 μm to about 1.5 mm.

In some embodiments, an elastomeric stamp composition further comprises a rigid backing layer attached to the stamp that is substantially parallel or concentric with an outer surface of the stamp. Materials suitable for use as rigid or semi-rigid backing layers include, but are not limited to: metals, glasses, fibers, composites thereof, a mesh thereof, and combinations thereof. The rigid or semi-rigid backing layer can be adhered to the stamp after it is prepared, or the backing layer can be adhered to the stamp during a curing step. Suitable methods for adhering the backing layer to a stamp body include, but are not limited to, ozone treating at least one of the backing layer or the stamp body, plasma treating at least one of the backing layer or the stamp body, corona treating at least one of the backing layer or the stamp body, applying an adhesive layer to at least one of the backing layer or the stamp body, and the like, and combinations thereof.

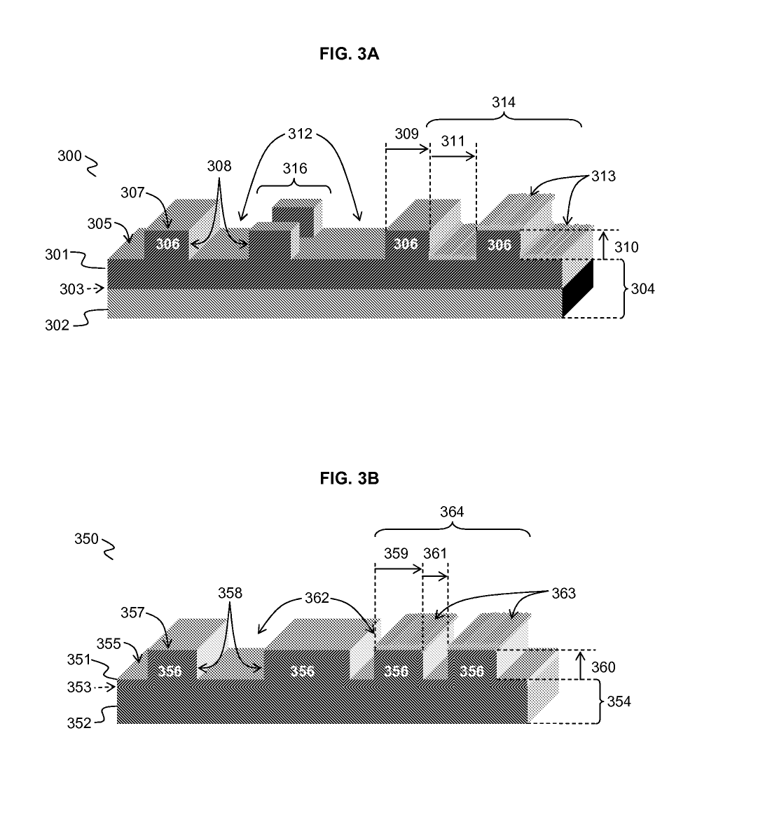

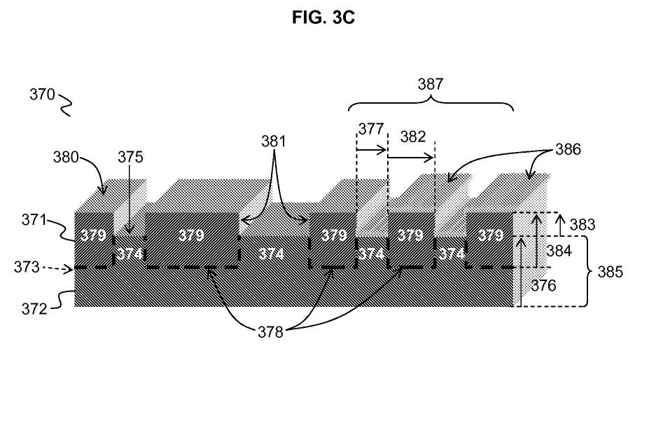

FIGS. 3A and 3B provide three-dimensional schematic representations of elastomeric stamps of the present invention comprising a first elastomer and a second elastomer, wherein the first elastomer coats the second elastomer to form an outer surface thereon, the outer surface including at least one protrusion thereon, the protrusion being contiguous with and defining a pattern on the surface of the stamp.

Referring to FIG. 3A, an elastomeric stamp, 300, is provided comprising a first elastomer, 301, and a second elastomer, 302. The second elastomer and first elastomer form an interface, 303. The stamp comprises a body portion, 304, that includes any portion of the stamp below that stamp surface, 305. The surface of the stamp, 305, includes at least one protrusion, 306 and 316, thereon, which forms a pattern on the surface of the stamp. The pattern can comprise any topography, including by not limited to protrusions forming lines, 306, and/or protrusions forming isolated features, 316, and combinations thereof. The at least one protrusion, 306 and 316, include a face portion, 307, and a sidewall portion, 308, and has a lateral dimension, 309, a vertical dimension, 310, and a spacing between adjacent protrusions, 311. Any and/or all of these dimensions, 309, 310 and 311, can be varied across the surface of the stamp, 305. The surface of the stamp, 305, is exposed in regions, 312, surrounding and/or between the at least one protrusion.

In some embodiments, the second elastomer includes a surface having at least one protrusion thereon wherein the first elastomer coats at least a portion of the second elastomer. Referring to FIG. 3B, an elastomeric stamp, 350, is provided comprising a first elastomer, 351, and a second elastomer, 352. The second elastomer and the first elastomer form an interface, 353. The stamp comprises a body portion, 354, that includes any portion of the stamp below the stamp surface, 355. The surface of the stamp, 355, includes at least one protrusion thereon, 356, in which the shape of the at least one protrusion is formed substantially by the three-dimensional shape of the second elastomer, 352. The first elastomer, 351, coats at least a portion of the second elastomer, 352. In some embodiments, the first elastomer conformally coats the second elastomer. The at least one protrusion, 356, includes a face portion, 357, and a sidewall portion, 358, and has a lateral dimension, 359, a vertical dimension, 360, and a spacing between adjacent protrusions, 361. Any and/or all of these dimensions, 359, 360 and 361, can be varied across the surface of the stamp, 355. The surface of the stamp, 355, is exposed in regions, 362, between protrusions. In some embodiments, the first elastomer coats only the face of the at least one protrusion, 357, only the sidewalls of the at least one protrusion, 358, or only the spacing region between adjacent protrusions, 359.

As shown in FIGS. 3A and 3B, in some embodiments, the second elastomer provides a backing layer to the first elastomer. In some embodiments, such as the stamp of FIG. 3B, the backing layer can comprise topographical variations. In such embodiments, a surface comprising the first elastomer is the only surface that can be contacted with a substrate (i.e., the second elastomer does not make contact with a substrate).

FIG. 3C provides a further embodiment of the present invention. Referring to FIG. 3C, a stamp, 370, comprises a second elastomer, 372, having a surface, 373, including at least one protrusion, 374, thereon. The at least one protrusion, 374, includes a face, 375, having vertical dimension, 376, and a lateral dimension, 377. The stamp further comprises a first elastomer, 371, which fills a space, 378, formed by adjacent protrusions, 374, on the second elastomer. Thus, the first elastomer, 371, forms at least one second protrusion, 379, having a face portion, 380, and a sidewall portion, 381. The protrusion comprising the first elastomer, 379, has a lateral dimension, 382, and a vertical dimension, 383, determined by the thickness, 384, of the first elastomer. In a preferred embodiment the thickness of the first elastomer, 384, and the vertical dimension, 383, of the protrusion, 379, is such that the height of the protrusion is greater than the height of the second elastomer's surface, 375. The body portion of the stamp, 385, comprises both the second elastomer and a portion of the first elastomer. Thus, in some embodiments a stamp comprises a second elastomer including a surface having at least one protrusion thereon, the face of said first protrusion forming a surface of the stamp, and a second protrusion comprising a first elastomer, wherein the second protrusion is adjacent to and has a vertical dimension greater than said first protrusion.

Referring to FIGS. 3A, 3B and 3C, in some embodiments, an ink comprising a conductive or semiconductive polymer and a solvent, 313, 363 and 386, respectively, discontinuously coats, 314, 364, and 386, respectively, the stamp, 300, 350 and 370, respectively. As used herein, “discontinuously coats” refers to a non-conformal coating on a stamp. Referring to FIG. 3B, in some embodiments, a discontinuous coating, 364, is provided wherein the coating is applied only to the face of the at least one protrusion, 357. Referring to FIGS. 3A and 3C, in some embodiments, a discontinuous coating, 314 and 387, respectively, is provided wherein the coating is applied to the face of the at least one protrusion, 357 and 380, respectively, and the surface of the stamp, 305 and 375, respectively, and at least a portion of the at least one protrusion, 306 and 379, respectively, such as the sidewall portion, 308 and 381, respectively, is not coated by the ink. In some embodiments, the sidewall portion, 308 and 381, respectively, is substantially free from an ink. As used herein, a “sidewall portion substantially free from an ink” refers to about 50% or more, about 60% or more, about 70% or more, about 80% or more, or about 90% or more of the surface area of a sidewall being uncoated by an ink.

In some embodiments, the first and second elastomers are chosen by a property such as, but not limited to, a modulus, a hardness, a density, a surface free energy, a swellability (i.e., a percentage increase in volume upon exposure to a solvent), an elasticity, and combinations thereof that are different.

In some embodiments, the first elastomer has a modulus greater than the second elastomer. As used herein, a “modulus” refers to a mechanical measurement related to the stiffness, hardness, elasticity, shear strength, and combinations thereof, of an elastomer and/or composition for use with the present invention. For example, while Young's modulus cannot be strictly determined for elastomers due to the nonlinear nature of the stress-strain relationship for these materials, a modulus can be found at a particular strain, such as a low strain. Thus, in some embodiments, a “modulus” can refer to a Young's modulus, E, of an elastomer and/or composition for use with the present invention, under a specific strain, which is given by equation (1):

$$E = \frac{{FL}_{0}}{{A}_{0} Δ L} \qquad ( 1 )$$

wherein F is a force applied to an elastomer and/or composition, A₀ is the original cross-sectional area through which the force is applied, L₀ is the original length of the elastomer and/or composition, and ΔL is the amount by which the length of the elastomer and/or composition changes in response to the applied force.

In some embodiments, a “modulus” can refer to a bulk modulus, K, of an elastomer and/or composition, which is given by equation (2):

$$K = - V \frac{\partial P}{\partial V} \qquad ( 2 )$$

wherein V is the volume of an elastomer and/or composition, P is a pressure applied to the elastomer and/or composition, and ∂P/∂V denotes the partial derivative of pressure with respect to volume. In some embodiments, the inverse of the bulk modulus relates directly to the compressibility of an elastomer and/or composition.

In some embodiments, a “modulus” can refer to a shear modulus, G, of an elastomer and/or composition, which is given by equation (3):

$$G = \frac{Fh}{Δ xA} \qquad ( 3 )$$

wherein F is an applied force acting upon an area, A, of an elastomer and/or composition having an initial length, h, and undergoes a transverse displacement, Δx, in response to the applied force.

Any of definitions provided herein for modulus (i.e., a Young's modulus, a bulk modulus, a shear modulus, and/or a hardness) of an elastomer are suitable for use in determining appropriate combinations of elastomers for use with the present invention. In some embodiments, a material having an asymmetric modulus can be used. In such cases, any value of modulus for a material can be utilized to make relevant comparisons between different materials. Generally, the modulus of various elastomers should be made under similar conditions of pressure, temperature, and strain to make relevant comparisons. Table 1 provides Young's modulus values of a non-limiting set of elastomers, polymers and other materials suitable for use with the present invention.

TABLE 1
The Young's modulus of various elastomers, polymers, and other
materials suitable for use with the present invention.

| | Young's Modulus |
|---|---|
| Composition | (E, in MPa) |
| Low-density PDMS (small strain) | 0.36-0.87 |
| High-density PDMS (small strain) | 3.4 |
| Rubber (small strain) | 10-100 |
| Low-density polyethylene | 200 |
| High-density polyethylene | 1,400 |
| Poly(tetrafluoroethylene) | 500 |
| Polypropylene | 1,500-2,000 |
| Polyethylene terephthalate | 2,000-2,500 |
| Parylene | 3,100 |
| Polystyrene | 3,000-3,500 |
| Nylon | 3,000-7,000 |

In some embodiments, a flexible stamp for use with the present invention includes at least one surface having a Young's modulus of about 0.5 MPa to about 150 MPa, about 0.5 MPa to about 100 MPa, about 1 MPa to about 80 MPa, about 1 MPa to about 50 MPa, about 1 MPa to about 40 MPa, about 1 MPa to about 25 MPa, about 1 MPa to about 20 MPa, about 1 MPa to about 15 MPa, about 1 MPa to about 10 MPa, about 1 MPa to about 5 MPa, about 1 MPa to about 3 MPa, about 3 MPa to about 150 MPa, about 3 MPa to about 100 MPa, about 3 MPa to about 80 MPa, about 3 MPa to about 50 MPa, about 3 MPa to about 20 MPa, or about 3 MPa to about 10 MPa. In some embodiments, the Young's modulus of at least a portion of the stamp surface can be varied to optimize the patterning process. For example, as the lateral dimensions of the patterns decrease, the Young's Modulus of the flexible stamp can increase to ensure that the lateral dimensions are maintained. The Young's modulus of a flexible stamp can be controlled by modifying a prepolymer composition, curing agent, curing time, curing temperature, and combinations thereof.

In some embodiments, the first elastomer has a modulus of 3 MPa or more and the second elastomer has a modulus of about 3 MPa or less. In some embodiments, the first elastomer has a modulus of about 3.5 MPa or more and the second elastomer has a modulus of about 3 MPa or less.

In some embodiments, a stamp of the present invention comprises a surface having at least one protrusion thereon, wherein the at least one protrusion has a modulus at least about 20% greater than a modulus of the stamp surface.

In some embodiments, the modulus of the first elastomer is at least about 20% greater than the modulus of a second elastomer. In some embodiments, the modulus of the first elastomer is about 20% to about 1000% greater than the modulus of a second elastomer. In some embodiments, the modulus of the first elastomer is a minimum of about 20%, about 50%, about 100%, about 150%, about 200%, about 300%, about 400%, or about 500%, greater than the modulus of a second elastomer. In some embodiments, the modulus of the first elastomer is a maximum of about 1000%, about 900%, about 800%, about 700%, about 600%, or about 500% greater than the modulus of a second elastomer.

Referring to FIGS. 3A, 3B and 3C, in some embodiments, the second elastomer, 302, 352 and 372, respectively, comprises PDMS, and the first elastomer, 301, 351 and 371, respectively, comprises high-density PDMS (“H-PDMS”). Typically, H-PDMS swells less, and has a higher modulus, than PDMS. Not being bound by any particular theory, H-PDMS can absorb a solvent from an ink of the present invention, but does so to a lesser degree than, and exhibits superior solvent resistance compared to, PDMS. Thus, a stamp including a protrusion having a face portion, 307, 357 and 380, respectively, comprising H-PDMS can undergo a lesser amount of deformation upon contacting a substrate, exhibit reduced swelling when used with an ink of the present invention, and can also have a longer useful lifetime. Similarly, a stamp having a body, 304, 354 and 385, respectively, comprising PDMS can increase the stamp's ability to retain solvent during the applying and transferring, thereby enabling the use of an ink comprising a conductive or semiconductive polymer.

In some embodiments, transfer of an ink from a stamp to a substrate is facilitated by conformal contact between the two surfaces. Not being bound by any particular theory, the flexibility of the stamps can ensure conformal contact between a substrate and a surface of the at least one protrusion on the stamp is achieved. Referring to FIGS. 3A, 3B and 3C, a stamp having a body, 304, 354 and 385, respectively, comprising PDMS can increase the stamp's ability to maintain conformal contact with a substrate during the contacting.

In some embodiments, the first elastomer has a density that is greater than the density of the second elastomer. For example, in some embodiments the density of the first elastomer is at least about 10%, about 20%, about 30%, about 50%, about 100%, about 200%, about 300%, about 400%, or about 500% greater than the density of the second elastomer.

In some embodiments, the first elastomer has a surface free energy less than a surface free energy of the second elastomer. In some embodiments, the surface free energy of the first and second elastomers is selected to control the wetting of the first elastomer with an ink relative to the wetting of the second elastomer.

In some embodiment, the first elastomer has a surface free energy greater than a surface free energy of the second elastomer. In some embodiments, the first elastomer has a surface free energy that is about 10%, about 20%, about 30%, about 50%, about 75%, about 100%, about 150%, about 200%, about 250%, about 300%, about 350%, or about 400% greater than the surface free energy of the second elastomer. Additionally, in some embodiments, a drop of water forms a contact angle on a surface of the first elastomer that is about 10%, about 20%, about 30%, about 50%, about 75%, about 100%, about 150%, about 200%, about 250%, about 300%, about 350%, or about 400% greater than the contact angle formed by a drop of water on a surface of the second elastomer.

In some embodiments, a solvent is present in the body of the stamp, wherein the solvent present in the body continuously wets an ink on at least a face of a protrusion. Therefore, in some embodiments the body portion of a stamp encloses an inner volume suitable for containing a solvent, wherein the solvent enclosed therein is in fluid communication with at least a face portion of the at least one protrusion.

In some embodiments, the first elastomer has a swellability (i.e., a percentage increase in volume upon exposure to a solvent) less than a swellability of the second elastomer. As used herein, “swellability” refers to the percentage change in the volume of an elastomer upon exposure to (e.g., contact with, immersion in) a chemical species capable of permeating the elastomer under equilibrium conditions. The chemical species can be a liquid, a vapor, a gas, a mist, and combinations thereof. For example, aromatic solvents such as benzene, toluene, xylenes, cumene, and the like; halogenated solvents such as chloroform, dichloroethane, and the like; and combinations thereof are capable of permeating elastomers for use with the present invention. Swellability can be determined by measuring the volume of an elastomer prior to exposure to a chemical species, placing the elastomer in a closed system comprising a chemical species capable of permeating the elastomer until equilibrium is achieved, and making a second measurement of volume. The percentage difference between the two volume measurements is the swellability of the elastomer.

Not being bound by any particular theory, for soft lithography applications, many inks comprise solvents and other species capable of penetrating and/or permeating the elastomers that comprise the stamp, which can lead to swelling of the stamp and subsequent loss of critical dimension, reproducibility, and the like. Therefore, providing a stamp composition comprising a first elastomer having a reduced swellability can lead to improved reproducibility of forming patterns having lateral dimensions of about 50 μm or less by the methods of the present invention.

In some embodiments, the swellability (i.e., the percentage change the in volume) of the first elastomer is at least about 10%, about 20%, about 30%, about 40%, about 50%, about 60%, about 70%, about 80%, about 90%, about 100%, about 120%, about 150%, about 200%, or about 250% less than the swellability of the second elastomer.

In some embodiments, the first elastomer has a thickness that is less than that of the second elastomer. For example, the first elastomer can have a thickness of about 90%, about 80%, about 70%, about 50%, about 25%, about 10%, about 5%, about 1%, about 0.5%, or about 0.1% that of the second elastomer.

In one embodiment, the elastomeric stamp comprises two elastomers; however, the present invention also includes elastomeric stamps comprising more than two elastomers (e.g., 3, 4, 5, or 6, or more elastomers). In some embodiments, a plurality of elastomers can form an elastomeric stamp composition having, for example, a laminate structure, and variations thereof. In some embodiments, a SAM is formed on at least a portion of the surface of the first elastomer, and wherein the self-assembled monolayer is covalently attached to the first elastomer.

In some embodiments, the stamps further comprise a metal coating the surface of the stamp. Metals suitable for use with the present invention can be chosen from: an alkali metal, an alkali earth metal, a transition metal, a group 13 metal, a group 14 metal, a group 15 metal, and alloys and oxides thereof. In some embodiments, the stamp is coated with a metal chosen from: silver, gold, copper, palladium, platinum, tin, nickel, and combinations thereof.

In some embodiments, the metal coats a portion of the stamp. In some embodiments, the metal conformally coats the stamp surface.

Not being bound by any particular theory, a stamp comprising a metal coating has a surface free energy that is significantly greater than a surface free energy of an uncoated elastomeric stamp. Therefore, a metal coated stamp can be readily wetted by an ink composition of the present invention. Moreover, the metal coating can provide a method to prevent the ink composition from penetrating into the body of the stamp, thereby reducing swelling and extending the useful lifetime of a stamp. However, as discussed above, transferring an ink from a metal surface to a substrate can be difficult due to potentially strong adhesive and/or attractive forces between an ink and a metal coating.

The present invention has found that the presence of a SAM-forming species on the metal coating of a stamp can significantly improve the transfer of an ink from a coated stamp to a substrate.

Thus, the present invention is also directed to an elastomeric stamp composition comprising:
an elastomeric stamp having a surface including at least one protrusion thereon, the protrusion having face and sidewall portions, and the protrusion being contiguous with and defining a pattern on the surface of the stamp;
a metal coating at least the face of the at least one protrusion;
a SAM-forming species covalently attached to at least a portion of the metal coating; and
an ink comprising a conductive or semiconductive polymer and a solvent discontinuously coating the stamp surface and the at least one protrusion, wherein the ink uniformly coats the face of the at least one protrusion and wherein the sidewall portion is substantially free from the ink.

In a preferred embodiment the SAM-forming species does not provide monolayer coverage on the metal coating, thereby enabling the ink to interact with the metal coating during an applying process to provide a uniform ink coating on the at least one protrusion, while the SAM-forming species improves the transfer of the ink coating from the stamp to a substrate.

In some embodiments, about 50% or more, about 60% or more, about 70% or more, about 80% or more, about 90% or more, about 95% or more, or about 100% of the metal surface area is covered by the SAM-forming species covalently attached thereto. For example, a SAM-forming species that uniformly covers about 50% of the metal coating has a density equivalent to one-half of the maximum density of a self-assembled monolayer.

In some embodiments, the SAM-forming species covers about 50% to about 100% of the surface of a metallized stamp. In some embodiments, the SAM has a minimum coverage of about 50%, about 55%, about 60%, about 65%, about 70%, about 75%, or about 80% of the surface of a metallized stamp. In some embodiments, the SAM has a maximum coverage of about 100%, about 99%, about 98%, about 95%, about 92%, about 90%, or about 85% of the surface of a metallized stamp.

In some embodiments, the SAM-forming species uniformly covers the metal surface. As used herein, “uniformly covers” refers to a density of the SAM-forming species on a first area of the metal being the same as the density of the SAM-forming species on a second area of the metal.

A SAM-forming species can also cover the a metal coating on a stamp surface to provide a pattern thereon. Patterned SAMs can be provided by microcontact printing, chemical functionalization of the metal surface, and the like.

In some embodiments, the SAM-forming species has the structure:

-L-M-X

wherein -L- is a linker group that covalently bonds the SAM-forming species to the metal surface; -M- is a group chosen from: an optionally substituted C₁-C₂₀ alkyl, an optionally substituted C₁-C₂₀ alkenyl, an optionally substituted C₁-C₂₀ alkynyl, an optionally substituted C₁-C₂₀ aryl, an optionally substituted C₁-C₂₀ heteroaryl, and combinations thereof, and —X is an optional terminal group.

In some embodiments, -L- is a group chosen from: —S—; —O—; —NH—; —NR—; —NH—C(═O)—; —NR—C(═O)—; —C(═O)—NH—; —C(═O)—NR—; —SiH₂—; —Si(R)(R′)-; —Si(OR)(OR′)—; and combinations thereof, wherein R and R′ are independently an optionally substituted C₁-C₈ alkyl, alkenyl, alkynyl, aryl, or heteroaryl group. It is also within the scope of the present invention that -L- is covalently attached to at least a portion of the metal coating via more than one covalent bond (i.e., two, three, or more covalent bonds), or that -L- is covalently attached to the at least a portion of the metal coating via a double bond or a triple bond. In such embodiments, any of the groups H, R, R′, (═O), OR and OR′ described above can be optionally absent to provide an additional covalent bond with at least a portion of the metal surface.

In some embodiments, a molecule that forms the SAM includes an optional terminal group, —X. In some embodiments, the optional terminal group contributes to a hydrophobic character of the stamp surface. For example, the optional functional group can be a hydrophobic functional group. As used herein, “hydrophobic” refers to films, coatings, and SAMs that have a tendency to repel water, are resistant to water and/or cannot be wetted by water. In some embodiments, the optional functional group is chosen from: a fluoro (—F), a secondary amino (—N(R)(R′)), a trialkylsilyl (—Si(R)(R′)(R″)), and combinations thereof, wherein R, R′ and R″ are independently a C₁-C₄ straight- or branched-chain alkyl group. In some embodiments, a SAM-forming species is a molecule chosen from: perfluorodecanethiol, octadecanethiol, octanethiol, and combinations thereof.

In some embodiments, water deposited on a hydrophobic surface of the present invention forms a droplet having a contact angle of about 80° to about 180°. In some embodiments, water deposited onto a hydrophobic coating of the present invention forms a minimum contact angle of about 70°, about 75°, about 80°, about 85°, about 90°, about 100°, about 110°, or about 120°.

In some embodiments, the stamp further comprises a second SAM-forming species having the structure:

-L-M-X′

wherein -X′ is a group chosen from: carboxy (—COOH), primary amino (—NH₂), hydroxy (—OH), and combinations thereof. Thus, in some embodiments, the stamp further comprises a molecule having a hydrophilic functional group. As used herein, “hydrophilic” refers to a group that capable of forming a hydrogen bond.

In some embodiments, at least a portion of the metal coating comprises a SAM-forming species having a hydrophobic functional group and a second a SAM-forming species having a hydrophilic functional group. The ratio of hydrophobic a SAM-forming species to hydrophilic SAM-forming species can be controlled to influence the surface free energy of the stamp. In some embodiments, the molar ratio of a hydrophobic SAM-forming species to a hydrophilic SAM-forming species is about 1:1 to about 100:1, about 1:1 to about 10:1, about 1:1 to about 8:1, about 1:1 to about 4:1, about 1:1 to about 2:1, or about 1:1. In some embodiments, the minimum molar ratio of a hydrophobic SAM-forming species to a hydrophilic SAM-forming species is about 1:1, about 2:1, about 3:1, about 4:1, about 5:1, about 6:1, about 7:1, about 8:1, about 9:1, or about 10:1. In some embodiments, the maximum molar ratio of hydrophobic a SAM-forming species to hydrophilic a SAM-forming species is about 100:1, about 90:1, about 80:1, about 70:1, about 60:1, about 50:1, about 40:1, about 30:1, about 20:1, or about 15:1, or about 12:1.

In some embodiments, the metallized elastomeric stamp has a surface area of at least about 4 cm². In some embodiments, the metallized elastomeric stamp has a surface area of about 4 cm² to about 5,000 cm². In some embodiments, an elastomeric stamp has a minimum surface area of at least about 4 cm², about 5 cm², about 10 cm², about 20 cm², about 50 cm², about 100 cm², about 150 cm², about 200 cm², about 300 cm², or about 400 cm². In some embodiments, an elastomeric stamp has a maximum surface area of about 5,000 cm², about 4,500 cm², about 4,000 cm², about 3,5000 cm², about 3,000 cm², about 2,500 cm², about 2,000 cm², about 1,500 cm², about 1,000 cm², or about 500 cm².

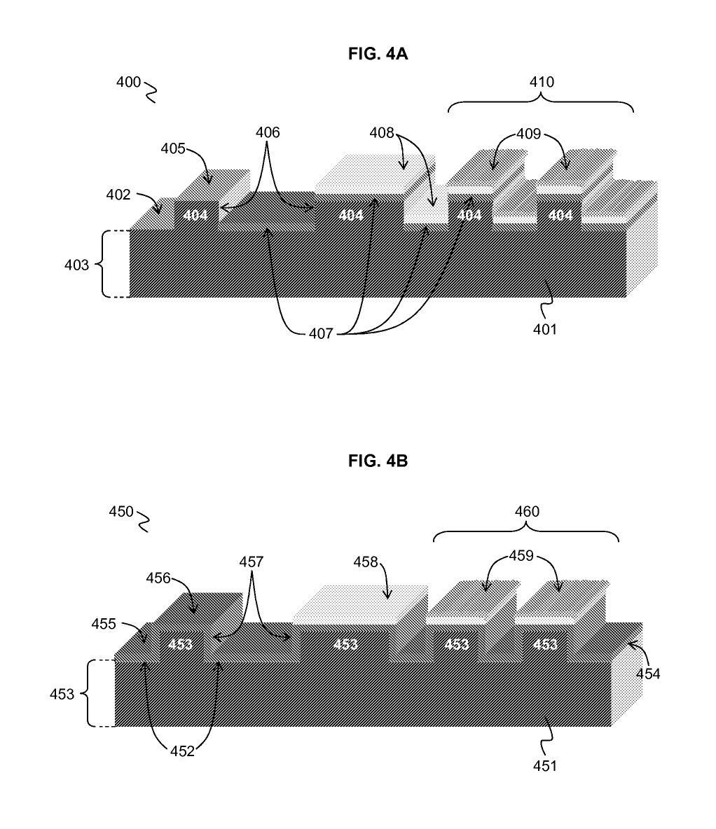

FIGS. 4A and 4B provide three-dimensional schematic representations of metallized stamps of the present invention. Referring to FIG. 4A, an elastomeric stamp, 400, is provided comprising an elastomer, 401, having a surface, 402, including at least one protrusion thereon, 404. The protrusion, 404, includes a face portion, 405, and a sidewall portion, 406. The stamp further includes a body portion, 403, comprising the volume of the stamp other than the protrusion, 404. At least one of the surface of the stamp, 402, or the face portion of the protrusion, 405, is coated with a metal, 407. In an embodiment provided in FIG. 4A, the metal, 407, coats the surface of the stamp, 402, as well as the face portion of the at least one protrusion on the stamp surface, 405. However, additional embodiments in which the metal, 407, coats only the face portion of the at least one protrusion, 405, are also within the scope of the present invention. On at least a portion of the metal, 407, is provided a SAM-forming species, 408. The SAM-forming species, 408, is provided on at least the metal coating the face portion of the protrusion, and optionally on a metal coating the stamp surface. The coating, 408, can comprise a SAM-forming species, but the density of the coating can vary considerably; from about 20% to 100%, about 30% to about 95%, or about 40% to about 90% surface-area coverage of the metal. A discontinuous coating, 410, comprising an ink, 409, is provided on at least the face portion of the at least one protrusion. In some embodiments, the ink, 409, coats only the surfaces of the stamp having a SAM-forming species, 408, thereon. In some embodiments, the sidewall portion of the at least one protrusion, 406, is substantially free from the ink, 409.

Referring to FIG. 4B, an elastomeric stamp, 450, is provided comprising an elastomer, 451, having a surface, 452, including at least one protrusion thereon, 453. The stamp surface, 452, and the at least one protrusion, 453, are conformally coated with a metal, 454. The resulting metal-coated stamp includes a surface portion, 455, a face portion, 456, and a sidewall portion, 457. At least a portion of the metal is further coated with a SAM-forming species, 458. In an embodiment provided in FIG. 4B, the SAM-forming species, 458, coats the face portion of the stamp, 456. In some embodiments, the SAM-forming species additionally coats at least one of the surface portion, 455, and/or the sidewall portion, 457. As described above, the density of the SAM-forming species can be varied. A discontinuous coating, 460, comprising an ink, 459, is provided on at least the face portion of the metal coating. In some embodiments, the ink, 459, coats only the surfaces having a SAM-forming species, 458, thereon. In some embodiments, the sidewall portion of the at least one protrusion, 457, is substantially free from the ink, 459.

The present invention is also directed to stamp compositions suitable for patterning substrates having surface areas of about 100 cm² or greater. A critical parameter for creating uniform patterns across large surface areas is the ability to minimize distortions in a stamp during the contacting of a stamp with a substrate. Not being bound by any particular theory, distortions in a stamp during the contacting can occur due to a non-uniform stamp thickness, a non-planarity, and the like. Thus, the present invention is further directed to providing stamps having uniform thicknesses and optimum flatness.

As used herein, a “distortion” in a flat stamp surface refers to a deviation from flatness. For example, the surface of a flat, planar stamp of the present invention having a flat, planar backing layer thereon will have a minimum of deviations from planarity between the stamp surface and backing layer. In some embodiments, the distortion is the magnitude of the deviation from planarity across the entire surface of a flat stamp. In some embodiments, a stamp of the present invention has a distortion of about 20 μm or less, about 15 μm or less, about 12 μm or less, about 10 μm or less, about 8 μm or less, about 5 μm or less, or about 2 μm or less per 10 cm² of surface area.

Not being bound by any particular theory, distortions in the stamp surface can be minimized by: utilizing materials having identical coefficients of thermal expansion as the molding materials that contact an elastomeric precursor during curing, minimizing the temperature during a curing process, utilizing a master having a topography that can compensate for differential expansion of surfaces in a stamp mold, and combinations thereof.

In some embodiments, the stamps of the present invention have a substantially uniform thickness. As used herein, the thickness of the stamp, as described above, refers to the thickness of the body of the stamp, and does not include the at least one protrusion thereon. In some embodiments, a stamp of the present invention has a thickness difference of about 10% or less, about 8% or less, about 5% or less, about 2% or less, about 1% or less, about 0.5% or less, about 0.1% or less, or about 0.05% or less across the entire thickness of the stamp.

### Methods of Preparing the Stamps

The present invention is also directed to a method of preparing a metallized elastomeric stamp composition, the method comprising:
(a) providing an elastomeric stamp having a surface including at least one protrusion thereon, the protrusion having a face portion and a sidewall portion and being contiguous with and defining a pattern on the surface of the stamp;
(b) depositing a metal onto at least the face portion of the protrusion to form a metal surface; and
(c) covalently bonding to the metal surface a SAM-forming species.

In some embodiments, a stamp having a topographical pattern and a flexible or elastomeric morphology can be prepared from a master stamp comprising a topographical pattern in the surface of a rigid material.

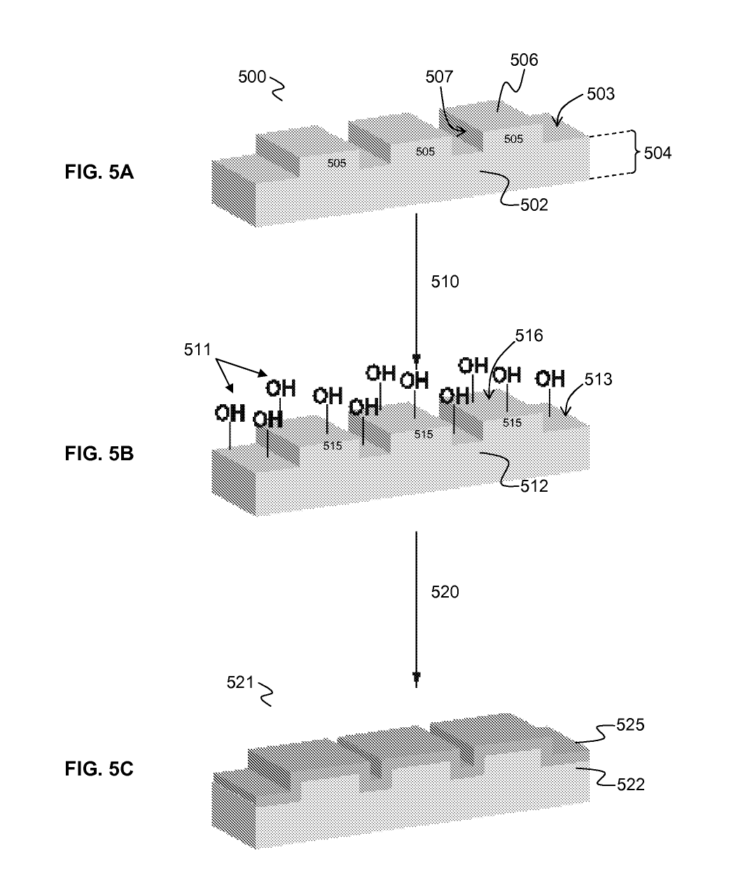

FIGS. 5A-5C provide a three-dimensional schematic representation of a process for preparing a metal-coated elastomeric stamp according to one embodiment of the invention. Referring to FIG. 5A, an elastomeric stamp, 500, is provided, wherein the stamp comprises an elastomer, 502, including a surface, 503, and having a body portion, 504, enclosed by the surface. The stamp surface, 503, includes at least one protrusion thereon, the protrusion being contiguous with and defining a pattern on the stamp surface. The protrusion comprises a face portion, 506, and a sidewall portion, 507. In some embodiments, the stamp, 500, is functionalized with a polymer layer (not shown).

In some embodiments process of the present invention comprises activating the stamp surface, 510, by for example, a pre-treating as described elsewhere herein. In some embodiments, a pre-treating suitable for activating a stamp surface comprises at least one of: oxidizing the stamp surface or functionalizing the stamp surface.

Referring to FIG. 5B, the activating, 510, can provide one or more functional groups, 511, on at least the face portion, 516, of the protrusion, 515. Suitable functional groups, 511, include but are not limited to, —OH, —OR, —SH, —COOH, —C(O)H, —C(O)R, —SiH₃, —SiH₂R, —SiHRR′, —SiRR′R″, —SiH₃, —SiH₂(OR), —SiH(OR)(OR′), —Si(OR)(OR′)(OR″), —F, —Cl, and combinations thereof, wherein R, R′ and R″ are independently chosen from a C₁-C₆ straight-, branched- or cyclic-chain alkyl, or combine to form a cyclic C₃-C₆ alkyl group. In some embodiments, the activating can comprise oxidizing the surface of the stamp, for example, by any one of: exposure to a plasma, chemical oxidation, exposure to UV light, and combinations thereof.

Not being bound by any particular theory, the functional groups can promote deposition and/or adhesion of a metal to the surface of an elastomer. A metal is then deposited, 520, on the surface of the stamp.

Referring to FIG. 5C, a metal-coated stamp, 521, is provided, comprising an elastomer, 522, having a conformal metal coating, 525, thereon. In some embodiments, the metal layer, 525, comprises silver (Ag), as depicted in FIG. 5C. Suitable methods for metal deposition, 520, include, but are not limited to, evaporating, electrolessly depositing, galvanically replacing, electroplating, chemical vapor depositing, thermally depositing, and combinations thereof, and any other metal deposition techniques as would be apparent to a person of ordinary skill in the art. In some embodiments, the metal layer, 525, and is be co-deposited with a polymer.

In some embodiments, a SAM-forming species is further deposited on at least a portion of the metal coating, 525. A SAM-forming species can be deposited on the metal coating by any one of: microcontact printing, screen-printing, stenciling, syringe deposition, ink-jet printing, dip-pen nanolithography, immersion, vapor deposition, and combinations thereof, and any other deposition techniques as would be apparent to a person of ordinary skill in the art.

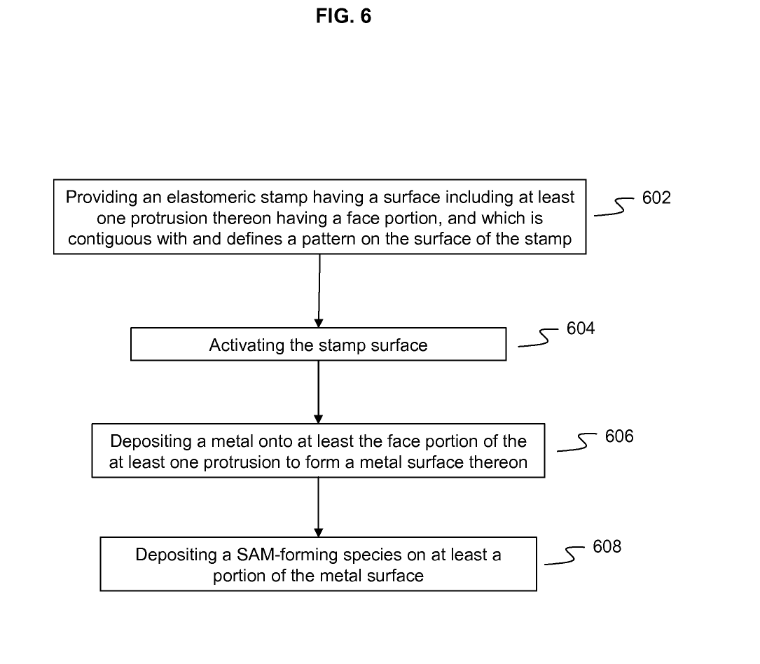

FIG. 6 provides a flow diagram for a method of preparing a metallized elastomeric stamp composition according to an embodiment of the invention. At block 602, an elastomeric stamp having a surface including at least one protrusion thereon having a face portion, and which is contiguous with and defines a pattern on the surface of the stamp is provided.

In one embodiment, the stamp surface is activated, as shown by block 604. In one embodiment, activating 604 comprises oxidizing the stamp surface. In another embodiment, activating 604 comprises activating and/or functionalizing the stamp surface. Returning to FIG. 5B, activated elastomeric surfaces, 513 and 516, are shown.

Returning to FIG. 6, a metal can deposited onto at least the face portion of the at least one protrusion to form a metal surface thereon, as shown in block 606. Suitable methods for metal deposition, 606, are described herein. In some embodiments, the temperature of the stamp is controlled during the metal deposition process. Temperature control during metal deposition can be important because metal deposition can induce thermal heating on the stamp surface. Because of the differential coefficients of expansion between the metal and the stamp surface, heating of the stamp can result in three-dimensional distortion the stamp that can lead to cracking, buckling, and peeling of the metal upon cooling. Thus, in some embodiments, the temperature of the stamp is controlled during a metal deposition process at about 100° C. or less, about 90° C. or less, about 80° C. or less, about 70° C. or less, about 60° C. or less, about 50° C. or less, about 40° C. or less, about 30° C. or less, or about 25° C. or less. In some embodiments, a metal is deposited by an electroless deposition process that can be performed at about 25° C. or less (i.e., at about room temperature).

In some embodiments, as shown by block 608, a SAM-forming species is deposited onto at least a portion of the metal surface. In some embodiments, block 608 can be omitted from the process of the present invention.

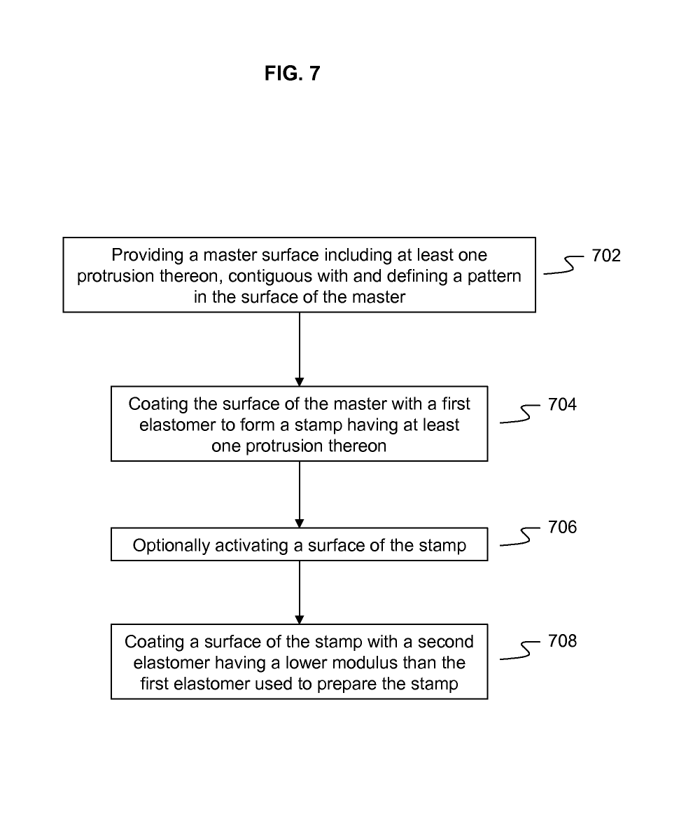

FIG. 7 provides a flow diagram for a method of preparing an elastomeric stamp composition according to an embodiment of the invention. At block 702, a master having a surface including at least one protrusion thereon, contiguous with and defining a pattern on the surface of the master is provided.

In one embodiment, the master is covered with an elastomeric precursor, as shown by block 704. The precursor can be cured or partially cured to form a stamp comprising an elastomer having a surface including at least one protrusion thereon.

A surface of the stamp (e.g., a face portion of a protrusion) can be optionally activated, as shown by block 706. In one embodiment, activating 706 comprises oxidizing the stamp surface. In another embodiment, activating 706 comprises functionalizing the stamp surface.

The stamp surface is then coated with an elastomer having a modulus lower than the modulus of the stamp, as shown by block 708. The stamp and the master can be separated either before or after applying the lower-modulus elastomer to a surface of the stamp.

In another embodiment, an elastomeric stamp having a surface including at least one protrusion thereon is provided. In some embodiments, the elastomeric stamp comprises one elastomeric layer. In one embodiment, the elastomeric layer is PDMS. In another embodiment, the elastomeric stamp comprises a first elastomeric layer and a second elastomeric layer. The stamp surface is then activated, for example, by oxidizing and/or functionalizing the stamp surface. The stamp surface is then coated with an elastomer having a modulus higher than the modulus of the elastomeric stamp composition.

The present invention is also directed to an injection-molding process for preparing a stamp, the process comprising:
providing a substantially planar first surface having at least one injection port and at least one vent port therethrough;
applying to the substantially planar first surface, a master having a surface including at least one protrusion thereon, the protrusion being contiguous with and defining a pattern on the surface of the master;
rigidly positioning a substantially planar second surface at a fixed distance from the first surface, wherein the first and second surfaces are substantially co-planar, and wherein a volume including the master is enclosed between the first and second surfaces; and
injecting an elastomeric precursor through the injection port into the enclosed volume.

In some embodiments, the process further comprises: curing the elastomeric precursor. Suitable curing processes include, but are not limited to, heating, exposing to UV light, and the like. In some embodiments, the temperature of the elastomer is maintained at about 80° C. or less, about 70° C. or less, about 60° C. or less, about 50° C. or less, about 40° C. or less, about 35° C. or less, or about 30° C. or less during the curing. In some embodiments, the temperature during the curing is minimized.

In some embodiments, the process further comprises rigidly positioning a back plane co-planar with the master, wherein the back plane is within the volume enclosed by the first and second surfaces. In some embodiments, the back plane and the master are comprised of the same materials. In some embodiments, the back plane and the master are comprised of materials having the same or substantially similar coefficients of thermal expansion. As used herein, a coefficient of thermal expansion, a, refers to the change in material length (and similarly, volume) for each degree of temperature.

In some embodiments, the master has an anisotropic surface suitable for compensating for any difference in thermal expansion properties between the master and the back plane and/or the first and second surfaces.

In some embodiments, the process further comprises: positioning a rigid spacer to surround the edges of the master. The rigid spacer can comprise the same or a different material compared to the master and the first and second surfaces. The rigid spacer can be used to ensure that the second surface and/or the rigid back plane are maintained at a fixed and constant distance (i.e., across the entire surface area) from the master.

### Ink Compositions

The present invention is also directed to a polymer ink composition consisting essentially of:
a conductive or semiconductive polymer in a concentration of about 0.1% to about 5% by weight;
a first solvent having a vapor pressure at 25° C. of about 20 mm Hg or less present in a concentration of about 50% or less by weight; and
a second solvent having a vapor pressure greater than the first solvent, wherein the conductive or semiconductive polymer has a solubility in the second solvent of about 1 mg/mL or more.

As used herein, “consisting essentially” refers to the ink composition including one or more conductive or semiconductive polymers, one or more first solvents, and one or more second solvents. Thus, the ink composition of the present invention includes polymer blends, and multicomponent solvent mixtures so long as at least one of each component is present in the ink composition.

As used herein, an “ink” refers to a conductive or semiconductive polymer composition suitable for forming a pattern on a substrate having a hole or electron mobility of about 10⁻⁶ cm²/V·s or more. Conductive and/or semiconductive polymers suitable for use with the present invention include, but are not limited to, an arylene vinylene polymer, a polyphenylenevinylene, a polyacetylene, a polythiophene, a polyimidazole, a polypyrrole, a polynaphthalene, a polyfluorene, a polytetrathiafulvene, a poly(phenylenesulfide), a polyaniline, doped variants thereof, substituted variants thereof, copolymers thereof, and combinations thereof.

As used herein, in some embodiments a “conductive or semiconductive polymer” can further comprise a light-emitting polymer, molecule, functional group, moiety, species, dopant, and the like capable of emitting light in the infrared or visible regions of the electromagnetic spectrum. Polymeric compositions suitable for preparing LEDs and multilayer structures comprising the polymers are known to persons of ordinary skill in the art. Thus, the inks and methods of the present invention are suitable for preparing light-emitting diode “LED” structures (e.g., organic LEDs) and articles of manufacture comprising LEDs.

As used herein, a “doped variant” of a polymer refers to a polymer composition in which impurities have been introduced to change its electrical properties.

As used herein, a “substituted variant” of a polymer refers to a polymer having one, two, three or more pendant side groups covalently attached to the polymer. The side groups can modify the solubility, electrical properties, and the like of the polymer.

In some embodiments, the conductive or semiconductive polymer is a thermoplastic polymer. As used herein, a “thermoplastic polymer” refers to a composition that can undergo plastic deformation upon heating and becomes firm when cooled, with this process able to be repeated without the material becoming brittle.

Suitable ink compositions include solutions, suspensions, gels, creams, glues, adhesives, liquids, viscous liquids, semi-solids, and the like that can be poured, sprayed, or otherwise evenly applied to a stamp. After the applying an ink can become non-fluidic as long as the ink remains in a flexible (i.e., non-hardened) state until an ink-coated stamp is contacted with a substrate. In some embodiments, an ink for use with the present invention has a tunable viscosity, and/or a viscosity that can be controlled by one or more external conditions.

A conductive or semiconductive polymer is present in an ink composition in a concentration of about 0.1% to about 5%, about 0.1% to about 3%, about 0.1% to about 2%, about 0.1% to about 1%, about 0.5% to about 5%, about 0.5% to about 3%, about 0.5% to about 2%, about 0.5% to about 1%, about 1% to about 5%, about 1% to about 3%, about 1% to about 2%, about 2% to about 5%, about 2% to about 3%, or about 3% to about 5% by weight of the ink composition.

Not being bound by any particular theory, the polymer concentration in the ink is suitable to form a discontinuous film covering at least a portion of the stamp. For example, an ink composition having a polymer concentration greater than about 5% by weight can form a continuous film on a stamp surface in which a polymer film deposited on a face of a protrusion is connected with a polymer film deposited on a surface of the stamp (e.g., by filling a space between adjacent protrusions, by depositing a polymer film on a sidewall of a protrusion, and the like). Additionally, an ink composition having a polymer concentration less than about 0.1% by weight can be too dilute to form a continuous film or a pinhole-free film on a face portion of a stamp.

The ink composition includes a first solvent having a vapor pressure at 25° C. of about 20 mm Hg or less present in a concentration of about 50% or less by weight. In some embodiments, the first solvent is an aromatic solvent. Exemplary, non-limiting, solvents having a vapor pressure at 25° C. of about 20 mm Hg or less include decane, dodecane, diethylketone, tetralin, butylacetate, n-butanol, xylene, cumene, cymene, mesitylene, chlorobenzene, dichlorobenzene, and other substituted aromatic solvents, N-methylpyrrolidone, N,N-dimethylformamide, and the like, and other solvents known to persons of ordinary skill in the art. In some embodiments, the first solvent is present in a concentration of about 50% or less, about 40% or less, about 30% or less, about 25% or less, about 20% or less, about 15% or less, about 10% or less, or about 5% or less by weight.

In some embodiments, the second solvent has a vapor pressure at 25° C. of about 20 mm Hg or less, about 15 mm Hg or less, about 12 mm Hg or less, about 10 mm Hg or less, or about 8 mm Hg or less.

In some embodiments, the first solvent has a boiling point of about 120° C. or higher, about 125° C. or higher, about 130° C. or higher, about 135° C. or higher, about 140° C. or higher, about 150° C. or higher, or about 160° C. or higher.

Not being bound by any particular theory, a first solvent having a vapor pressure at 25° C. of about 20 mm Hg or less enables the ink composition to maintain a fluidic, viscous, semi-viscous, tacky, or otherwise flexible, non-hardened state during a time interval between applying the ink to a stamp and transferring the ink from the stamp to a substrate. For example, drying of the ink on the stamp prior to the contacting can lead to cracking of the polymer pattern, which can lead to defects in an electrical device comprising the conductive or semiconductive polymers. Additionally, drying of the ink on the stamp prior to the contacting can lead to incomplete transfer of a polymer pattern from the stamp to a substrate.

The ink composition also includes a second solvent having a vapor pressure greater than the first solvent, wherein the conductive or semiconductive polymer has a solubility in the second solvent of about 1 mg/mL or more. In some embodiments, the second solvent can include a solvent mixture, wherein the mixture of solvents has a vapor pressure greater than the second solvent. As the concentration of the first solvent is varied, the concentration of the second solvent is adjusted to compensate.

The second solvent has a vapor pressure greater than the first solvent. In some embodiments, the second solvent has a vapor pressure of about 10 mm Hg or more, about 15 mm Hg or more, about 20 mm Hg or more, about 25 mm Hg or more, about 40 mm Hg or more, about 50 mm Hg or more, about 75 mm Hg or more, about 100 mm Hg or more, about 125 mm Hg or more, or about 150 mm Hg or more at 25° C.

In addition to any of the first solvents described above, additional solvents suitable for use as second solvents in the ink composition of the present invention include, but are not limited to water, methanol, ethanol, n-propanol, iso-propanol, toluene, benzene, pyridine, a C₅-C₇ straight-, branched- or cyclic-chain hydrocarbon (e.g., hexane, cyclohexane, heptane, and the like), methylenechloride, chloroform, carbon tetrachloride, 1,2-dichloroethane, acetone, methylethylketone, ethylacetate, propylacetate, diethylether, tetrahydrofuran, and the like, and combinations thereof. In some embodiments, a second solvent is present in an ink in a concentration of about 10% to about 90%, about 15% to about 85%, about 25% to about 85%, about 40% to about 80%, or about 50% to about 75% by weight of the ink.

In some embodiments, the first solvent is a xylene or xylenes, and the second solvent is toluene.

In some embodiments, the second solvent has a boiling point of about 120° C. or less, about 115° C. or less, about 110° C. or less, about 105° C. or less, about 100° C. or less, about 90° C. or less, about 80° C. or less, or about 70° C. or less.

In some embodiments, the conductive or semiconductive polymer has a solubility in the second solvent of about 1 mg/mL or more, about 2 mg/mL or more, about 5 mg/mL or more about 10 mg/mL or more, about 15 mg/mL or more, about 20 mg/mL or more, about 25 mg/mL or more, about 30 mg/mL or more, about 50 mg/mL or more, or about 100 mg/mL or more.

Not being bound by any particular theory, after the applying of an ink to a stamp and through at least the contacting, the second solvent continuously evaporates from the ink thereby precipitating the polymer from the ink composition. After the contacting, solvents remaining in the ink can be removed therefrom, e.g., by heating, blowing, etc.

In some embodiments, as the lateral dimensions of the desired electrically conductive or semiconductive patterns decrease (i.e., below about 100 nm), it can be necessary to reduce the physical length or molecular weight of the polymers in the ink composition.

In some embodiments, the composition of an ink can be formulated to control its viscosity. Parameters that can control ink viscosity include, but are not limited to, solvent composition, solvent concentration, the molecular weight of the polymer, the degree of cross-linking between polymers, the presence of side groups on a polymer, and the like, and combinations thereof.

In some embodiments, an ink has a viscosity or an apparent viscosity at 40° C. of about 1 centiPoise (cP) to about 10,000 cP, about 1 cP to about 8,000 cP, about 1 cP to about 5,000 cP, about 1 cP to about 2,000 cP, about 1 cP to about 1,000 cP, about 1 cP to about 500 cP, about 1 cP to about 100 cP, about 1 cP to about 80 cP, about 1 cP to about 50 cP, about 1 cP to about 20 cP, about 1 cP to about 10 cP, about 5 cP to about 5,000 cP, about 5 cP to about 1,000 cP, about 5 cP to about 500 cP, about 5 cP to about 200 cP, about 5 cP to about 100 cP, about 5 cP to about 50 cP, about 5 cP to about 25 cP, about 5 cP to about 20 cP, about 5 cP to about 15 cP, about 5 cP to about 10 cP, about 10 cP to about 10,000 cP, about 10 cP to about 5,000 cP, about 10 cP to about 1,000 cP, about 10 cP to about 500 cP, about 10 cP to about 100 cP, about 10 cP to about 50 cP, about 10 cP to about 40 cP, about 10 cP to about 25 cP, about 10 cP to about 20 cP, about 20 cP to about 10,000 cP, about 20 cP to about 5,000 cP, about 20 cP to about 1,000 cP, about 20 cP to about 500 cP, about 20 cP to about 100 cP, or about 20 cP to about 50 cP.

### Patterning Methods

The patterning methods and processes of the present invention are micro-contact printing processes. As used herein, “micro-contact printing” (“μCP”) refers to a patterning process in which a “stamp” having a topographical pattern and a flexible or elastomeric morphology is placed in contact with a substrate, and the topographical pattern in the stamp is transferred to the surface by transferring an “ink” from the surface of the stamp (e.g., the topographical pattern) to the substrate.

The present invention is directed to a process for forming a conductive or semiconductive polymer pattern on a substrate, the process comprising:
providing a stamp having a surface including at least one protrusion thereon, the protrusion being contiguous with and defining a pattern on the surface of the stamp;
applying an ink comprising a conductive or semiconductive polymer and a solvent to the stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer pattern has an electron or hole mobility of about 10⁻⁶ cm²/V·s or more.

In some embodiments, the process further comprises pre-treating, as described above, at least a portion of the substrate prior to the contacting.

In some embodiments, the ink is applied to a stamp by a process chosen from: spraying, flowing, dip-coating, spin-coating, drop casting, vapor depositing, screen printing, ink jet printing, syringe depositing, brushing, and the like, and combinations thereof, as well as any other ink application methods known to persons of ordinary skill in the art.

In some embodiments, the process comprises precipitating the ink onto at least a protrusion of a stamp. For example, after applying an ink to a stamp in which the ink includes at least a conductive or semiconductive polymer and a solvent in which the polymer has a solubility of about 1 mg/mL or more, a second solvent can be added to the ink (i.e., applied to the surface of the stamp). The second solvent is one in which the solubility of the polymer is about 1 mg/mL or less, about 0.1 mg/mL or less, about 0.01 mg/mL or less, about 1 μg/mL or less, about 0.1 μg/mL or less, or is substantially insoluble. As the concentration of the second solvent present on the stamp increases, the conductive or semiconductive polymer begins to precipitate from the ink onto the stamp.

In some embodiments, the second solvent is the same as the solvent present in the ink, but further includes an ionic species, moiety, salt, and the like capable of complexing with the conductive or semiconductive polymer to decrease its solubility in the solvent mixture.

In some embodiments, the applying provides a coated stamp comprising a discontinuous ink coating across the stamp surface. As used herein, a “discontinuous ink coating” refers to a non-conformal ink coating on the stamp. Not being bound by any particular theory, a discontinuous coating can ensure that the ink is uniformly and reproducibly transferred to a substrate.

Various methods can be used to ensure the ink-coating is uniform across the entire surface of the stamp. For example, in some embodiments, the process further comprises pre-treating, as described above, at least a portion of the stamp surface prior to the applying.

Additional methods suitable to ensure the ink-coating is uniform across the stamp surface also include, for example, applying the ink to a surface of a stamp by spraying or flowing, and then spinning or rotating the stamp. In some embodiments, the stamp can be spun or rotated at about 100 revolutions per minute (rpm) to about 5,000 rpm, or about 1,000 rpm to about 3,000 rpm. In some embodiments, additional ink is applied to the stamp surface during the rotating or spinning.

In those embodiments in which the stamp is rotated or spun to ensure a uniform ink coating it can be advantageous to further incubate the coated stamp prior to the spinning. Not being bound by any particular theory, incubating can promote interactions between the ink and a surface of the stamp. Incubating can ensure that the ink is not completely or largely removed from a coated stamp during spinning. For example, it has been observed that the ink is largely removed from ink-coated stamps that are immediately spun or rotated after the applying. However, incubating the coated stamp for about 30 seconds to about 1 hour can ensure that a uniform coating of ink remains on the at least one protrusion of the stamp after a spin-coating process (i.e., rapidly spinning or rotating the stamp). Thus, in some embodiments, the applying comprises coating the stamp with the ink, incubating the coated stamp for about 1 minute to about 10 minutes, and spinning the stamp at about 100 rpm to about 5,000 rpm.

Additionally, in some embodiments, incubating can be performed when the process does not include rapidly spinning the coated stamp. For example, it has also been found that incubating can improve transfer of the conductive or semiconductive polymer pattern from the stamp to the substrate.

Incubating can be performed at room temperature or at an elevated temperature and/or pressure, a decreased temperature and/or pressure, and combinations thereof. In some embodiments, incubating is for a time period of about 30 seconds to about 1 hour, about 30 seconds to about 30 minutes, about 30 seconds to about 10 minutes, about 30 seconds to about 5 minutes, about 1 minute to about 1 hour, about 1 minute to about 30 minutes, about 1 minute to about 10 minutes, about 1 minute to about 5 minutes about 2 minutes to about 1 hour, about 2 minutes to about 30 minutes, about 2 minutes to about 10 minutes, or about 2 minutes to about 5 minutes.

Not being bound by any particular theory, the concentration of the conductive or semi-conductive or semiconductive polymer in the ink can be varied depending on the method of applying the ink to the stamp surface. For example, applying methods utilizing a spin-coating process typically require a higher concentration of a conductive or semiconductive polymer in the ink compared to spraying processes. Thus, in some embodiments the present invention is directed to a microcontact patterning process in which an ink comprising about 1% or greater, about 1.2% or greater, about 1.5% or greater, or about 2% by weight of a conductive or semiconductive polymer in a solvent is spin-coated on the surface of a stamp having at least one protrusion thereon, wherein the ink uniformly coats a face portion of the at least one protrusion. And in some embodiments the present invention is directed to a pattern process in which an ink comprising about 1.5% or less, about 1.2% or less, about 1% or less, or about 0.7% or less by weight of a conductive or semiconductive polymer in a solvent is spray-coated on the surface of a stamp having at least one protrusion thereon, wherein the ink uniformly coats a face portion of the at least one protrusion.

A second method that can be utilized to ensure uniform and reproducible patterning is by maintaining the ink (i.e., the conductive or semiconductive polymer) in a fluidic, gelled or flexible state during at least the contacting. This can be accomplished by at least one of: ensuring a solvent is present in the ink, providing a solvent reservoir in the body of the stamp, heating at least one of the stamp and/or the ink, and the like, and combinations thereof.

Thus, in some embodiments, the process further comprises wetting the stamp with a solvent prior to the applying, wherein the solvent is the same or different from a solvent present in the ink, and wherein the solvent maintains the ink in a fluidic, gelled or flexible state during at least the contacting. In some embodiments, the first solvent has a vapor pressure at 25° C. of about 50 mm Hg or less, about 40 mm Hg or less, about 30 mm Hg or less, about 25 mm Hg or less, about 20 mm Hg or less, about 15 mm Hg or less, or about 10 mm Hg or less. In some embodiments, the stamp is wetted with a xylene.

The wetting of the stamp can occur by dipping the stamp in a solvent, exposing the stamp to solvent vapors, storing the stamp in a enclosed solvent atmosphere prior to the applying, providing a reservoir suitable for containing the solvent within the body of the stamp wherein the solvent reservoir is in fluid communication with at least the face of the at least one protrusion of the stamp, and combinations thereof.

In some embodiments, the process further comprises wetting the stamp with a first solvent prior to the applying, wherein the first solvent is the same or different from the ink solvent, and wherein the first solvent facilitates uniformly coating the at least one protrusion with the ink.

In some embodiments, prior to the applying the stamp is immersed in a solvent having a vapor pressure of about 20 mm Hg or less for a time period of about 5 minutes or less, about 2 minutes or less, about 1 minute or less, about 30 seconds or less, about 10 seconds to about 5 minutes, about 10 seconds to about 2 minutes, about 10 seconds to about 1 minute, or about 30 seconds.

Maintaining the ink (i.e., the conductive or semiconductive polymer) in a fluidic, gelled or flexible state during at least the contacting can also ensure an absence of defects such as cracks, pinholes, and the like in the pattern. Thus, the present invention is also directed to forming a conductive or semiconductive polymer pattern substantially free from cracks, pinholes, and mechanical defects. As used herein, “substantially free from cracks, pinholes, and mechanical defects” refers to a defect density on a patterned substrate of about 1 defect or less per 1 cm², about 1 defect or less per 10 cm², about 1 defect or less per 50 cm², about 1 defect or less per 100 cm², about 1 defect or less per 500 cm², about 1 defect or less per 1,000 cm², about 1 defect or less per 5,000 cm², about 1 defect or less per 10,000 cm², about 1 defect or less per 100,000 cm², or about 1 defect or less per 1,000,000 cm² of patterned substrate area. As used herein, “substantially free from cracks, pinholes, and mechanical defects” can also refer to a defect density on a patterned substrate of about 1 defect or less per 100 pixels, about 1 defect or less per 500 pixels, about 1 defect or less per 1,000 pixels, about 1 defect or less per 5,000 pixels, about 1 defect or less per 10,000 pixels, about 1 defect or less per 100,000 pixels, about 1 defect or less per 1,000,000 pixels, about 1 defect or less per 10,000,000 pixels, or about 1 defect or less per 100,000,000 pixels.

In some embodiments, the presence of a solvent during at least the applying and the contacting can ensure that the ink is substantially free from crystallinity during the applying and the contacting. As used herein, “substantially free from crystallinity” refers to an inability to identify crystalline regions of the conductive or semiconductive polymer when it is present on the stamp during the contacting. In some embodiments, a crystalline region of a conductive or semiconductive polymer can be formed in the ink while on the stamp, and the crystalline region can be removed by heating, exposing the ink to a solvent, and combinations thereof prior to the contacting.

In some embodiments, maintaining the ink (i.e., the conductive or semiconductive polymer) in a fluidic, gelled or flexible state during at least the contacting can be done by maintaining the stamp, the substrate, or a combination thereof at a temperature of about 50° C. or more, about 60° C. or more, about 75° C. or more, about 85° C. or more, about 90° C. or more, about 100° C. or more, about 110° C. or more, about 120° C. or more, or about 150° C. or more during the contacting. Thus, in some embodiments, the process further comprises providing thermal energy to the substrate, the stamp, or a combination thereof during the contacting. In some embodiments, the contacting further comprises providing thermal energy to at least one of: the substrate, the stamp, and combinations thereof. In some embodiments, the providing thermal energy comprises heating at least one of the substrate, the stamp, and combinations thereof to a temperature of about 35° C. to about 150° C., about 35° C. to about 125° C., about 35° C. to about 125° C., about 35° C. to about 110° C., about 35° C. to about 100° C., about 35° C. to about 80° C., about 35° C. to about 50° C., about 50° C. to about 150° C., about 50° C. to about 125° C., about 50° C. to about 125° C., about 50° C. to about 110° C., about 50° C. to about 100° C., about 50° C. to about 80° C., or about 35° C.

The contacting transfers the ink from the at least one protrusion to the substrate and can be promoted by one or more interactions between the ink and the stamp, between the ink and the substrate, between the stamp and the substrate, and combinations thereof that promote adhesion of an ink to an area of a substrate. Not being bound by any particular theory, adhesion of an ink to an area of a surface can be promoted by gravity, a Van der Waals interaction, a covalent bond, an ionic interaction, a hydrogen bond, a hydrophilic interaction, a hydrophobic interaction, a magnetic interaction, and combinations thereof. Conversely, the minimization of these interactions between an ink and the surface of a stamp can facilitate transfer of the ink from the stamp to the substrate.

In some embodiments, contacting the stamp with a substrate can be facilitated by the application of pressure or vacuum to the backside of either or both the stamp and the substrate. In some embodiments, the application of pressure or vacuum can ensure that the ink is substantially removed from between the surfaces of the stamp and substrate. In some embodiments, the application of pressure or vacuum can ensure that there is conformal contact between the at least one protrusion of the stamp and the substrate. In some embodiments, the application of pressure or vacuum can minimize the presence of gas bubbles present between the stamp and the substrate, or gas bubbles present in the ink. Not being bound by any particular theory, the removal of gas bubbles can facilitate the reproducible formation of patterns having lateral dimensions of 100 μm or less.

The pressure applied to either of the backside of a stamp and/or the backside of the substrate during the contacting can be varied. In a preferable embodiment the pressure is applied uniformly across the surfaces that are contacted with one another. In some embodiments, a pressure of about 1 psi to about 200 psi, about 1 psi to about 100 psi, about 1 psi to about 50 psi, about 1 psi to about 20 psi, about 1 psi to about 10 psi, about 1 psi to about 5 psi, about 5 psi to about 200 psi, about 5 psi to about 100 psi, about 5 psi to about 50 psi, about 5 psi to about 20 psi, about 5 psi to about 10 psi, about 10 psi to about 200 psi, about 10 psi to about 100 psi, or about 10 psi to about 50 psi is applied. In some embodiments, a pressure of about 1 psi to about 4 psi is applied to the backside of the stamp during the contacting.

In some embodiments, the contacting is performed to pattern a flexible substrate. Not being bound by any particular theory, conformal contact between the face of the at least one protrusion and a flexible substrate can be enhanced by positioning the flexible substrate on a non-rigid backing material during the contacting. The non-rigid backing material permits conformal contact between the stamp and the flexible substrate even when the stamp is not substantially planar. The use of a non-rigid backing material behind a flexible substrate can be of particular use when a cylindrical stamp, a non-planar stamp, and other stamp geometries are utilized.

In some embodiments, the processes of the present invention are “low temperature” processes. As used herein, “low temperature” processing refers to those during which the substrate is maintained at a temperature of about 50° C. or less.

Thus, the present invention is also directed to a low-temperature process for forming a conductive or semiconductive polymer pattern on a substrate, the process comprising:
providing a stamp having a surface including at least one protrusion thereon, the protrusion being contiguous with and defining a pattern on the surface of the stamp,
wherein the at least one protrusion comprises an elastomer having a modulus of about 3 MPa or more;
wetting the stamp with a first solvent to provide a wetted stamp;
applying an ink comprising a conductive or semiconductive polymer and a solvent to the wetted stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer is maintained in a fluidic, gelled, or flexible state during the contacting, wherein a temperature of about 50° C. or less is maintained during the process, and wherein the conductive or semiconductive polymer pattern has an electron or hole mobility of about 10⁻⁶ cm²/V·s or more.

In some embodiments, the at least one protrusion comprises an elastomer having a surface free energy that is about 50% or less than a surface free energy of the substrate as described elsewhere herein.

In some embodiments, the at least one protrusion comprises an elastomer having a surface free energy of about 25 ergs/cm² to about 35 ergs/cm², as described elsewhere herein.

The coated stamp is contacted with the substrate for a period of time sufficient to transfer the conductive or semiconductive polymer to the substrate. The result of the contacting is the formation of a pattern comprising the conductive or semiconductive polymer on the substrate wherein the conductive or semiconductive polymer adheres to the first area and second area of the substrate in a pattern defined by the at least one protrusion on the stamp.

In some embodiments, the contacting is performed at room temperature. In some embodiments, the contacting step further comprises removing thermal energy from at least one of: the substrate, the stamp, and combinations thereof (i.e. cooling the stamp, the substrate, and combinations thereof).

The present invention is also directed to a process for patterning a substrate, the process comprising:
providing a substrate comprising a first area having a conductor and a second area having a dielectric;
providing a stamp having a surface including at least one protrusion thereon, the protrusion being contiguous with and defining a pattern on the surface of the stamp;
pre-treating the surface of the stamp to provide a pre-treated stamp;
applying an ink comprising a conductive or semiconductive polymer to at least the at least one protrusion of the pre-treated stamp to provide a coated stamp; and
contacting the coated stamp with the substrate for a period of time sufficient to transfer the conductive or semiconductive polymer to the substrate, wherein the conductive or semiconductive polymer adheres to the first area and second area of the substrate in a pattern defined by the surface of the stamp.

Thus, the processes of the present invention are suitable for patterning substrates such as thin film transistors, displays, electronic devices, and the like in which areas of the substrate have different surface free energy, different exposed functional groups, and the like.

Process products of the present invention include, but are not limited to, an organic thin film transistor, an organic light emitting diode, an organic field effect transistor, an organic molecular switch, an organic photovoltaic device, an organic light-emitting electrochemical cell, and combinations thereof.

In particular, the process products of the present invention include electronic devices in which the conductive or semiconductive properties of the polymer are essential for the proper functioning of the electronic devices. Therefore, the present invention also comprises preventing degradation of the conductive or semiconductive polymer during any aspect of the patterning, as well as any subsequent processes. Non-limiting examples of degradation that can occur to a conductive or semiconductive polymer include chemical or photo-initiated degradation of the conductive or semiconductive polymer during the applying and the contacting. In some embodiments, the preventing comprises shielding the conductive or semiconductive polymer from ultraviolet light. In some embodiments, the preventing comprises excluding oxidative reagents from the conductive or semiconductive polymer during the applying and the contacting.

In some embodiments, a process of the present invention comprises depositing an ink onto a surface of a metallized elastomeric stamp composition to form a coated stamp. The formation of a metal layer on a stamp surface can prevent penetration of an ink into the elastomeric portion of the stamp, which can cause buckling, cracking, wrinkling or other size distortions in the pattern of the ink that are transferred from the stamp to a substrate. Thus, coating an elastomeric stamp with a metal layer allows polymer patterns to be formed reliably, without visible buckling, cracking, or wrinkling.

In some embodiments, a SAM is formed on the surface of a metal prior to the applying. A SAM can enable facile application of an ink to a metallized stamp surface, and in some embodiments, facile transfer of an ink from the metallized stamp surface to a substrate. Not being bound by any particular theory, the presence of a mixture of hydrophobic and hydrophilic molecules in a SAM that coats a metal surface can assist both the wetting of a stamp by an ink, as well as the release and/or transfer of the ink from the stamp to a substrate. This is because to obtain efficient wetting and transfer a balance of hydrophilic and hydrophobic properties is typically required. For example, a fluorinated or perfluorinated SAM surface can provide excellent transfer properties; however, it can be difficult to uniformly apply an ink to such a surface, even using an ink comprising a solvent having a low polarity and a non-polar polymer. Thus, it can be advantageous to provide a stamp surface having a mixture of hydrophilic and hydrophobic groups, whereby the hydrophilic groups can provide uniform wetting of the stamp surface by an ink, and the hydrophobic groups can provide uniform and reproducible transfer of the ink from the stamp to a substrate.

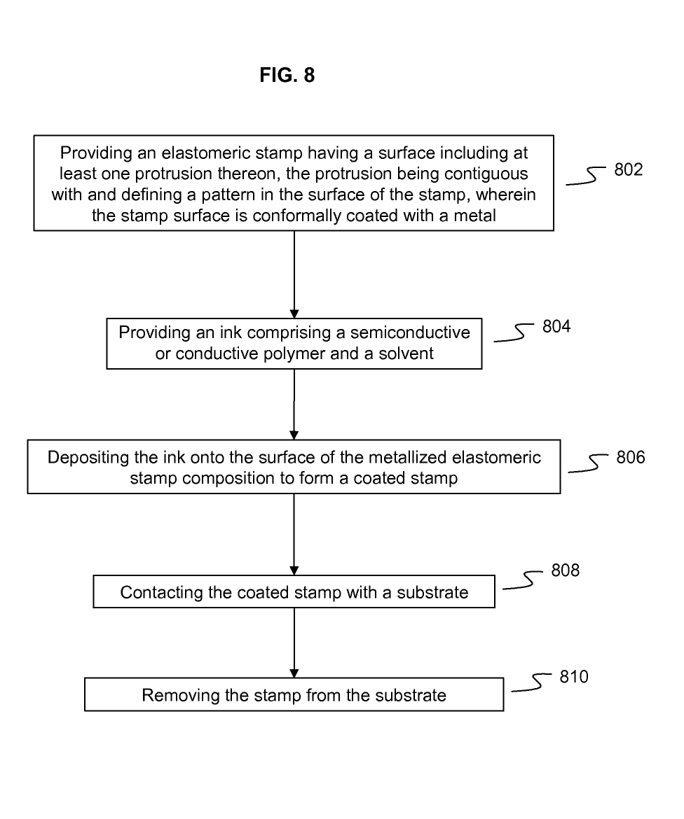

FIG. 8 provides a schematic flow diagram for a method of forming a pattern comprising polymer onto a substrate according to one embodiment of the invention. At block 802, a metallized elastomeric stamp composition having a surface including at least one protrusion thereon, the protrusion being contiguous with and defining a pattern in the surface of the stamp, wherein the stamp surface is conformally coated with a metal is provided. In one embodiment, the elastomeric stamp comprises a PDMS elastomer. In another embodiment, the elastomeric stamp comprises a first elastomer comprising H-PDMS and a second elastomer comprising PDMS.

At block 804, an ink is provided. In one embodiment, the ink comprises an organic semiconductor and a solvent. At block 806, the ink is deposited onto the surface of the metallized stamp to form a coated stamp. Depositing the ink 806 can be done by drop casting, spin casting, dip casting, spraying, vapor deposition, and the like, as would be apparent to a person of ordinary skill in the art of deposition and coating methodology.

In some embodiments, the coated stamp is dried. The coated stamp can be dried, for example, by evaporation of solvent from the ink. In some embodiments, a dried, coated stamp can be re-wetted with a solvent. In other embodiments, the coated stamp is not dried. For example, a coated stamp can be stored in a vapor-rich atmosphere or pre-swelled (i.e., exposed to a vapor and/or solvent capable of permeating the stamp).

At block 808, the coated stamp is contacted with a substrate. Contacting the coated stamp to the substrate results in transfer of the ink from the stamp to the substrate. In some embodiments, the contacting 808 with the substrate is performed for about 20 seconds to about 30 seconds while pressure is applied to the backside of the stamp. In other embodiments, contacting 808 is performed for 5 minutes or less, about 4 minutes or less, about 3 minutes or less, about 2 minutes or less, about 1 minute or less, or about 30 seconds or less.

In some embodiments, contacting 808 is performed at room temperature. In other embodiments, contacting 808 is performed at elevated temperatures. For example, one or both of the stamp and/or substrate can be heated to a temperature of about 30° C. to about 100° C. during the contacting. In other embodiments, contacting 808 is performed at decreased temperatures, for example at about 0° C. to about 20° C. In some embodiments, contacting 808 is performed at about atmospheric pressure. In some embodiments, the humidity of the environment during contacting 808 is controlled. For example, the humidity can be controlled at about 1% to about 50% humidity during the contacting.

In some embodiments, at block 810, the stamp and substrate are separated from contact with one another. Typically, the metal portion of the metallized stamp composition is retained on the stamp. However, in some embodiments it can be advantageous to transfer the metal from the stamp to the substrate.

In some embodiments, the viscosity of an ink is modified during one or more of an applying step, step, reacting step, or combinations thereof. For example, the viscosity of an ink can be decreased while applying the ink to the stamp to ensure uniform coating of the stamp by the ink. After contacting the coated stamp with a surface, the viscosity of the ink can be increased to ensure that the lateral dimensions of the protrusions on the stamp are transferred to the lateral dimensions of a pattern formed on the substrate.

Not being bound by any particular theory, the viscosity of an ink can be controlled by an external stimulus such as temperature, pressure, pH, electrical current, a magnetic field, and combinations thereof. For example, increasing the temperature of an ink will typically decrease its viscosity.

In some embodiments, the methods of the present invention further comprise reacting the ink with an area of the substrate. As used herein, “reacting” refers to initiating a chemical reaction comprising at least one of: reacting one or more components present in the ink with each other, reacting one or more components of an ink with a substrate. In some embodiments, reacting comprises applying an ink to a substrate (i.e., a reaction is initiated upon contact between an ink and a substrate). In some embodiments, reacting the ink comprises a chemical reaction between the ink and a functional group on the substrate. Not being bound by any particular theory, a component of an ink can react with a material by reacting on the substrate. In some embodiments, an ink reacts only the surface of a substrate (i.e., no penetration and reaction below the surface of the substrate). Such a patterning method can be useful for subsequent self-aligned deposition reactions on the substrate.

In some embodiments, reacting the ink comprises removing solvent from the ink. Not being bound by any particular theory, the removal of solvent from an ink can solidify the ink, or catalyze cross-linking reactions between components of an ink. For inks containing solvents with a low boiling point (e.g., b.p.<70° C.), the solvent can be removed without heating the substrate. Solvent removal can also be achieved by heating the substrate, the ink, the stamp, and combinations thereof.

In some embodiments, reacting the ink comprises cross-linking components within the ink. Cross-linking reactions can be intramolecular or intermolecular, and can also occur between a component and the substrate.

In some embodiments, reacting comprises exposing an ink to a reaction initiator. Reaction initiators suitable for use with the present invention include, but are not limited to, thermal energy, radiation, acoustic waves, an oxidizing or reducing plasma, an electron beam, a stoichiometric chemical reagent, a catalytic chemical reagent, an oxidizing or reducing reactive gas, an acid or a base (e.g., a decrease or increase in pH), an increase or decrease in pressure, an alternating or direct electrical current, agitation, sonication, friction, and combinations thereof. In some embodiments, reacting comprises exposing an ink to multiple reaction initiators.

Radiation suitable for use as a reaction initiator can include, but is not limited to, electromagnetic radiation, such as microwave light, infrared light, visible light, ultraviolet light, x-rays, radiofrequency, and combinations thereof.

In some embodiments, the stamp is removed before reacting the ink. In some embodiments, the stamp is removed after reacting the ink. Not being bound by any particular theory, leaving the stamp in place during the reacting step can help to ensure reproducible patterns are produced with the desired lateral dimensions. For example, removing the stamp after the reacting can ensure that the ink does not spread across the surface prior to or during reacting, thereby retaining the lateral dimensions of the at least one protrusion.

Only the ink coating on the face of the at least one protrusion is transferred from the stamp to the substrate during the contacting. Thus, in some embodiments an ink coating remains on at least a portion of the stamp that is not transferred to the substrate during the contacting. Therefore, in some embodiments the process further comprises removing an ink coating from at least a portion of the stamp surface after the contacting. Suitable processes for the removing include, but are not limited to, washing, dissolving, blowing, peeling, scraping, melting, and the like, and combinations thereof.

In some embodiments, an ink coating that is not transferred from the stamp to a substrate is recycled. For example, an ink coating can be removed from the stamp, optionally purified, optionally dried, and mixed with the appropriate amounts of a solvent to provide a recycled ink. The recycled ink can be separately packaged or contained prior to application to a stamp surface, or the recycled ink can be combined into a common ink reservoir for use, e.g., in continuous printing processes.

### Kits

The present invention is also directed to a kit for patterning a polymer onto a substrate, the kit comprising:
(a) a metallized elastomeric stamp composition having a surface including at least one protrusion thereon, the protrusion being contiguous with and defining a pattern on the surface of the stamp, wherein the stamp surface is conformally coated with a metal, and wherein at least a portion of the metal is covered by a self-assembled monolayer, the self-assembled monolayer being covalently attached to the metal coating;
(b) an ink comprising a polymer coating the stamp surface; and
(c) instructions directed to patterning a substrate using the metallized elastomeric stamp composition.

The present invention is also directed to a kit for patterning a polymer onto a substrate, the kit comprising:
(a) an elastomeric stamp composition comprising a first elastomer and a second elastomer, wherein the first elastomer coats the second elastomer to form an outer surface thereon, the surface including at least one protrusion thereon, the protrusion being contiguous with and defining a pattern on the surface of the first elastomer;
(b) an ink comprising a polymer coating the surface of the stamp; and
(c) instructions directed to patterning a substrate using the heterogeneous elastomeric stamp composition.

In some embodiments, the kit further comprises instructions incorporated in a booklet, or alternatively, printed on the top surface of the removable backing layer and/or the rigid or semi-rigid support.

In some embodiments, the kit further comprises a non-permeable seal surrounding an outer edge of the elastomeric material. The non-permeable seal can prevent, for example, ambient vapors and gases from permeating the elastomeric material, and increase the shelf life of the kit. Additionally, the non-permeable seal can prevent an ink from escaping from the kit during storage, as well as improving the stability of an ink.

The kits of the present invention comprise instructions relating to methods of using the kits to form polymeric patterns on a substrate. In some embodiments, the instructions can comprise a label or other printed matter. “Printed matter” can be, for example, one of a book, booklet, brochure or leaflet. Possible formats include, but are not limited to, a bullet point list, a list of frequently asked questions (FAQ) or a chart. Additionally, the information to be imparted can be illustrated in non-textual terms using pictures, graphics or other symbols. For example, printed matter can be in a form prescribed by a governmental agency regulating the manufacture, use or sale of chemical reagents (e.g., a Materials Safety Data Sheet), which notice reflects classification of any chemicals included with the kit. The printed matter can also contain information on the dangers associated with using the kit. In some embodiments, printed matter can be accompanied by a pre-recorded media device.

A “pre-recorded media device” can be, for example, a visual media device, such as a videotape cassette, a DVD (digital video disk), filmstrip, 35 mm movie or any other visual media device. Alternately, a pre-recorded media device can be an interactive software application, such as a CD-ROM (compact disk-read only memory) or floppy disk. Alternately, a pre-recorded media device can be an audio media device, such as a record, audiocassette or audio compact disk. The information contained on a pre-recorded media device can describe the use of the kit of the present invention for patterning a substrate with a polymer.

In some embodiments, the instructions are presented in a format chosen from: an English-language text, a foreign-language text, a visual image, a chart, a telephone recording, a website, access to a live customer service representative, and any other format that would be apparent to one of ordinary skill in the art. In some embodiments, the instructions include a direction for use, appropriate age use, a warning, a telephone number or a website address.

### EXAMPLES

The controlled, accurate, high-volume patterning of substrates (e.g., pre-fabricated circuits) with conductive and semiconductive or semiconductive polymers is important for the development of electrophoretic display devices and a range of other flexible electronics applications. Existing technologies such as ink-jet printing cannot controllably and reproducibly form these pattern at sufficiently high resolution. Soft Lithography is a leading patterning approach for today's commercial requirements and for the higher resolution requirements of the future.

In exemplary embodiments, the present invention provides methods for soft lithographic transfer of conductive or semiconductive polymers to substrates, for example, polyimide (“PI”) and silver (“Ag”)-coated polycarbonate (PC) substrates.

### Example 1

Non-functionalized elastomeric stamps comprising an elastomer (i.e., PDMS, available as SYLGARD® 184, Dow Corning Corp. Midland, Mich.) were prepared by a replica molding process, as described in U.S. Pat. Nos. 5,512,131; 5,900,160; 6,180,239; and 6,776,094; and pending U.S. application Ser. No. 10/766,427, all of which are incorporated herein by reference in their entirety.

### Example 2

A non-functionalized elastomeric stamp was prepared as in Example 1 using PDMS as the elastomer. The stamp was then functionalized by exposure to an air plasma for 1 minute, followed by treatment with a fluorinated silane ((tridecafluoro-1,1,2,2-tetrahydrooctyl) trichlorosilane). The air plasma treatment oxidizes the stamp surface to form, for example, Si—OH groups and regions of SiO₂, which is more reactive towards the fluorosilane than a non-plasma treated stamp surface. However, the oxidized stamp surface is also more susceptible to cracking and fracture during subsequent processing. For example, when an ink comprising a polymer (arylene vinylene polymer) and a solvent (toluene) were deposited onto the functionalized stamp, cracks began to form on the stamp surface. As the ink was deposited on the face of the at least one protrusion, cracks in the stamp were replicated in the ink layer.

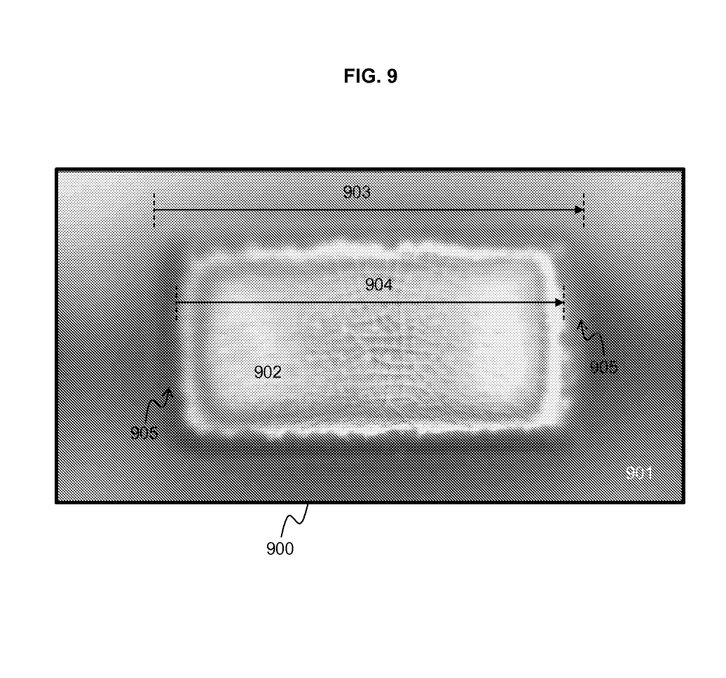

An optical microscope image of the dry, coated stamp surface is presented graphically in FIG. 9. Referring to FIG. 9, an optical microscope image, 900, shows the functionalized stamp surface, 901, having a polymeric pattern thereon, 902. As shown, the polymeric pattern of the ink has numerous cracks and defects.

Pre-treating the PDMS stamp with a fluorinated-SAM results in pattern wherein the majority of the surface area of each pixel is transferred to the substrate, but the conductive or semiconductive polymer does not fully coat the complete lateral dimension of the at least one protrusion, 903. As shown in FIG. 9, the lateral dimension of the ink, 904, on the at least one protrusion leaves an edge, 905, of the at least one protrusion uncoated by the ink. This can result in a pattern having slightly smaller dimensions than the dimensions of the at least one protrusion on the stamp.

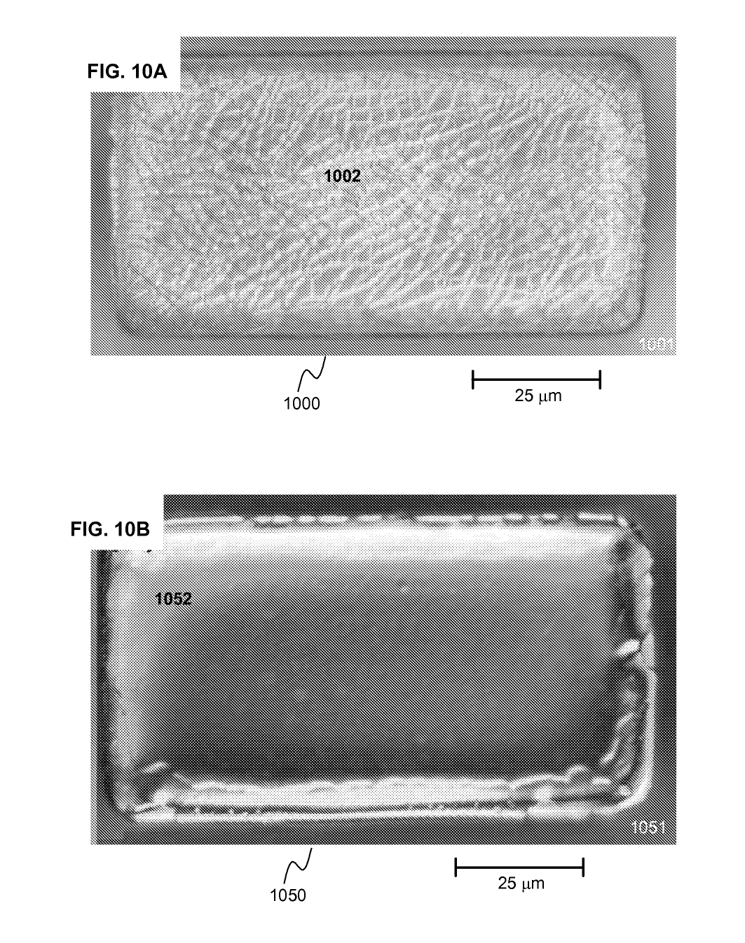

A second optical microscope image of a dry, coated stamp surface prepared by the procedure of this Example is presented in FIG. 10A. Referring to FIG. 10A, an optical microscope image, 1000, shows the functionalized stamp surface, 1001, having a polymeric pattern thereon, 1002. As shown, the polymeric pattern of the ink has numerous cracks and defects. The cracking observed in the ink layer is not a result of the ink layer itself cracking, but a result of the development of cracks in the stamp surface. Because the development of cracks in the stamp surface is a result of both plasma treating the stamp surface followed by swelling of the stamp induced by a solvent present in the ink, simply depositing the ink on a stamp that has not been plasma treated will not induce cracking in the stamp or in the ink coating.

### Example 3

A non-functionalized elastomeric stamp was prepared as in Example 1 using PDMS as the elastomer. The stamp was then functionalized by exposure to an oxygen plasma for 1 minute followed by electroless deposition of a conformal metal layer (Ag) onto the stamp surface. Perfluorodecanethiol was applied to the metal surface to form a fluorinated SAM thereon. An ink comprising a conductive or semiconductive polymer (arylene vinylene polymer) and a solvent (toluene) was then applied to the stamp surface. Excess of the ink was then removed from the stamp by spinning the stamp at about 3,000 rpm for several seconds. The ink was then allowed to dry on the stamp surface.

An optical microscope image of the coated stamp surface is presented graphically in FIG. 10B. Referring to FIG. 10B, an optical microscope image, 1050, shows the functionalized stamp surface, 1051, having a polymeric pattern thereon, 1052. As shown, the polymeric pattern deposited onto the metallized stamp composition of Example 2 exhibits none of the defects and/or cracking that were present in the pattern deposited onto the stamp prepared according to Example 1.

### Example 4

A master was prepared as described in U.S. Pat. Nos. 5,512,131; 5,900,160; 6,180,239 and 6,776,094. The master was coated with high-density PDMS (“H-PDMS”, coating thickness was approximately 100 μm). The H-PDMS layer was partially cured in an oven at 60° C. to 70° C. for about 20 minutes and then cooled to room temperature. A PDMS precursor (SYLGARD® 184) was then applied to the backside of the partially cured H-PDMS to form an elastomeric stamp, which was then cured in an oven at 60° C. to 70° C. for 12 to 18 hours. The stamp was then separated from the master to provide a stamp including a surface having at least one protrusion thereon. In some embodiments, a glass backplane was further adhered to the backside of the PDMS layer. An ink comprising a conductive or semiconductive polymer (arylene vinylene polymer) and a solvent (toluene) was then applied to the stamp surface having the at least one protrusion thereon. Excess ink was removed from the stamp by spinning the stamp at about 3,000 rpm for several seconds.

### Example 5

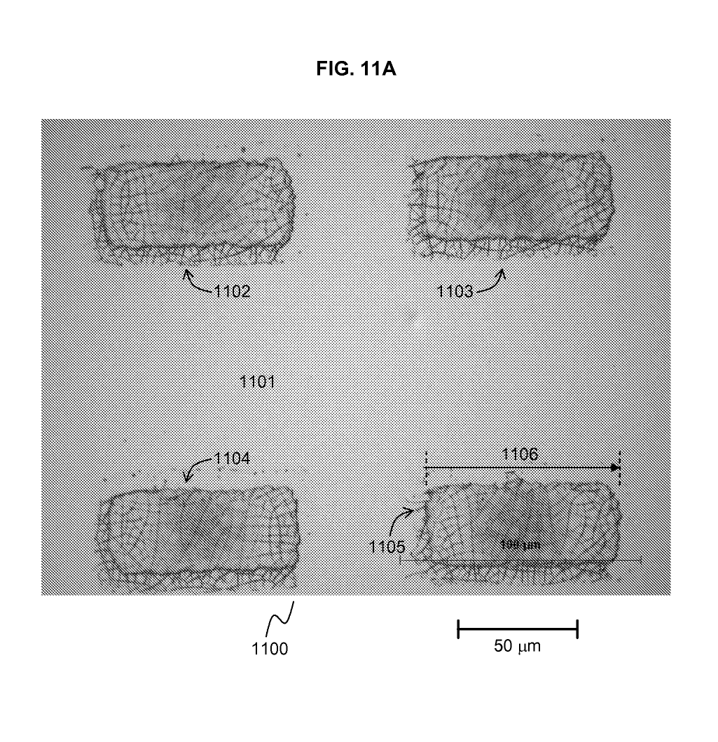

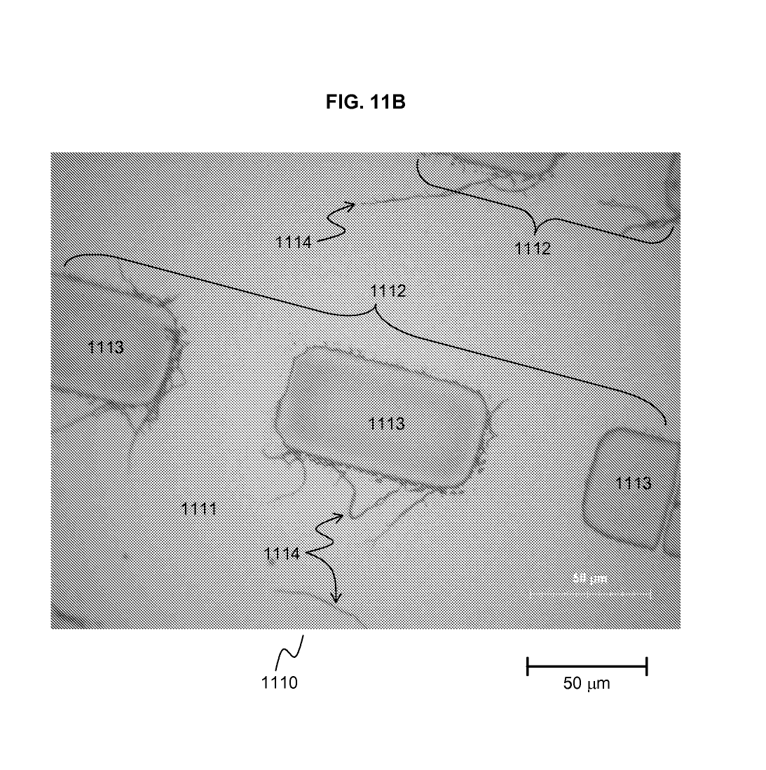

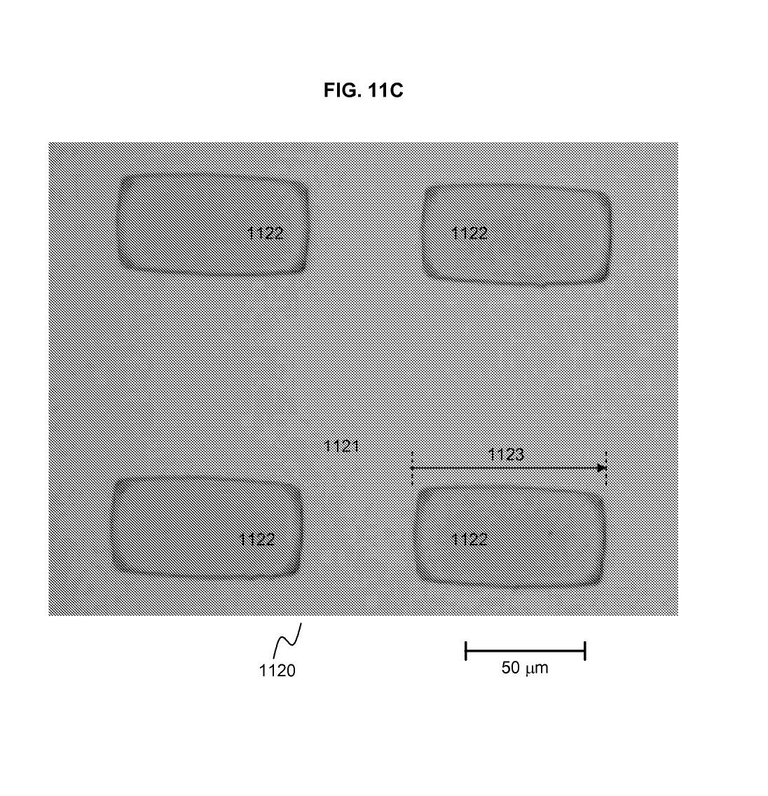

Conductive or semiconductive polymer patterns were formed on substrates (silver-coated polycarbonate, “Ag-coated polycarbonate”) using the ink-coated stamp compositions prepared in Examples 2-4. The patterns were formed by contacting the ink-coated stamps with a substrate at room temperature for 10-30 seconds, which was a sufficient amount of time to transfer the conductive or semiconductive polymer from the stamp to the substrate. The conductive or semiconductive polymer patterns formed using the stamps prepared in Examples 2-4 are presented graphically in FIGS. 11A, 11B and 11C, respectively.

Prior to patterning, the substrates (e.g., polyimide, Ag-coated polycarbonate, etc.) were stored in an Argon environment. Immediately before patterning the substrates were rinsed with iso-propanol, dried under a stream of dry nitrogen, and treated with hexamethyldisilazane (“HMDS”) by placing the clean substrates on a wire mesh support on a glass enclosure containing several drops of HMDS. The substrates were incubated in HMDS-containing glass enclosure for at least five minutes, and then rinsed with iso-propanol and dried with dry nitrogen.

A pattern was prepared using the inked stamp of Example 2. Referring to FIG. 11A, an optical microscope image, 1100, shows a Ag-coated polycarbonate substrate, 1101, having a conductive or semiconductive polymer pattern thereon, 1102, 1103, 1104 and 1105. As shown, the conductive or semiconductive polymer pattern has numerous cracks and defects. The cracks and defects observed in the pattern on the substrate were present in the ink coating on the stamp surface (see FIGS. 9 and 10A). Additionally, the feature size (i.e., a lateral dimension, 1106) of the pattern are inconsistent between pixels 1102, 1103, 1104 and 1105.

A pattern was prepared using the inked stamp of Example 3. Referring to FIG. 11B, an optical microscope image, 1110, shows a Ag-coated polycarbonate substrate, 1111, having a polymeric pattern thereon, 1112. As shown, the polymeric pattern lacks widespread defects and cracks in the body of the polymeric pattern, 1113. However, defects on the periphery of the pattern, 1114, having a string-like appearance can be seen. These are likely a result of incomplete removal of excess of the ink from the surface of the coated stamp prior to contacting the stamp with the substrate. The pattern has a minimum lateral dimension of about 40 μm. The minimum lateral dimensions of the pattern are consistent, compared the pattern presented in FIG. 11A, which did not have consistent minimum lateral dimensions across the substrate.

A pattern was prepared using the inked stamp of Example 4. Referring to FIG. 11C, an optical microscope image, 1120, shows a silver-coated polycarbonate substrate, 1121, having a pattern comprising a conductive or semiconductive polymer thereon, 1122. As shown, the polymeric pattern contains virtually no cracks or defects. The pattern has a minimum lateral dimension of about 40 μm. Additionally, the feature size (i.e., a lateral dimension, 1123) of the pattern is consistent across the entire field of the image.

Not being bound by any particular theory, a stamp surface that includes at least one indentation having a comprising an elastomer having a Modulus of about 3 MPa or more and a surface energy of about 25 ergs/cm² to about 35 ergs/cm² enables both efficient wetting of the at least one protrusion by the ink, as well as efficient transfer of the ink to the substrate without pre-treating the stamp surface. Eliminating the pre-treating of the stamp results in greatly improved performance such as reducing cracking in the patterns and increased stamp lifetime.

### Example 6

### i. Approach

In exemplary embodiments, direct printing is used to form a pattern comprising a conductive or semiconductive polymer, allowing for simultaneous deposition and patterning of the conductive or semiconductive polymer on PI and Ag substrates in a single processing step. In direct printing, a stamp containing the desired features is coated with an ink that includes a conductive or semiconductive polymer. The ink-coated stamp is then contacted against the substrate to be patterned. In the regions of direct contact between the raised features of the stamp and the substrate, the conductive or semiconductive polymer is transferred to the substrate. Suitable stamp materials for printing a conductive or semiconductive polymer on PI and Ag substrates include, but are not limited to, surface-modified PDMS and an ultraviolet (UV)-curable epoxy.

### ii. Stamp & Substrate Preparation

For example, in direct printing, the stamp suitably has some affinity for the ink, or at least the conductive or semiconductive polymer, so that the ink will uniformly wet at least a surface of a protrusion of the stamp during inking. This affinity can be tuned so that it is less than the affinity of ink, or at least the conductive or semiconductive polymer, for the substrate. Physical characteristics of the stamp, such as Young's Modulus and hardness, relate to the ability to form good contact between stamp and substrate, as well as overall deformation during printing.

A variety of different stamp materials are useful in the practice of the present invention, including PDMS, urethanes, epoxies, and other polymers. For the PDMS stamps and Ag-coated polycarbonate substrates, the surface chemistry is suitably modified with hydrophobic, hydrophilic, conjugated, or fluorinated moieties, depending on the requirements.

### iii. Printing with PDMS Stamps

Patterning of the conductive or semiconductive polymer is suitably performed by direct printing with surface-modified PDMS stamps. The surface of the PDMS stamp was modified with a fluorosilane to allow easy release of the conductive or semiconductive polymer from the PDMS stamp. The conductive or semiconductive polymer was dissolved in a solvent and deposited on the modified surface of the PDMS stamp. In some embodiments, the surface of the PI and Ag substrates were also modified to improve adhesion between the conductive or semiconductive polymer and the substrate of interest. In some embodiments, the PI substrate is modified with 4-phenyl butyl trichlorosilane (“PBT”) and the Ag substrate is modified with pentafluorobenzenethiol (“PFT”). The ink-coated PDMS stamp is then contacted with the modified PI or Ag substrate at 100° C. to transfer the conductive or semiconductive polymer from the raised regions of the stamp (i.e., the at least one protrusion of the stamp) to the substrate.

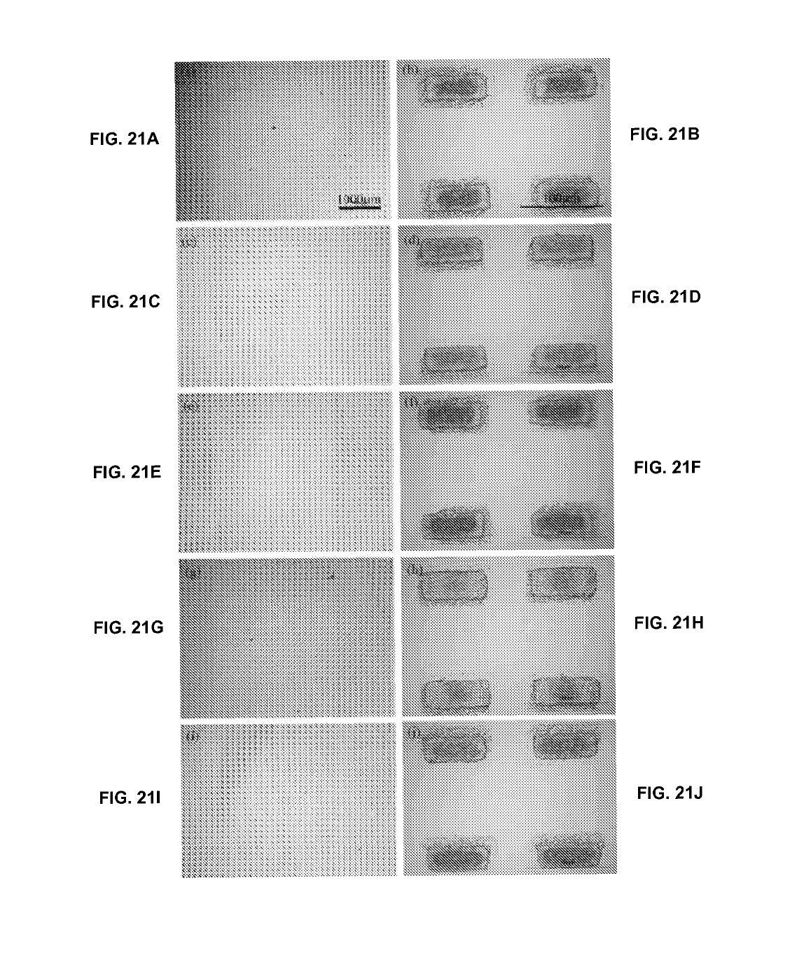

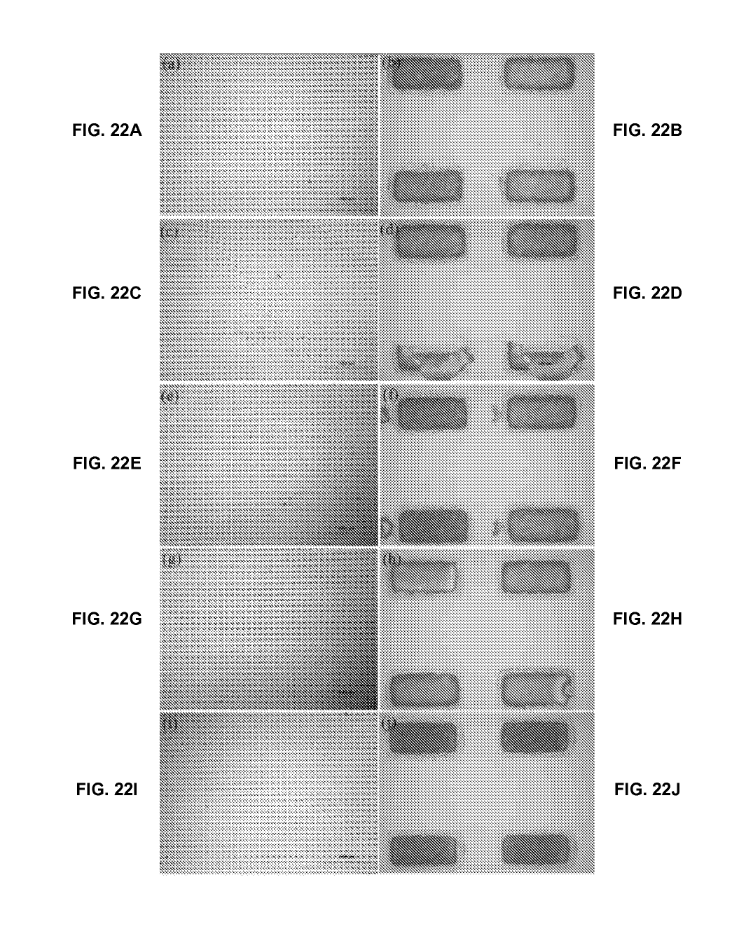

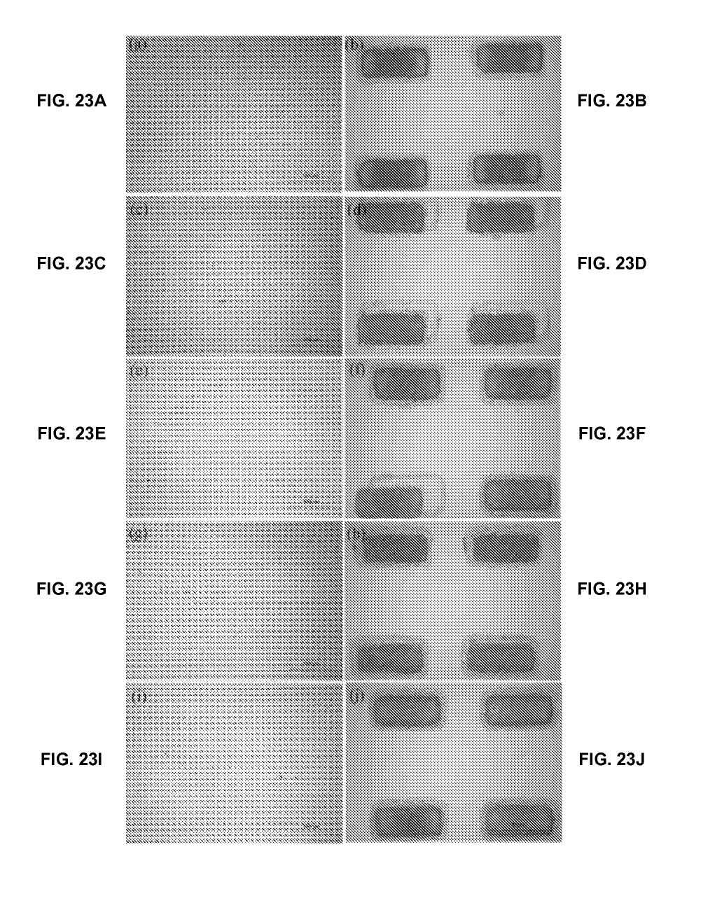

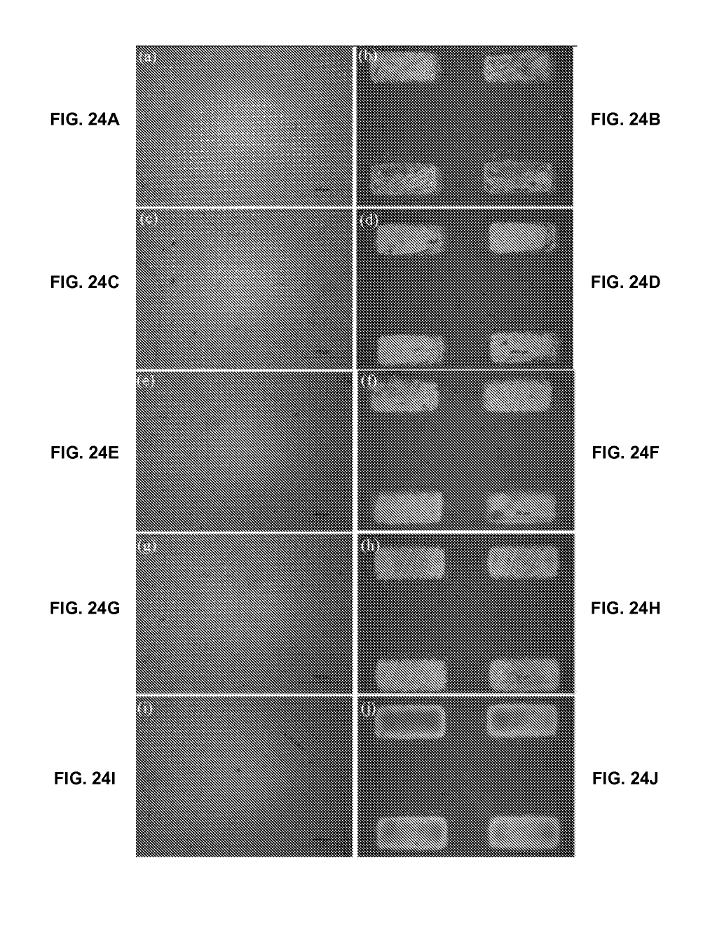

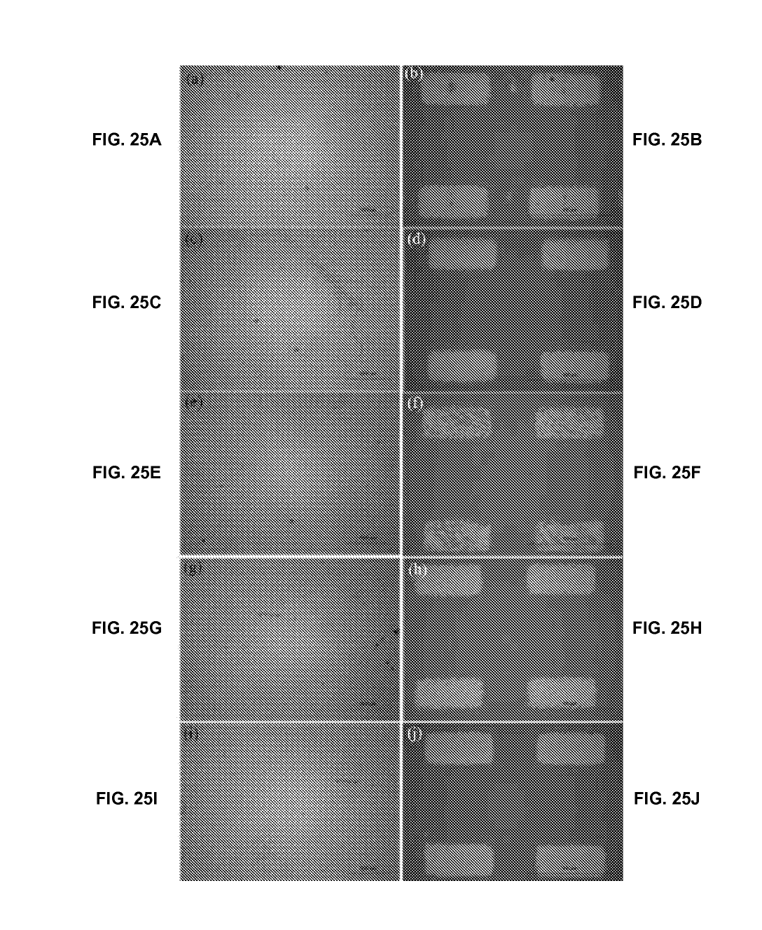

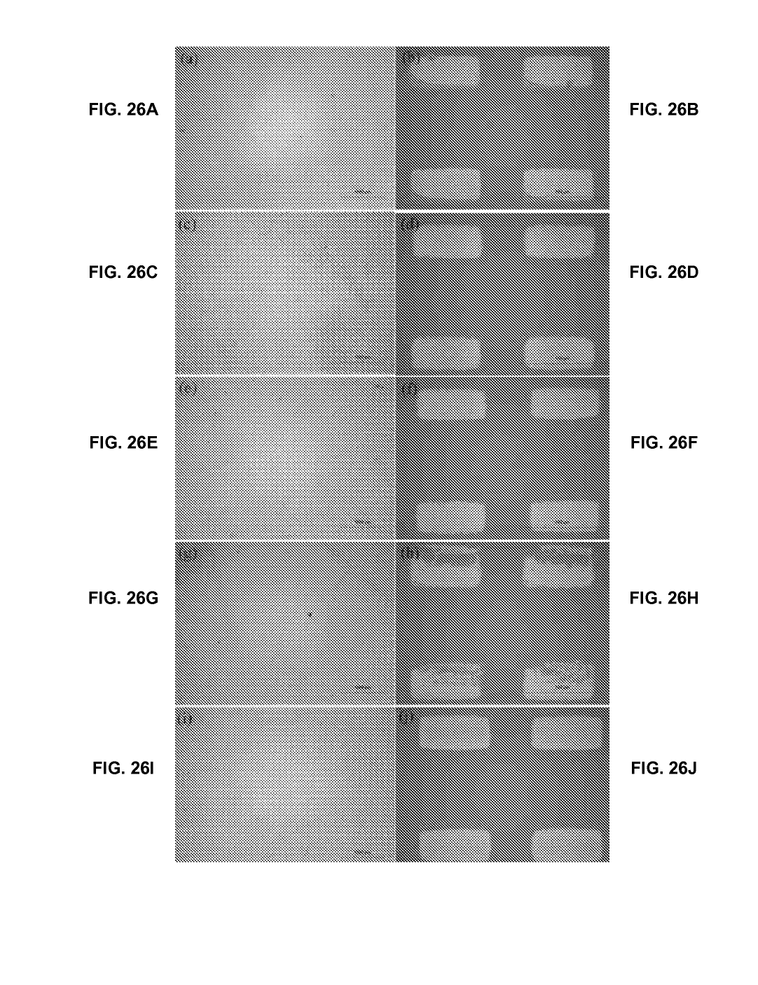

Three exemplary samples were printed on Ag substrates (“samples 1-3”) and three exemplary samples were printed on PI substrates (“samples 4-6”) using the methods described herein. For both PI and Ag-coated substrates, a rectangular array of continuous conductive or semiconductive polymer pixels over the desired 1 cm×1 cm area were patterned. Detailed optical micrograph images of each of the printed samples 1-6 are shown in FIGS. 21A-21J, 22A-22J, 23A-23J, 24A-24J, 25A-25J and 26A-26J, respectively.

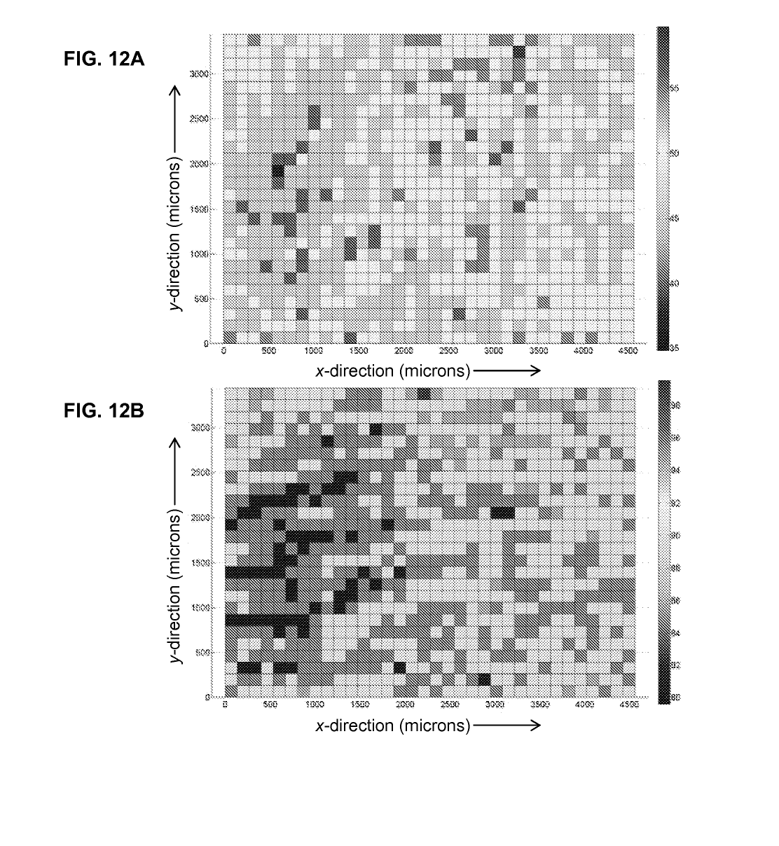

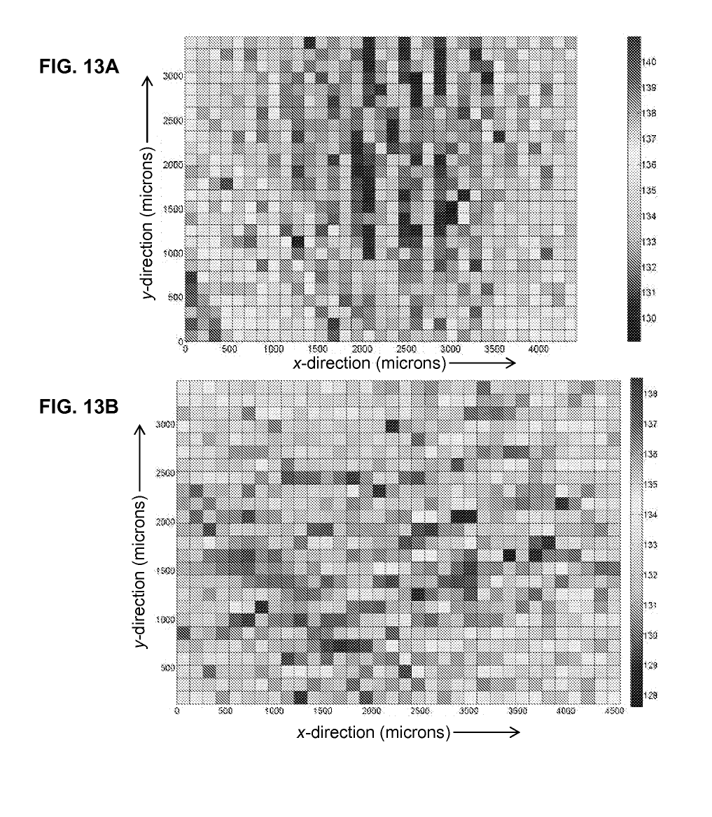

The distributions of pixel dimensions and spacings for sample 1, a conductive or semiconductive polymer printed on a Ag-coated substrate, are shown in FIGS. 12A and 12B and FIGS. 13A and 13B. Referring to FIG. 12A, the average pixel width was 47.8±3.6 μm. Referring to FIG. 12B, the average pixel length was 87.9±3.6 μm. Referring to FIG. 13A, the average spacing between pixels was 133.9±1.9 μm in the horizontal direction (i.e., the “x-direction”). Referring to FIG. 13B, the average spacing between pixels was 132.1±1.6 μm in the vertical direction (i.e., the “y-direction”). These pixel dimensions are representative of all the printed samples.

Additionally, the average thickness of the printed pixels for each sample was measured by stylus profilometry, the results of which are listed in Table 2. To determine the average pattern thickness for each sample, 7 pixels on each sample were randomly selected and measured, and the results were numerically averaged.

TABLE 2
Average pattern thickness of all printed samples patterned
with a conductive or semiconductive polymer.

| | Average thickness |
|---|---|
| Sample | (nm) |
| 1 | 97.1 ± 19.0 |
| 2 | 127.4 ± 7.1 |
| 3 | 65.6 ± 10.1 |
| 4 | 99.9 ± 10.8 |
| 5 | 87.0 ± 19.8 |
| 6 | 86.0 ± 14.3 |

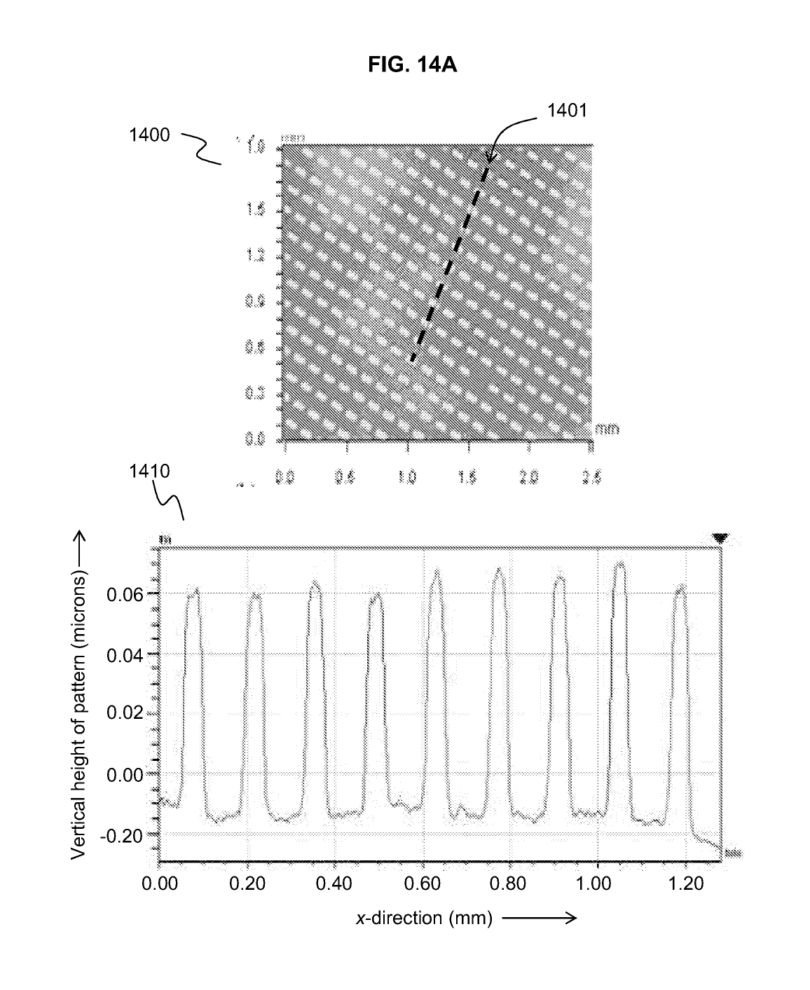

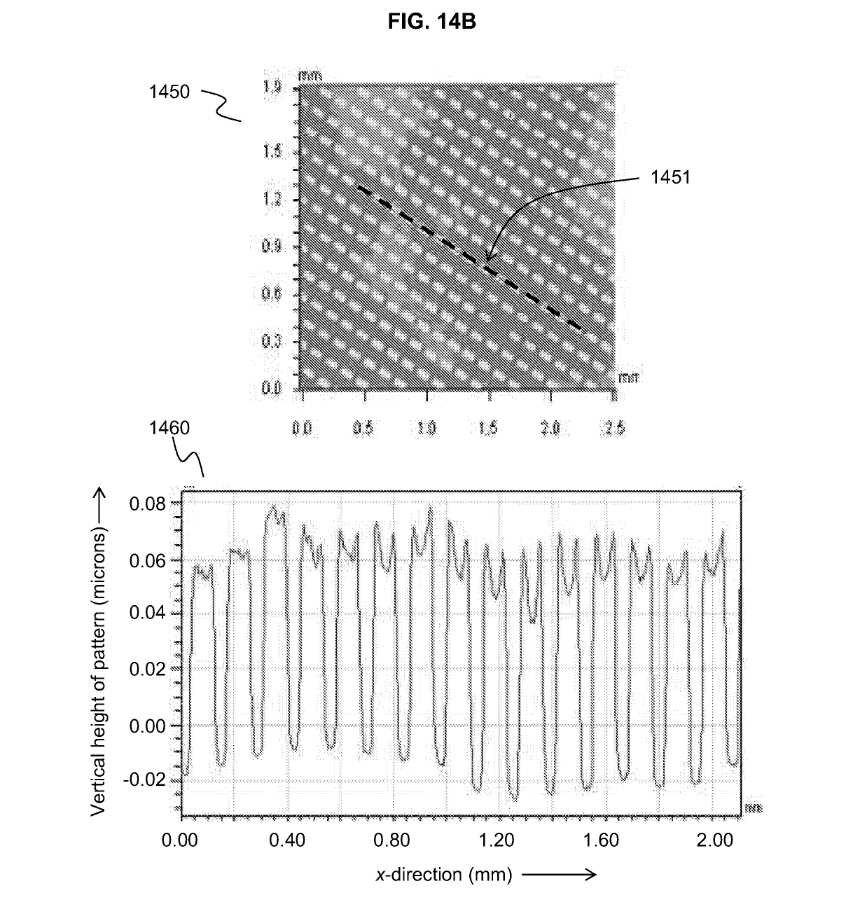

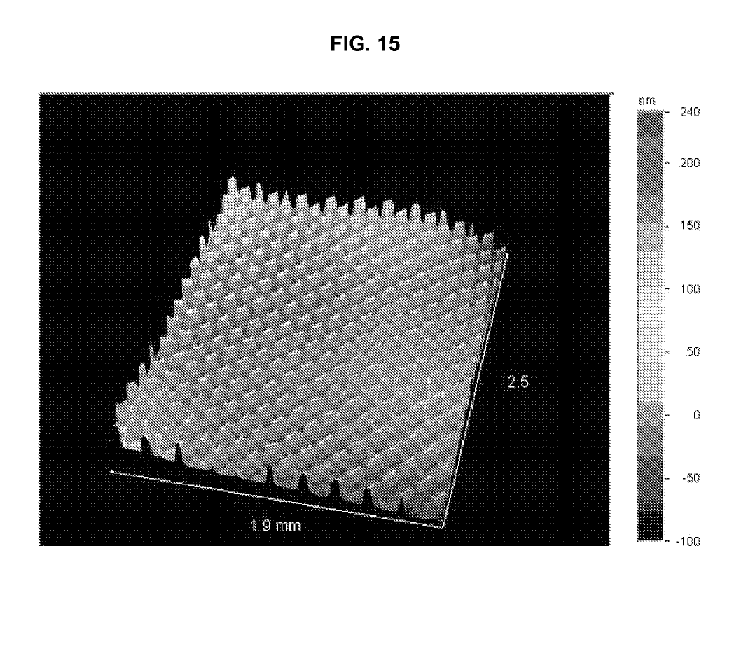

The conductive or semiconductive polymer pattern thickness can be further tuned by changing the concentration of the conductive or semiconductive polymer in xylene and the spin speed. To characterize the uniformity of the conductive or semiconductive polymer pattern thickness across the printed samples, optical profilometry was performed on samples printed on PI. Optical profilometry profiles of samples 4 and 5 are shown in FIGS. 14A and 14B and FIG. 15, respectively. Referring to FIG. 14A, a stylus profiled the pattern of sample 4, 1400, along a first line, 1401, the results of which are displayed in plot 1410. A second scan was then performed in a second direction that was rotated 90° relative to the first scan. Referring to FIG. 14B, a stylus profiled the pattern of sample 4, 1450, along a first line, 1451, the results of which are displayed in plot 1460. The line scans displayed in FIGS. 14A and 14B indicate that pixel width and pattern thickness are uniform across a column of pixels.

FIG. 15 provides a three-dimensional optical profile of sample 5, and illustrates that the patterns formed by the present invention have a uniform thickness across at least a 1.9 mm×2.5 mm printed area.

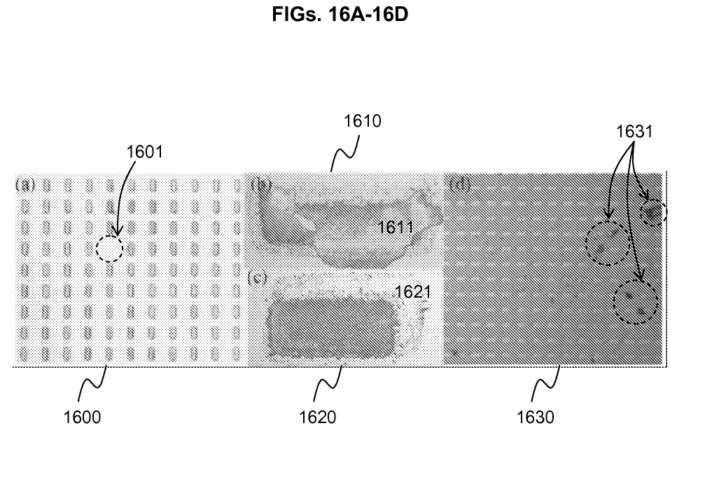

Inspection of the printed samples with an optical microscope reveals several defects that are present in the printed samples, such as missing pixels, double printing/deformed features, and surface contamination. Examples of these defects are provided in FIGS. 16A-16D. Referring to FIG. 16A, an optical microscope image of a patterned silver-coated substrate is provided, 1600. The pattern includes a missing pixel, 1601, in the pattern array. Missing pixel defects can result from, for example, incomplete coating of a stamp with an ink or a failure of the conductive or semiconductive polymer to transfer from the at least one protrusion to the substrate during the contacting. In some embodiments, missing pixel defects can be reduced by selecting an elastomer having a surface free energy less than that of the substrate, and which is sufficient to be uniformly wetted by an ink. Additional pre-treating processes can be further utilized to modify the surface of a stamp to improve the wetting and adhesion of a conductive or semiconductive polymer to a stamp and/or improve transfer of the conductive or semiconductive polymer to the substrate.

Referring to FIG. 16B, an optical microscope image of a patterned silver-coated substrate is provided, 1610. The pattern includes a deformed pixel, 1611. In some embodiments, deformed pixel defects can arise, for example, due to poor transfer of the conductive or semiconductive polymer from the at least one protrusion of the stamp to the substrate, from non-uniform application of pressure to the stamp and/or the substrate during the contacting, movement of the stamp during the contacting, and combinations thereof.

Referring to FIG. 16C, an optical microscope image of a patterned silver-coated substrate is provided, 1620. The pattern includes a double printed pixel, 1621. Double printing can arise, for example, from a failure to properly align a stamp with an area of the substrate prior to the contacting, from non-uniform application of pressure to the stamp and/or the substrate during the contacting, movement of the stamp during the contacting, and combinations thereof.

Not being bound by any particular theory, movement of the stamp during the contacting can particularly manifest itself as a shadow effect around individual pixels. Both pattern deformation (FIG. 16B) and double printing (FIG. 16C) can be avoided by mechanizing the patterning process so that the pressure and position of the stamp is constant.

Referring to FIG. 16D, an optical microscope image of a patterned polyimide substrate is provided, 1630. The pattern includes areas of the substrate that exhibit surface contamination, 1631. Surface contamination can arise, for example, from a failure to clean the substrate prior to the contacting, from an incomplete cleaning of the substrate, from contamination of the substrate after a cleaning pre-treatment and prior to the contacting, and combinations thereof. Exemplary patterning conditions include ambient conditions in a non-cleanroom environment, as well as the use of a cleanroom to minimize surface contamination.

Additional patterning defects can arise from a failure to retain the feature size of the at least one protrusion in a lateral dimension of the pattern on the substrate. This can be manifest as one or more lateral dimensions of the pattern, or the spacing between printed features of the pattern being slightly out of specification. Three factors have been identified that can lead to pattern distortion: swelling of the stamp by a solvent during the applying of an ink to the stamp, incomplete coating of the stamp with the ink, and a failure to provide uniform pressure to the stamp and/or substrate during the contacting. The swelling and incomplete ink coating of the stamp can be largely eliminated by properly selecting a material and/or pre-treating of the stamp. In addition to those examples described herein, further modification of the surface chemistry of a stamp can be utilized to achieve more complete and uniform ink coverage on the stamp, and in particular the at least one protrusion of the stamp. Furthermore, as discussed above, distortions that arise as a consequence of non-uniform hand-pressure during the contacting can be minimized with machine stamping. Machine stamping reproducibly and uniformly applies pressure across the stamp to minimize feature distortion.

### iv. Printing with Epoxy Stamps

To demonstrate the materials flexibility of soft lithographic printing, epoxy stamps were used to successfully directly pattern conductive or semiconductive polymers on substrates. In exemplary embodiments, an ink was spin-coated on an epoxy stamp and then contacted with phenyl butyl trichlorosilane (“PBT”) functionalized-PI or pentafluorobenzenethiol (“PFT”) functionalized-Ag substrates at about 150° C. Removing the epoxy stamp selectively transferred the conductive or semiconductive polymer to the substrate from the protrusions on the stamp. The amount of material transferred and the uniformity of the resulting pattern was observed to vary depending on the planarity and rigidity of the epoxy stamp.

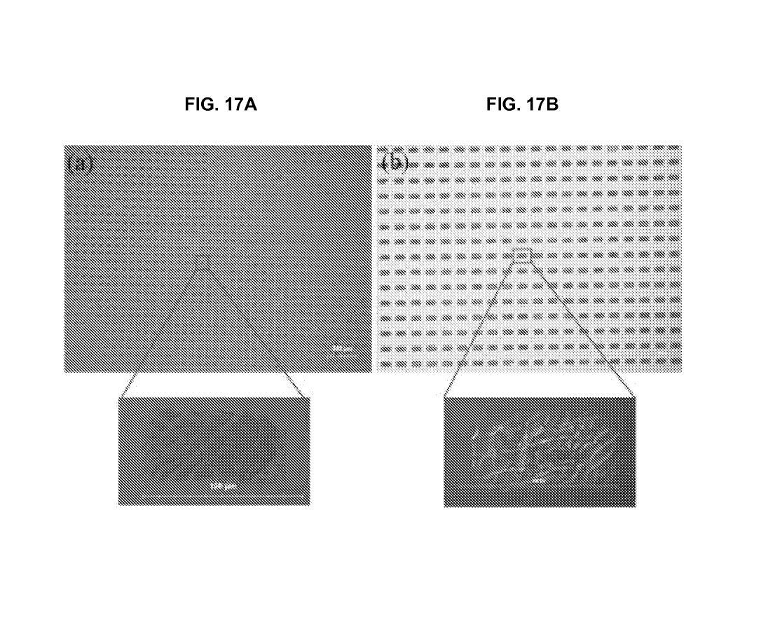

Epoxy stamps having rectangular protrusions were used to pattern PI and Ag substrates with a conductive or semiconductive polymer, but resulted in incomplete transfer of the conductive or semiconductive polymer to the substrate, and produced non-uniform patterns over the 1 cm×1 cm substrate area (see FIG. 17A). Not being bound by any particular theory, poor printing over large areas likely results from a non-uniform epoxy stamp surface and difficulty forming and/or maintaining conformal contact between the epoxy stamp and the substrates. This is because the epoxy stamp is more rigid and less flexible than a PDMS stamp, and thus does not readily conform to the PI and Ag substrates. As a consequence, only small regions of the conductive or semiconductive polymer are transferred from the epoxy stamp to these substrates. To improve the large-area printing, conformal epoxy stamps were prepared. Large-area printing, as shown in FIG. 17B, has been achieved.

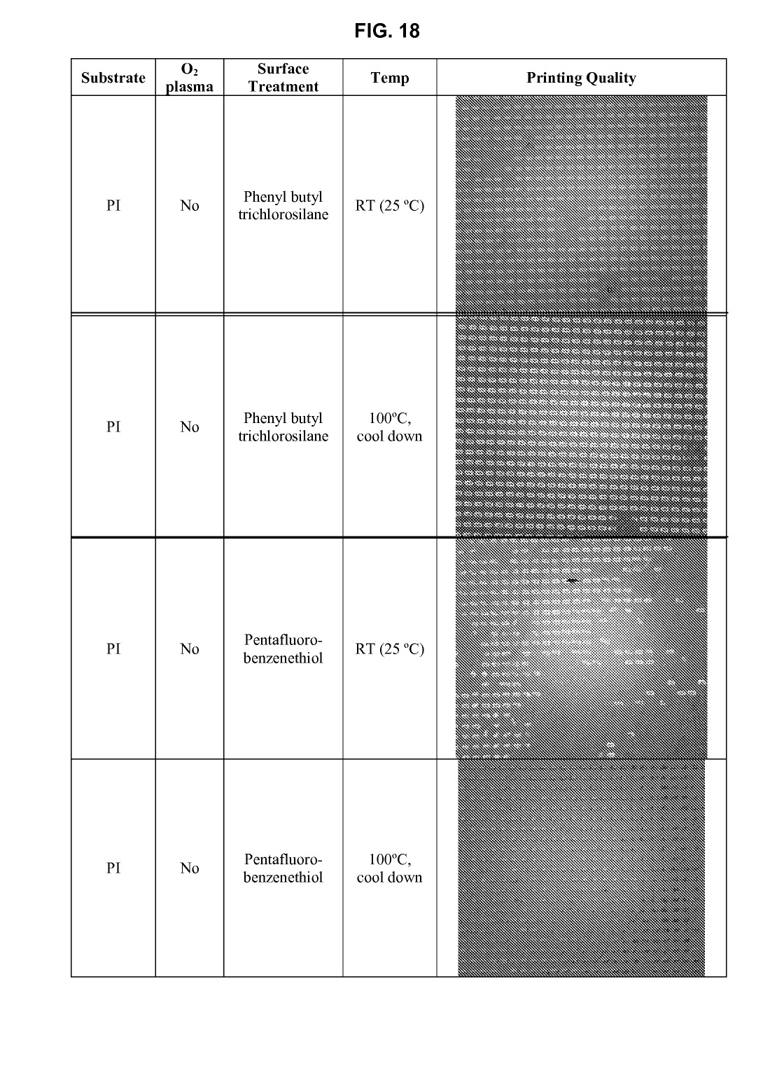

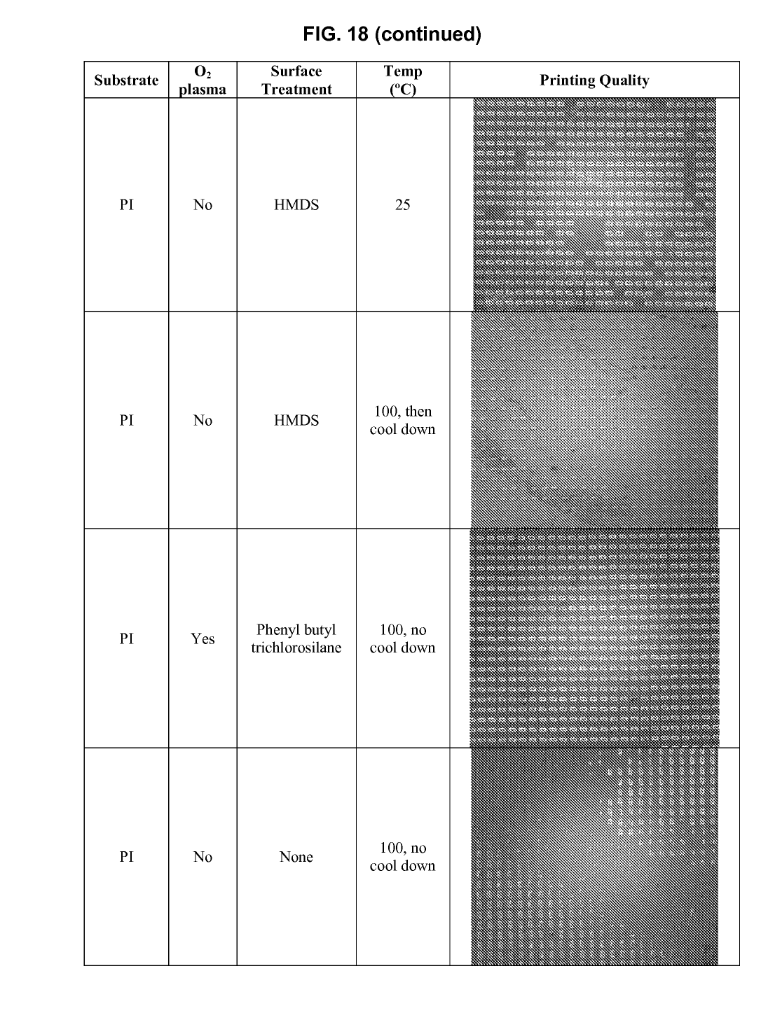

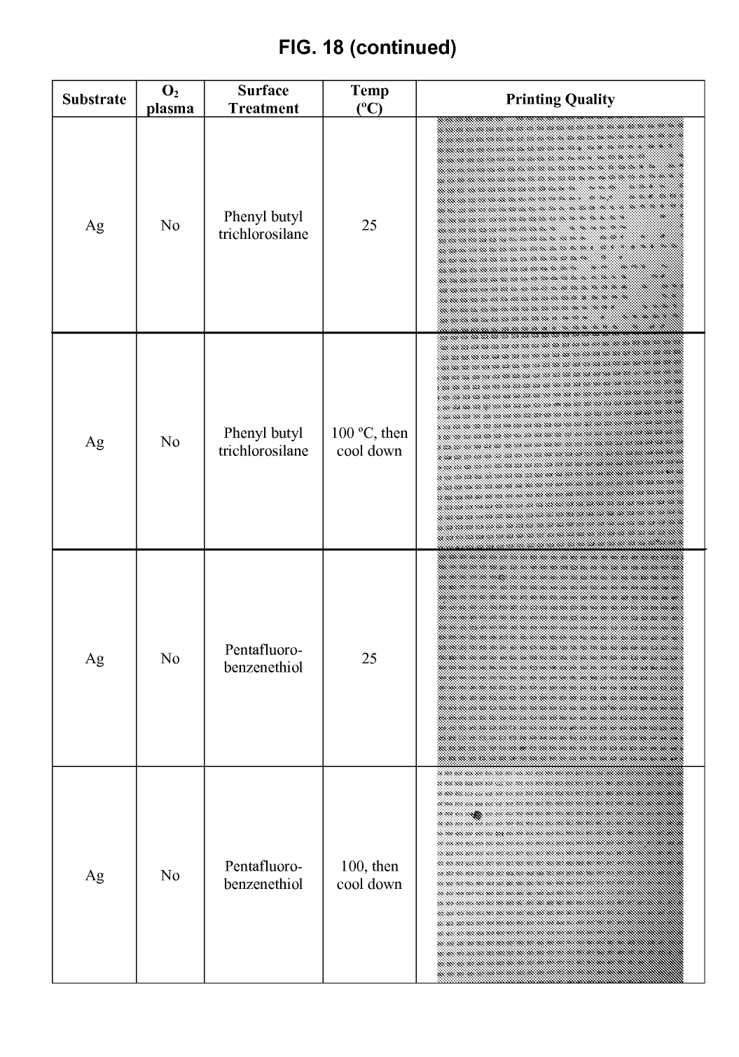

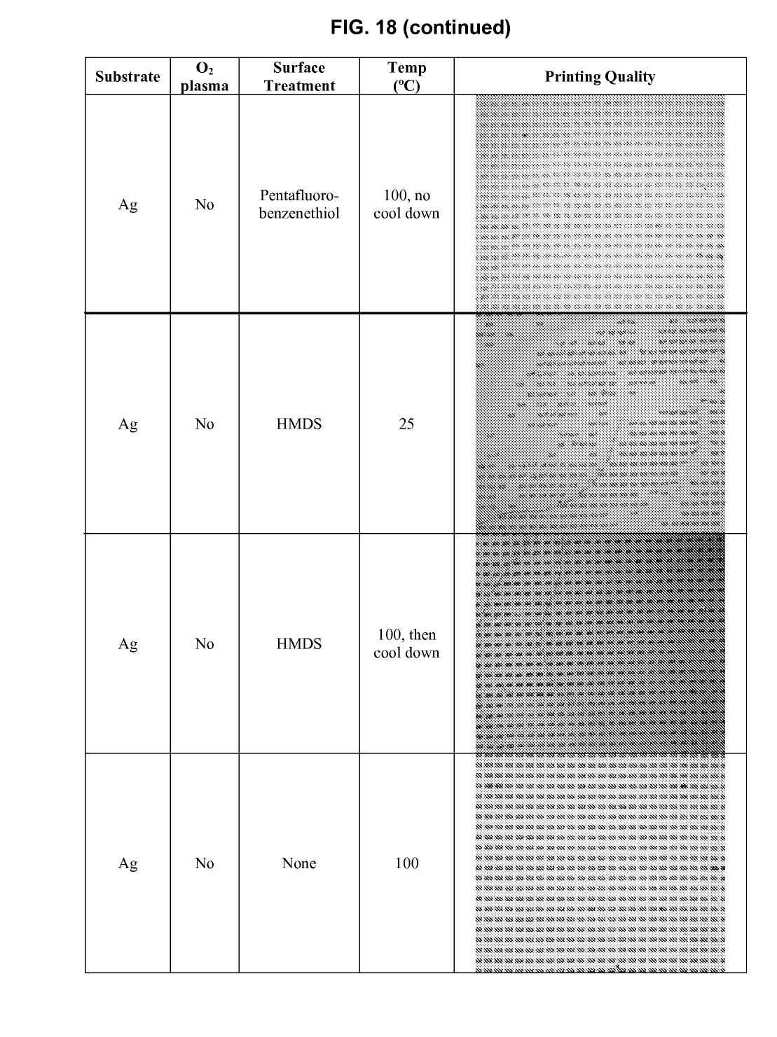

Additional experiments were performed to determine the effect of temperature and the use of identical surface pre-treatments on PI and Ag substrates. The results obtained with PDMS stamps pre-treated with a fluorinated-SAM are summarized in FIG. 18. Printing at 100° C. yielded satisfactory conductive or semiconductive polymer patterns regardless of whether the stamp was removed at 100° C. or removed at room temperature. Furthermore, it was not necessary to clean (i.e., pre-treat) either of the Ag substrate (e.g., with nitric acid) or the PI substrate (e.g., with plasma) prior to contacting to achieve satisfactory pattern transfer at 100° C. Indeed, the conductive or semiconductive polymer transferred to the Ag substrate at 100° C. regardless of whether the substrate was pre-treated. Thus, it is possible to use a single pre-treatment process for composite substrates having both PI and Ag patterned areas to achieve high-quality patterning of a conductive or semiconductive polymer on these substrates. And moreover, the patterning process can be performed at room temperature if desired.

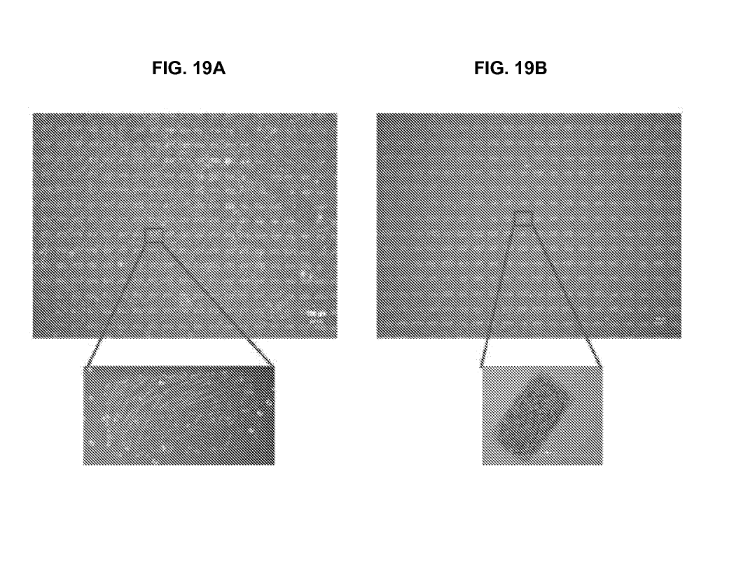

Further direct patterning experiments were performed on PI substrates. A PI substrate was pre-treated with an atmospheric plasma and then functionalized with phenyl trichlorosilane or 4-phenyl butyl trichlorosilane. A polymer semiconductor (2 wt % arylene vinylene polymer in cumene) was spin-coated onto an epoxy stamp having at least one protrusion thereon. The stamp was then contacted with the PI substrate for 2 minutes at about 150° C. while a 420 g mass was rested on the back surface of the stamp. While continuing the contacting, the stamp/substrate stack was then cooled to room temperature and the stamp was removed from the substrate. The resulting patterns are shown in FIGS. 19A and 19B.

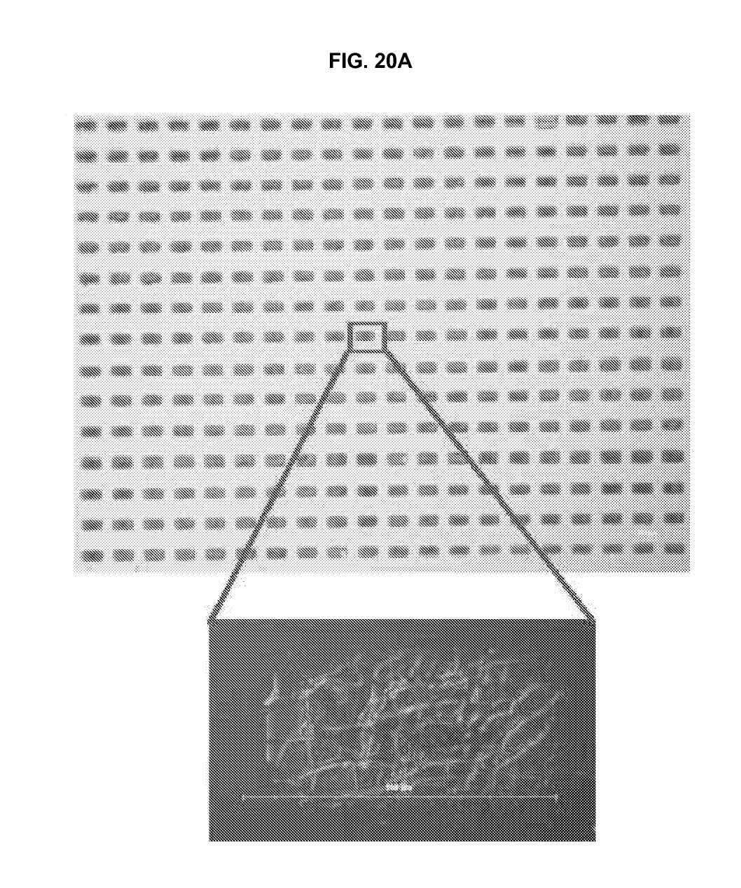

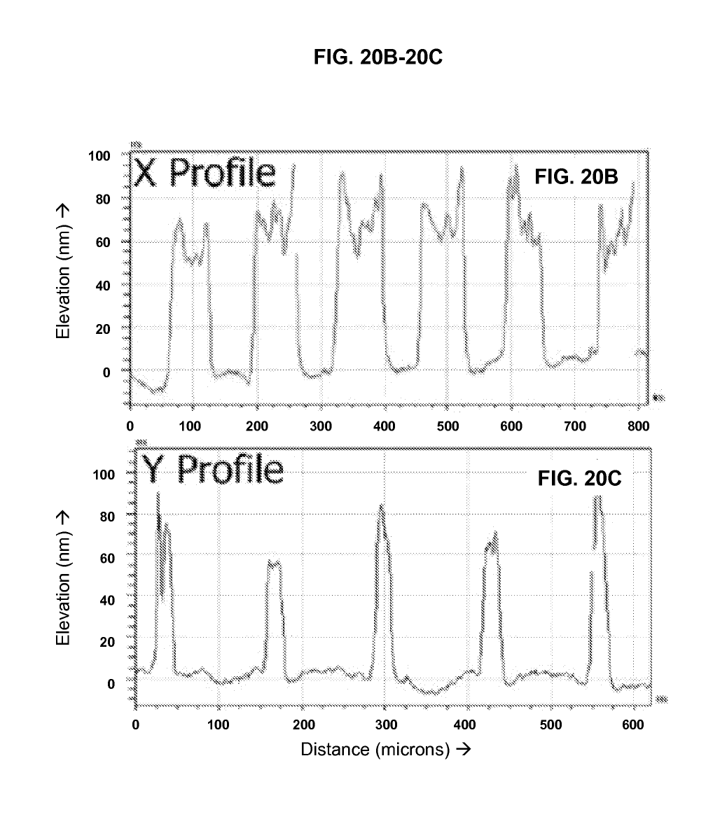

Additional experiments were performed using direct printing on a Ag substrate. The Ag substrate was pre-treated with nitric acid, and then rinsed with deionized water and then ethanol. The substrate was then soaked in a 10 mM solution of pentafluorobenzenethiol (“PFT”), or nitrobenzenethiol (“NBT”), or exposed to PFT vapors in a reduced pressure atmosphere. A polymer semiconductor (2 wt % arylene vinylene polymer in cumene) was spin coated onto an epoxy stamp having at least one protrusion thereon. The stamp was then contacted with the PI substrate for 2 minutes at about 150° C. while a 420 g mass was rested on the back surface of the stamp. While continuing the contacting, the stamp/substrate stack was then cooled to room temperature and the stamp was removed from the substrate. The results of these printing experiments are shown in FIG. 20A-20C.

As described throughout, a conductive or semiconductive polymer pattern can be successfully transferred to a substrates (e.g., PI and/or Ag) using a modified PDMS stamp. The printed patterns include continuous pixels of about 50 nm to about 100 nm thickness over a 1 cm×1 cm test area. The flexibility of soft lithographic patterning to different processing conditions has also been demonstrated, including a range of solvents, temperatures, and surface treatments.

### Example 7

The effect of ink composition on patterning was determined by varying the ink composition. A stamp having at least one protrusion comprising H-PDMS was prepared by the procedure described in Example 4 except that a glass backplane was joined to the PDMS backing layer. The face of the at least one protrusion on the stamp had a length of 90 μm and a width of 50 μm.

For the patterning, the stamp was swelled with p-xylene, and the ink was deposited onto the pre-treated stamp and then spun at 2,000 rpm for several seconds. Immediately after spinning, the coated stamp was contacted with a substrate for about 10-20 seconds with a pressure of about 1.4 psi applied to the stamp's glass backing layer. The applying and contacting were performed at room temperature (about 25° C.). In some embodiments, a lateral dimension of the ink coating on the face of the at least one protrusion was measured. The patterning process was repeated using four different ink compositions (Inks A-D), and the stamp was cleaned after each process. In every case, the ink coating was maintained in a fluidic, gelled, or otherwise flexible, non-hardened state between applying the ink to the stamp and contacting the coated stamp with the substrate. Coated stamps in which the ink was permitted to dry resulted in a complete lack of pattern transfer. The results are listed in Table 3.

TABLE 3
Effect on ink composition ink coating and transfer efficiency.

| | Conductive or | | | | | | Ink | |
|---|---|---|---|---|---|---|---|---|
| | semiconductive | Conc. | | Conc. | | Conc. | Coating | Transfer |
| Ink | polymer | (wt-%) | Solvent 1 | (% v/v) | Solvent 2 | (% v/v) | (Length) | Efficiency |
| A | Arylene | 1.7% | Xylene | 0% | Toluene | 100% | 90 μm | 10% |
| | vinylene | | | | | | | |
| | copolymer | | | | | | | |
| B | Arylene | ″ | ″ | 10% | ″ | 90% | 87 μm | >90% |
| | vinylene | | | | | | | |
| | copolymer | | | | | | | |
| C | Arylene | ″ | ″ | 50% | ″ | 50% | 84 μm | ~100% |
| | vinylene | | | | | | | |
| | copolymer | | | | | | | |
| D | Arylene | ″ | ″ | 100% | ″ | 0% | 80 μm | ~100% |
| | vinylene | | | | | | | |
| | copolymer | | | | | | | |

As shown in Table 3, when an ink containing a single solvent having a vapor pressure greater than about 20 mm Hg is utilized (i.e., toluene, which has a vapor pressure of 28.5 mm Hg at 25° C.), the wetting of the stamp by the ink is highly efficient. Specifically, the ink completely coats the face of the at least one protrusion (i.e., the lateral dimension of the ink coating is 90 μm, which is also the lateral dimension of the face of the protrusion). However, the ink containing only toluene as a solvent exhibited poor transfer from the coated stamp to a substrate. The ink was transferred from only about 10% of the coated protrusions to the substrate. The transfer efficiency could be improved by increasing the temperature during the contacting. For example, heating the stamp or substrate to about 40° C. or more can increase the transfer efficiency to greater than 90%.

The transfer efficiency at room-temperature increased dramatically to more than 90% when a small amount of a solvent having a vapor pressure of about 20 mm Hg or less was included in the ink (i.e., Ink B, containing 10% xylene, which has a vapor pressure of about 8.8 at 25° C.). Additionally, the lateral dimensions of the ink coating on the face of the at least one protrusion were largely retained, decreasing only about 3% (from 90 μm to 87 μm). Thus, the presence of a solvent having a vapor pressure of about 20 mm Hg or less greatly enhances the patterning process of the present invention.

Further increase in the concentration of the solvent having a vapor pressure of about 20 mm Hg or less (i.e., Ink C, containing 50% xylene) led to additional improvements in transfer efficiency. However, the improvement in pattern transfer efficiency (from about 90% to about 100%) was accompanied by a further reduction in the lateral dimensions of the ink coating on the face of the at least one protrusion (i.e., to about 84 μm, compared to a maximum possible dimension of 90 μm).

Eliminating the low vapor pressure solvent (i.e., toluene) from the ink (i.e., Ink D), resulted in a further decrease of the lateral dimension of the ink coating on the face of the at least one protrusion (i.e., to about 80 μm, from a maximum possible lateral dimension of 90 μm). The transfer efficiency was retained at about 100%.

These results demonstrate that the ink composition can be adjusted to optimize and balance the efficiency by which the ink is applied to and coats a stamp, as well the efficiency with which an ink coated onto a stamp is transferred to a substrate. In particular, for the stamp and substrate combination examined herein, an ink containing a conductive or semiconductive polymer, a first solvent having a vapor pressure of about 20 mm Hg or less, and a second solvent having a vapor pressure greater than the first solvent provided the overall best performance.

### Example 8

An elastomeric stamp prepared according to the procedure of Example 4 having a stainless or glass backing layer was immersed in p-xylene and loaded into a spray coating apparatus. An ink comprising a conductive or semiconductive polymer (0.9% by weight arylene vinylene copolymer in p-xylene) was spray coated onto the stamp at room temperature and immediately contacted with a flexible gold substrate or a rigid polyimide-coated glass substrate for 2 seconds. A pressure of approximately 1.3 psi was applied to the backing layer of the stamp during the contacting. Transfer of the conductive or semiconductive polymer was observed over the tested range of 0.2 psi to 2 psi. A transfer efficiency>99% was observed when spray coating was utilized for applying the ink to a stamp having a protrusion comprising H-PDMS. Thus, high-quality conductive or semi-conductive polymer patterns were prepared using a spray-coating process without the need for an incubating step.

### Example 9

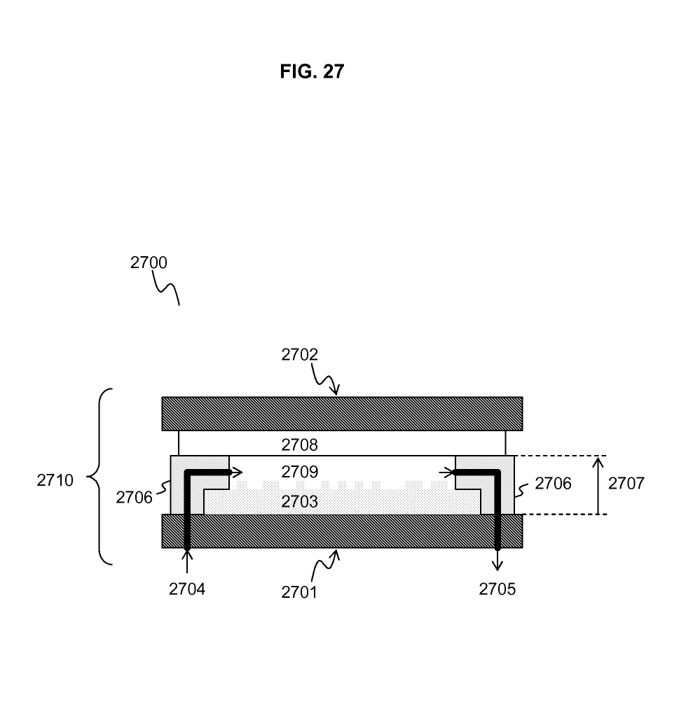

Stamps having a surface area of 10 cm×10 cm were prepared by providing a master (i.e., a silicon wafer having a raised pattern of photoresist thereon) of sufficient surface area. FIG. 27 provides a cross-sectional schematic representation of the molding apparatus, 2700, used to prepare the stamp. Referring to FIG. 27, the master, 2703, was placed on a steel plate, 2701, having an injection port, 2704, and a vent, 2705. A spacer, 2706, was placed to around the edges of the master, wherein the height of the spacer, 2707, determined the thickness of the stamp. A rigid or semi-rigid backing layer, 2708, (i.e., glass) was positioned in contact with the spacer, thereby forming an enclosed volume, 2709, that would become the stamp. The rigid backing layer, 2708, was secured in position using a second steel plate, 2702. A clamp was used to rigidly secure the stack, 2710, and an elastomer precursor was injected into the port, 2704. After the volume, 2709, was filled with the elastomeric precursor, the composition was cured at 80° C. for about 12 hours. The stamp had a thickness of about 750 μm.

The stamp had a mean distortion of about 15-18 μm across the 100 cm² surface area. This distortion arose from a differential thermal expansion between the silicon master and the glass backing layer, resulting in an isotropic shrinkage in the stamp of about 0.034%. This is in agreement with the theoretical value of 0.033%, calculated using Equation (4):

(α₁−α₂)(T_{f}−T_{c})=% Distortion (4)

wherein α₁ and α₂ refer to the coefficients of thermal expansion for the materials that contact the surfaces of the stamp, T_{f} refers to the final temperature after curing (i.e., room temperature or about 20° C.), and T_{c} refers to the curing temperature (i.e., about 80° C.). The coefficients of thermal expansion for glass (α₁) and silicon (α₂) are 8.5 ppm and 3 ppm, respectively. Based on Equation (4), isotropic distortions in the stamp surface can be minimized by compensating for distortions with an anisotropic master design, using a master having the same coefficient of thermal expansion as the rigid or semi-rigid backing layer, curing at room temperature, and combinations thereof. Additional methods for minimizing distortions in the stamp surface and increasing the planarity of the final stamp include, but are not limited to, reinforcing the steel plates to minimize buckling and/or bending during the injection molding process, utilizing a high precision mold having a non-compressible spacer, and the like, and combinations thereof.

### CONCLUSION

These examples illustrate possible embodiments of the present invention. While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

It is to be appreciated that the Detailed Description section, and not the Summary and Abstract sections, is intended to be used to interpret the claims. The Summary and Abstract sections can set forth one or more, but not all exemplary embodiments of the present invention as contemplated by the inventor(s), and thus, are not intended to limit the present invention and the appended claims in any way.

All documents cited herein, including journal articles or abstracts, published or corresponding U.S. or foreign patent applications, issued or foreign patents, or any other documents, are each entirely incorporated by reference herein, including all data, tables, figures, and text presented in the cited documents.

What is claimed is:

1. A process for forming a conductive or semiconductive polymer pattern on a substrate, the process comprising:
providing a stamp having a surface including at least one protrusion thereon, the protrusion being contiguous with and defining a pattern on the surface of the stamp;
applying an ink comprising a conductive or semiconductive polymer and a solvent to the stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer pattern has an electron or hole mobility of about 10⁻⁶ cm²/V·s or more.

2. The process of claim 1, further comprising preventing chemical or photo-initiated degradation of the conductive or semiconductive polymer during the applying and the contacting.

3. The process of claim 2, wherein the preventing comprises shielding the conductive or semiconductive polymer from ultraviolet light.

4. The process of claim 2, wherein the preventing comprises excluding oxidative reagents from the conductive or semiconductive polymer during the applying and the contacting.

5. The process of claim 1, further comprising maintaining the conductive or semiconductive polymer in a fluidic, gelled, or flexible state during at least the contacting.

6. The process of claim 5, further comprising maintaining the stamp, the substrate, or a combination thereof at a temperature of about 50° C. or less during the contacting.

7. The process of claim 6, further comprising: wetting the stamp with a first solvent prior to the applying, wherein the first solvent is the same or different from the ink solvent, and wherein the first solvent maintains the ink in a fluidic, gelled or flexible state during at least the contacting.

8. The process of claim 7, wherein the first solvent has a vapor pressure at 25° C. of about 20 mm Hg or less.

9. The process of claim 6, further comprising: wetting the stamp with a first solvent prior to the applying, wherein the first solvent is the same or different from the ink solvent, and wherein the first solvent facilitates uniformly coating the at least one protrusion with the ink.

10. The process of claim 9, wherein the first solvent has a vapor pressure at 25° C. of about 20 mm Hg or less.

11. The process of claim 5, further comprising maintaining the stamp, the substrate, or a combination thereof at a temperature of about 50° C. or more during the contacting.

12. The process of claim 11, further comprising providing thermal energy to the substrate, the stamp, or a combination thereof during the contacting.

13. The process of claim 1, further comprising pre-treating the stamp surface prior to the applying.

14. The process of claim 13, wherein the pre-treating comprises depositing on at least a portion of the stamp a layer chosen from: a fluorinated(C₄-C₂₀)alkyl-trihalosilane, a fluorinated(C₄-C₂₀)alkyl-trialkoxysilane, a halogen radical, an elastomer coating having a modulus of about 3 MPa or more, a polyacrylate coating, a polyurethane coating, an epoxy coating, a metal coating, a metal oxide coating, composites thereof, and combinations thereof.

15. The process of claim 1, further comprising incubating the coated stamp for a time period of about 2 minutes to about 1 hour prior to the contacting.

16. The process of claim 1, wherein the applying comprises coating the stamp with the ink, incubating the coated stamp for about 1 minute to about 10 minutes, and spinning the stamp at about 100 to about 5,000 rpm.

17. The process of claim 1, wherein the applying provides a coated stamp comprising a discontinuous coating of the ink on the at least one protrusion and the stamp surface.

18. The process of claim 1, wherein the ink is substantially free from crystallinity during the applying and the contacting.

19. The process of claim 1, wherein the conductive or semiconductive polymer pattern is substantially free from cracks, pinholes, and mechanical defects.

20. A product prepared by the process of claim 1.

21. The product of claim 20, wherein the product is chosen from a organic thin film transistor, an organic light emitting diode, an organic field effect transistor, an organic molecular switch, an organic photovoltaic device, an organic light-emitting electrochemical cell, and combinations thereof.

22. A low-temperature process for forming a conductive or semiconductive polymer pattern on a substrate, the process comprising:
providing a stamp having a surface including at least one protrusion thereon, the protrusion being contiguous with and defining a pattern on the surface of the stamp, wherein the at least one protrusion comprises an elastomer having a modulus of about 3 MPa or more;
wetting the stamp with a first solvent to provide a wetted stamp;
applying an ink comprising a conductive or semiconductive polymer and a solvent to the wetted stamp to provide a coated stamp; and
contacting the coated stamp with a substrate for a period of time sufficient to transfer the conductive or semiconductive polymer from the at least one protrusion to the substrate to form a conductive or semiconductive polymer pattern thereon, wherein the conductive or semiconductive polymer is maintained in a fluidic, gelled, or flexible state during the contacting, wherein a temperature of about 50° C. or less is maintained during the process, and wherein the conductive or semiconductive polymer pattern has an electron or hole mobility of about 10⁻⁶ cm²/V·s or more.

23. The process of claim 22, wherein the at least one protrusion comprises an elastomer having a surface free energy that is about 50% or less than a surface free energy of the substrate.

24. The process of claim 22, wherein the at least one protrusion comprises an elastomer having a surface free energy of about 25 ergs/cm² to about 35 ergs/cm².

25. An elastomeric stamp composition comprising:
an elastomeric stamp having a body and a surface including at least one protrusion thereon, the protrusion having face and sidewall portions, and the protrusion being contiguous with and defining a pattern on the surface of the stamp, the face comprising a first elastomer and the body comprising a second elastomer, wherein the first elastomer has a modulus at least about 20% greater than the second elastomer;
a first solvent having a vapor pressure at 25° C. of about 20 mm Hg or less present in at least the body in a concentration of about 30% by volume, wherein the first solvent is in fluid communication with the face portion; and
an ink comprising a conductive or semiconductive polymer and a solvent discontinuously coating the stamp surface and the at least one protrusion, wherein the ink uniformly coats the face of the at least one protrusion, wherein the sidewall portion is substantially free from the ink, and wherein the solvent present in the body continuously wets the ink on at least the face.

26. The elastomeric stamp composition of claim 25, further comprising a rigid backing layer attached to the body and substantially parallel to the face portion.

27. The elastomeric stamp of claim 25, wherein the first elastomer has a modulus of 3 MPa or more and the second elastomer has a modulus of about 3 MPa or less.

28. A metallized elastomeric stamp composition comprising:
an elastomeric stamp having a surface including at least one protrusion thereon, the protrusion having face and sidewall portions, and the protrusion being contiguous with and defining a pattern on the surface of the stamp;
a metal coating at least the face of the at least one protrusion;
a SAM-forming species covalently attached to at least a portion of the metal coating; and
an ink comprising a conductive or semiconductive polymer and a solvent discontinuously coating the stamp surface and the at least one protrusion, wherein the ink uniformly coats the face of the at least one protrusion and wherein the sidewall portion is substantially free from the ink.

29. The composition of claim 28, wherein the SAM-forming species has the structure:
-L-M-X
wherein -L- is a linker group that covalently bonds the SAM-forming species to the metal surface; -M- is a group chosen from: an optionally substituted C₁-C₂₀ alkyl, an optionally substituted C₁-C₂₀ alkenyl, an optionally substituted C₁-C₂₀ alkynyl, an optionally substituted C₁-C₂₀ aryl, an optionally substituted C₁-C₂₀ heteroaryl, and combinations thereof, and -X is an optional terminal group.

30. The composition of claim 29, wherein -L- is a group chosen from: —S—; —O—; —NH—; —NR—; —NH—C(O)—; —NR—C(O)—; —C(O)—NH—; —C(O)—NR—; —SiH₂—; —Si(R)(R′)-; —Si(OR)(OR′)—; and combinations thereof, wherein R and R′ are independently an optionally substituted C₁-C₈ alkyl, alkenyl, alkynyl, aryl, or heteroaryl group.

31. The composition of claim 29, wherein —X is a group chosen from: fluoro (—F), secondary amino (—N(R)(R′)), trialkylsilyl (—Si(R)(R′)(R″)), and combinations thereof, wherein R, R′ and R″ are independently a C₁-C₄ straight- or branched-chain alkyl group.

32. The composition of claim 31, further comprising a second SAM-forming species having the structure:
-L-M-X′
wherein -X′ is a group chosen from: carboxy (—COOH), primary amino (—NH₂), hydroxy (—OH), and combinations thereof.

33. The composition of claim 28, wherein about 50% or more of the metal surface area is covered by the SAM-forming species covalently attached thereto.

34. The composition of claim 33, wherein the SAM-forming species uniformly covers the metal surface.

35. A polymer ink composition consisting essentially of:
a semiconductive or a conductive or semiconductive polymer in a concentration of about 0.1% to about 5% by weight;
a first solvent having a vapor pressure at 25° C. of about 20 mm Hg or less present in a concentration of about 50% or less by weight; and
a second solvent having a vapor pressure greater than the first solvent, wherein the semiconductive or a conductive or semiconductive polymer has a solubility in the second solvent of about 1 mg/mL or more.

36. The composition of claim 35, wherein the second solvent is toluene.
